(19) United States
(12) Patent Application Publication
(10) Pub. No.: US 2014/0225630 A1
(43) Pub. Date: Aug. 14, 2014

(54) STUN DEVICE TESTING APPARATUS AND METHODS

(71) Applicant: Aegis Industries, Inc., Rockville, MD (US)

(72) Inventors: Kenneth J. Stethem, Hailey, ID (US); Seymour Friedel, Mena, AR (US); Michael A. Bromberg, Mason, NH (US); Peter Lewis, Nashua, NH (US); Anthony Anzelmo, Bolivia, NC (US)

(73) Assignee: Aegis Industries, Inc., Rockville, MD (US)

(21) Appl. No.: 14/042,010

(22) Filed: Sep. 30, 2013

Related U.S. Application Data
(60) Provisional application No. 61/707,101, filed on Sep. 28, 2012.

(51) Int. Cl. F41H 13/00; G01R 27/02

(52) U.S. Cl. CPC F41H 13/0018; G01R 27/02
USPC 324/691

(57) ABSTRACT

A testing apparatus includes a housing having a port for receiving a discharge end of an electrical discharge device. A discharge-receiving circuit is operatively connected to the port, and is configured to receive a discharge from the electrical discharge device. The discharge-receiving circuit includes a default resistor and at least one supplemental resistor. When in a first setting, the discharge-receiving circuit is configured so as to pass the discharge automatically through at least the default resistor. When in a second setting, the discharge-receiving circuit is configurable so as to selectively pass the discharge through at least one of the plurality of resistors.

### CROSS-REFERENCE TO RELATED APPLICATIONS

This application claims priority to and the benefit of U.S. Provisional Patent Application Ser. No. 61/707,101, entitled “Stun Device Testing Apparatus and Methods,” filed Sep. 28, 2012, the disclosure of which is hereby incorporated by reference herein in its entirety.

### INTRODUCTION

The use of neuromuscular incapacitation (NMI) devices (and other stun devices that emit electrical discharges against a target mammal) has increased over the last decade to encompass over 200,000 units in operation worldwide with over 800,000 actual firing deployments involving training personnel and law enforcement incidents. The output of stun devices is electrical in nature and thus may not leave an identifying mark or clear trace of historical events, unlike a bullet, that normally leaves such a mark. Furthermore, stun devices are designed to incapacitate effectively and temporarily an individual based on a unique and specific electrical output, as stated by a manufacturer.

Currently, there are many stun devices available around the world, featuring a variety of outputs with respect to voltage, current, waveform, and timing intervals. While many are available, however, only a limited number of manufacturers sell stun devices in a gun form-factor. U.S. Pat. Nos. 7,234,262 and 6,636,412 by Taser International and U.S. Pat. No. 6,575,073 by Stinger Systems all describe currently available commercial stun devices. The disclosures of these patents are hereby incorporated by reference herein in their entireties. The electrical output of each company's device differs significantly from the others and within each specified output for a given load, but each manufacturer makes their own claims of effectiveness and safety, as discussed below. The differences and characteristics of electrical output of stun devices are known from detailed and sophisticated measurements with a variety of specialized oscilloscopes and related measuring tools.

FIGS. 1, 1A and 2 and TABLE 1 show detailed traces of waveforms under specific conditions using sophisticated oscilloscopes as well as a summary of typical electrical output for a variety of related, electrically-focused technologies used in the medical profession and other fields. FIG. 1 shows waveforms from a commercially available stun device of a hand-held type, illustrating several important features of the waveform, including pulse height and charge, repetition rate, slope of the peak, duration of the waveform, changing shape of the waveform and total energy delivered. FIG. 1 depicts the waveforms at four resistances, while FIG. 1B depicts the waveforms of another stun device, at three resistances. FIG. 2 shows additional details of an “idealized” waveform discharged by a device presently in commercial use, indicating a variety of characteristics. The characteristics shown in FIGS. 1, 1A, and 2 define the waveform of choice for a given device and manufacturer. TABLE 1 provides a comparison of stun devices, and includes similar information for biomedical devices employing electrical current, such as Electroconvulsive (ECT) therapy, cauterizing devices (electro-surgery), and defibrillators.

TABLE 1
Electrical Discharge Comparison of Various Device Types

| | Voltage | | Current | | Pulse Duration | | Pulse Frequency | | Power | |
|---|---|---|---|---|---|---|---|---|---|---|
| Electric Fencing | 5-10 | kV | 10-20 | mA | 0.1-1 | sec | 0.5-1 | Hz | 0.1-18 | J/pulse |
| Early Stun Devices | 40-100 | kV | 3-4 | mA | ~20 | μsec | 5-20 | Hz | 0.8 | J/pulse |
| 7 watt Taser | | | | | | | | | | |
| Current Stun Devices | 18-50 | kV | 2-4 | mA average | 11 | μsec | 10-25 | Hz | 0.1-1.8 | J/pulse |
| 26 watt Taser | | | 18 | A peak | | | | | | |
| ECS, ECT | 70-450 | V | 20-900 | mA | 1.5 | msec | 70 | Hz | 0.6 | J/pulse |
| Defibrillators | ~750-1500 | V | 20-65 | A | 5-7 | msec | 1-6 | total | 100-360 | J/pulse |

| | | | | | | | | |
|---|---|---|---|---|---|---|---|---|
| Electrosurgery | 1000-9000 | V | variable | variable | <200,000 | Hz | 80-300 | Watts |

It is helpful to note that a manufacturer's claim of effectiveness and safety must be linked directly to a consistent electrical output. Manufacturers have conducted various safety studies involving humans and animals to allay public fears and to use as a defense in litigation, where the actual output of the device is considered to have been a cause of injury or death of the target. Thus, lacking regulatory approval of a universal waveform, each company documents its waveform's safety by performing safety studies for its own devices. While safety factors of each waveform have been disclosed in publications, the device use data and associated instances of injury and death to date also reveals significant questions regarding safety. Thus, the identity and integrity of a specific waveform is of high value to a number of stakeholders including manufacturers, end-users (e.g., law enforcement) and the public on whom the devices are deployed for non-lethal purposes. Examples of studies resulting in claims of both safety and potential injury can be found, for example, in the following publications: Jeffrey D. Ho, MD, James R. Miner, MD, Dhanunjaya R. Lakireddy, MD, Laura L. Bultman, MD, William G. Heegaard, MD, MPH, “Cardiovascular and Physiologic Effects of Conducted Electrical Weapon Discharge in Resting Adults,” ACADEMIC EMERGENCY MEDICINE, 13:589-595 (2006); Valentino, D. J., Walter, R. J., Dennis, A. J., Nagy, K., Loor, M. M., & Winners, J. et al., “Neuromuscular effects of stun device discharges,” JOURNAL OF SURGICAL RESEARCH, 143(1), 78-87 (2007); Valentino, D. J., Walter, R. J., Nagy, K., Dennis, A. J., Winners, J., & Bokhari, F. et al., “Repeated thoracic discharges from a stun device,” JOURNAL OF TRAUMA—INJURY, INFECTION AND CRITICAL CARE, 62(5), 1134-1142 (2007); A. Esquivel, E. Dawe, J. Sala-Mercado, R. Hammond, C. Bir, “The Physiologic Effects of a Conducted Electrical Weapon in Swine,” ANNALS OF EMERGENCY MEDICINE, Vol. 50, Issue 5, Pages 576-583 (2007); Lakkireddy, D., Khasnis, A., Antenacci, J., Ryshcon, K., Chung, M. K., & Wallick, D. et al., “Do electrical stun guns (TASER-X26®) affect the functional integrity of implantable pacemakers and defibrillators?,” EUROPACE, 9(7), 551-556 (2007); and Lakkireddy, D., Wallick, D., Ryschon, K., Chung, M. K., Butany, J., & Martin, D. et al., “Effects of cocaine intoxication on the threshold for stun gun induction of ventricular fibrillation,” JOURNAL OF THE AMERICAN COLLEGE OF CARDIOLOGY, 48(4), 805-811 (2006). The disclosures of these references are hereby incorporated by reference herein in their entireties.

Notwithstanding a manufacturer's claim of safety, electric stun device safety can only be assured if the stated waveform is both proven safe and is consistently produced and delivered by the device. Given the importance of this link between device output, safety, and effectiveness, we have determined it to be desirable that the output be verifiable for a given device during its cycle of normal duty and on a schedule of appropriate timing to ensure that only devices having outputs that are studied and verified safe are used on targets. However, there is no easy, simple way to verify device output on a regular basis within the typical law enforcement context. Thus, we have determined that verification of device output is needed in the law enforcement setting, in a testing apparatus that is simple to operate and inexpensive to purchase.

It also is reasonable to assume that as stun devices of different manufacturers and types become even more widely deployed and better studied, there will be a need to examine in detail the output of a specific device or class of devices. This output may be in relation to a specific incident or a class of incidents in which one or more devices are involved, including devices by different manufacturers. In such a case, currently, it is necessary to use sophisticated oscilloscopes operated by an expert or someone very familiar with the measurement equipment and the particular features of stun devices to capture, study and analyze the device's electrical output. Further, the waveform must be interpreted to assess whether it is, in fact, safe. While this approach may be helpful in determining the safety of a device right off the assembly line, stun devices are rarely, if ever, tested after being in the field for a period of time. Moreover, any tests performed on a particular device are often performed only after a discharge against a target has occurred, usually, and unfortunately, after there exists a reason for testing (e.g., an unintentional death of a target during deployment). There is essentially no focus on the actual routine verification of output prior to routine use. In addition, because electrical currents are transient and may not leave tangible traces that are currently recognized by the medical profession, the commonly recognized characteristics of an electrical discharge (voltage, amplitude, etc.) are often the only measure of output that was received by the target. These commonly recognized characteristics may not be sufficient, in all circumstances, to determine adequately or reliably the reason for an adverse result (i.e., a death of a target).

Moreover, if one follows the analogy of forensic study of ballistic evidence, it is clear that the capability to collect and analyze electric stun discharge evidence is lacking. Thus, we have determined that it is highly advantageous to have a device or series of measurement devices that are easy to operate and understand and are linked to the known waveform output of stun devices available. While some attempts are being made to develop systems to test particular stun devices from a specific manufacturer, these attempts do not appear to contemplate a device that test both existing and not-yet-developed stun devices, or to test and compile information on both existing and not-yet-developed stun devices to enable research into the safety and efficacy of electric waveforms and stun devices, generally. See, e.g., Nelson Bennett, “Tasers' test results sparks technology,” Richmond News (Sep. 9, 2009) (available at http://www2.canada.com/richmondnews/news/story.html?id=0fa3b787-b632-4543-a991-354de3f9cd74), the disclosure of which is hereby incorporated by reference herein in its entirety. Additionally, having these devices readily available (both economically and physically) would allow law enforcement departments and forensic investigators and coroners the capability of in-depth analysis of stun device discharges, as needed.

Stun device output is a function, in part, of the internal electronic circuitry designed to produce a given waveform of a given magnitude and duration. We have determined that it would be desirable for the discharge output to be verified during the life cycle of a device. Changes in output can occur due to a number of factors, including, but not limited to, defective manufacture, component failure due to use, current leakage to operator, change in manufacturing components, deliberate alteration of components and power supply, etc. Additionally, manufacturers develop and sell successor models of stun devices (e.g., Taser models M18, M26, X26, wireless systems, sentry systems; see www.taser.com) and may alter the original waveform and output as models change over time. Moreover, nearly all projectile-based gun-platform stun devices may also deliver a subcutaneous electrical discharge significantly different than a discharge directly against the skin. Thus, manufacturers' stated claims of output should not be relied upon as accurate over the lifetime of use of the device, nor across successor models. It would be desirable to verify such output on a routine basis.

Currently, stun device output is not regulated at the state or federal level with respect to waveform or magnitude, nor are manufacturing standards tied to any stated degree of device performance or acceptable deviation from stated specifications. Without verification, there is little, if any, accountability for holding manufacturers responsible for quality performance features. The lack of verification is problematic for law enforcement officials who use the devices routinely and who may be involved in litigation due to a specific, often fatal, incident. Such details become important in complex deployment situations where drugs, alcohol and extreme agitation, as well as a victim's pre-existing conditions (such as use of pacemakers, etc.) are present. Medical experience has shown that risks from electrical stimulation include abnormal heart rhythms, epileptic seizures, cell injury and death. While there is an extensive history of the use of stun-devices with no apparent long term effects, the possibility exists. Variations from the normal stimuli are of particular concern. For example very fast, high-amplitude transients can produce injury inside of cells. Ventricular fibrillation can be induced more easily at some rates, as well. Thus, a convenient and cost effective program by law enforcement to track and record the features of the devices deployed over time may be desirable.

Currently, a number of oscilloscopes and other measuring devices are employed for the detailed analysis of waveforms and output of stun devices. Many of these measuring devices and oscilloscopes are sophisticated with respect to data capture rate, range and magnitude of signal, signal sampling parameters, and ability to analyze, record and handle large amounts of stored data. The technology involved in typical electrical output analysis includes a multimeter as described in U.S. Pat. No. 7,342,393, issued Mar. 11, 2008, to Newcombe; combination test instruments and voltage detectors as described in U.S. Pat. No. 7,242,173, issued Jul. 10, 2007, to Cavoretto; devices generating electronic test signals as described in U.S. Pat. No. 6,944,569, issued Sep. 13, 2005, to Harbord; digital oscilloscopes with waveform pattern recognition as described in U.S. Pat. No. 6,621,913, issued Sep. 16, 2003, to de Vries; specialized circuits for measuring in-circuit resistance and current as described in U.S. Pat. No. 5,804,979, issued Sep. 8, 1998, to Lund; and devices designed to detect minimum pulse widths of waveforms as described in U.S. Pat. No. 5,708,375, issued Jan. 13, 1998, to Lemmens. U.S. Pat. No. 6,469,492, issued Oct. 22, 2002, to Britz and U.S. Pat. No. 5,930,745, issued Jul. 27, 1999, to Swift disclose additional testing equipment. The disclosures of each of the above-identified references are incorporated by reference herein in their entireties.

Additionally, there are a number of devices that are used to measure and verify electrical signals from a variety of biomedical devices including defibrillators, as described in U.S. Published Patent Application No. 2007/0226574, published Sep. 27, 2007, by Ryan; pacemakers, as described in U.S. Pat. No. 5,209,228, issued May 11, 1993, to Cano; electro-surgery devices; and others. Many electrical testing devices provide comparisons with known electrical standards such as the International Electrotechnical Commission (IEC) and the Association for the Advancement of Medical Instrumentation (AAMI). The disclosures of each of the above-identified references are incorporated by reference herein in their entireties.

However, no universal test devices currently exist that can consistently meet the needs described above for known and to-be-developed stun devices. Additionally, there presently exists no method for imposing accountability on users or manufacturers of stun devices by proving how a particular stun device was operating prior to discharge during routine use against a target. Moreover, there exists no system for collecting information and storing it reliably for “large data” analysis about stun device discharge characteristics to study the effects of stun devices on an industry-wide basis.

### SUMMARY

The technology disclosed herein consists of one or more testing devices or apparatus that are capable of a spectrum of measurements and data-handling features. The testing devices according to the technology include an adapter for effective, consistent, and safe coupling to an instrument capable of accepting, recording and analyzing the outputs of a stun device. Some of the contemplated testing devices include interchangeable adapters specific to testing particular stun devices. The testing device, in a basic form, may record only total electrical output, maximum voltage and current, or other simple numerical data. A more complex embodiment can also allow capture of waveform characteristics such as frequency, repetition rate, pulse train duration, anomalies, etc., at several different load options, each simulating contact with the human body. Other embodiments can provide options of waveform analysis, as compared to a “standard” waveform supplied by a manufacturer or other source. Embodiments of other devices can be equipped with data storage and analytical features, libraries of waveforms of various devices, statistical programs, and a variety of resistance factors simulating electrical pathways through human tissue. Other testing devices according to the technology can also be used to record total output and waveform features for repeated applications of stun devices. Furthermore, certain of these testing devices can report output relative to existing or new standards, regulations, and protocols, for the stun device industry as they are developed, relative to a variety of electrical safety standards in the U.S. or other jurisdictions, or relative to a set of specific standards for stun devices. These standards, regulations, or protocols may be developed by stun device manufacturers, governments, industry organizations, non-governmental organizations, medical organizations, standards-setting organizations, etc.

One difference between the technical features of many of the testing devices described in the Background and one embodiment of the stun device safety tester as described below, is the basic unit of electrical sampling. Available stun devices produce pulses with durations ranging from less than 1 microsecond to tens of milliseconds. In addition, transients associated with spark-gap type stun devices have durations that are fractions of a microsecond, as shown in FIG. 3 (note, e.g., leading spike on negative lobe). Thus, in contrast to defibrillator testers that measure single and very large pulses and pacemaker analyzers that measure relatively wide (slow) pulses over a very short period, the stun device tester in one embodiment will record the detailed behavior of waveforms with features ranging from very fast, high magnitude transients to normal pulse durations of tens of milliseconds. This suggests sampling rates of at least 20 mega samples/second for 10 milliseconds, demanding 200,000 words of storage to recreate waveforms or 20,000 words of storage to identify the presence of fast transients. Sampling rates of 10 mega samples/second may also be utilized. In one embodiment, normal waveforms from a spectrum of devices can be captured and analyzed as well as chaotic and very fast anomalies that, to date, have not been characterized for stun devices. While the medical and safety significance of such transients and anomalies are not entirely understood, such aberrations can be identified and measured to assess their relevance and to help ensure claimed output parameters and safety.

In one aspect, the technology relates to an apparatus including: a housing including a port for receiving a discharge end of an electrical discharge device; and an discharge-receiving circuit operatively connected to the port, the discharge-receiving circuit configured to receive a discharge from the electrical discharge device, wherein the discharge-receiving circuit has: a plurality of resistors including a default resistor and at least one supplemental resistor, wherein when in a first setting, the discharge-receiving circuit is configured so as to pass the discharge automatically through at least the default resistor, and wherein when in a second setting, the discharge-receiving circuit is configurable so as to selectively pass the discharge through at least one of the plurality of resistors. In an embodiment, the at least one supplemental resistor includes a first supplemental resistor and a second supplemental resistor. In another embodiment, a resistance of the default resistor is higher than a resistance of at least one of the first supplemental resistor and the second supplemental resistor. In yet another embodiment, the apparatus includes a switch for selectively setting the discharge-receiving circuit to either of the first setting and the second setting. In still another embodiment, the discharge-receiving circuit is set to the first setting when the discharge-receiving circuit is unpowered.

In another embodiment of the above aspect, the apparatus includes an environmental module for detecting at least one of an ambient temperature, an ambient humidity, and a barometric pressure. In another embodiment, the apparatus includes an air intake fan for drawing ambient air into the housing, and wherein the environmental module detects at least one of the ambient temperature and the ambient humidity, and wherein the environmental module is disposed downstream of the air intake fan. In another embodiment, the discharge-receiving circuit further includes an analysis module.

In another aspect, the technology relates to a method of configuring a circuit, the method including: detecting a condition indicative of a loss of power to the circuit; configuring the circuit such that an electrical discharge through the circuit is routed through at least one of a plurality of resistors, wherein the electrical discharge is received from a device located external to the circuit. In an embodiment, the method includes receiving the electrical discharge from the external device. In another embodiment, the method includes detecting a condition indicative of a receipt of power to the circuit; and selectively configuring the circuit so as to route the discharge through at least one of the plurality of resistors. In yet another embodiment, the method includes selecting a protocol; and selectively configuring the circuit based at least in part on the selected protocol. In still another embodiment, the condition is based at least in part on the position of a switch in the circuit.

In another embodiment of the above aspect, the condition is based at least in part on an absence of supply power to the circuit. In another embodiment, configuring the circuit has at least one of opening or closing a solenoid. In another embodiment, the circuit is disposed within a testing device.

In another aspect, the invention includes an article of manufacture having a computer-readable medium with computer-readable instructions embodied thereon for performing the methods described in the preceding paragraphs. In particular, the functionality of a method of the present invention may be embedded on a computer-readable medium, such as, but not limited to, a floppy disk, a hard disk, an optical disk, a magnetic tape, a PROM, an EPROM, CD-ROM, DVD-ROM or downloaded from a server. The functionality of the techniques may be embedded on the computer-readable medium in any number of computer-readable instructions, or languages such as, for example, FORTRAN, PASCAL, C, C++, Java, PERL, LISP, JavaScript, C#, Tcl, BASIC and assembly language. Further, the computer-readable instructions may, for example, be written in a script, macro, or functionally embedded in commercially available software (such as EXCEL or VISUAL BASIC).

### BRIEF DESCRIPTION OF THE DRAWINGS

Other features and advantages of the present technology, as well as the technology itself, can be more fully understood from the following description of the various embodiments, when read together with the accompanying drawings, in which:

FIG. 1 depicts a graph of waveforms from a commercially-available stun device, under four different resistor loads.

FIG. 1A depicts a graph of waveforms from another commercially-available stun device, under three different resistor loads

FIG. 2 depicts waveform detail and characteristics of a commercially available stun device.

FIG. 3 depicts waveform detail of a particular waveform produced by the stun device of FIG. 2.

FIG. 4A depicts a schematic perspective view of a stun device testing system in accordance with an embodiment of the technology.

FIG. 4B depicts a schematic perspective view of a stun device testing system in accordance with another embodiment of the technology.

FIG. 5A depicts a schematic block diagram of a stun device testing system in accordance with another embodiment of the technology.

FIG. 5B depicts a schematic block diagram of a stun device testing system in accordance with another embodiment of the technology.

FIG. 6A depicts a schematic diagram of a stun device testing system in accordance with another embodiment of the technology.

FIG. 6B depicts a schematic cross-sectional side view of an interface for a stun device testing system in accordance with one embodiment of the technology.

FIG. 6C depicts a partial perspective view of an interior portion of a housing for a stun device testing system in accordance with one embodiment of the technology.

FIG. 7A is a schematic block diagram of a hardware configuration of a stun device testing system in accordance with an embodiment of the technology.

FIG. 7B is a schematic block diagram of a field programmable gate array configuration for a stun device testing apparatus in accordance with an embodiment of the technology.

FIG. 8A is a schematic block diagram of a hardware configuration of a stun device testing apparatus in accordance with another embodiment of the technology.

FIG. 8B is a schematic block diagram of function performed by the hardware configuration of FIG. 8A.

FIG. 9A is a schematic diagram of a circuit utilized in the hardware configuration of FIG. 7A.

FIG. 9B is a schematic diagram of a circuit utilized in a stun device testing system in accordance with another embodiment of the technology.

FIG. 10 is a block diagram of a hardware configuration of a stun device testing apparatus in accordance with another embodiment of the technology.

FIG. 11 is a schematic diagram of a front end circuit utilized in the hardware configuration of FIG. 10.

FIG. 12 is a schematic diagram of control circuit utilized in the hardware configuration of FIG. 10.

FIG. 13 is a schematic diagram of a power circuit utilized in the hardware configuration of FIG. 10.

FIG. 14 is a schematic diagram of a sensor circuit utilized in the hardware configuration of FIG. 10.

FIG. 15 depicts an example CPLD clock diagram in accordance with one embodiment of the technology.

FIGS. 16A and 16B depicts an example addressing scheme in accordance with one embodiment of the technology.

FIGS. 17A-17B depict output load responses to output load steps.

FIG. 17C depict a frequency and phase plot of a response of an input circuit.

FIG. 17D depicts an output load response to an output load step.

FIGS. 18A-18C depict waveform details and characteristics of the stun device of FIG. 2.

FIG. 19 depicts a method of testing an electric discharge stun device, in accordance with one embodiment of the technology.

FIG. 20 depicts a method of ensuring proper operation of an electric discharge stun device, in accordance with one embodiment of the technology.

FIG. 21 depicts a method of determining a biological response to an electric discharge from a stun device, in accordance with one embodiment of the technology.

FIG. 22 depicts a method of configuring a circuit in a stun device testing system in accordance with another embodiment of the present technology.

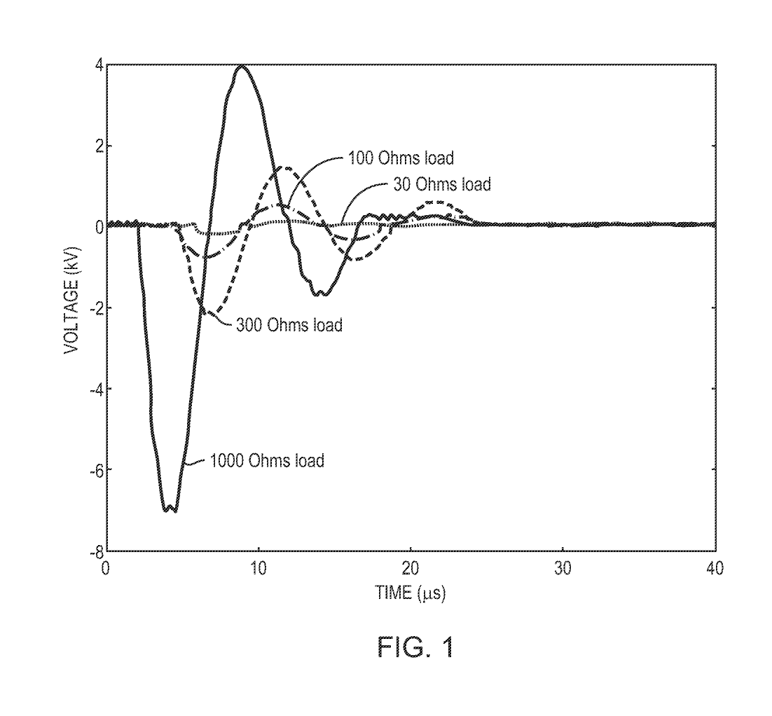

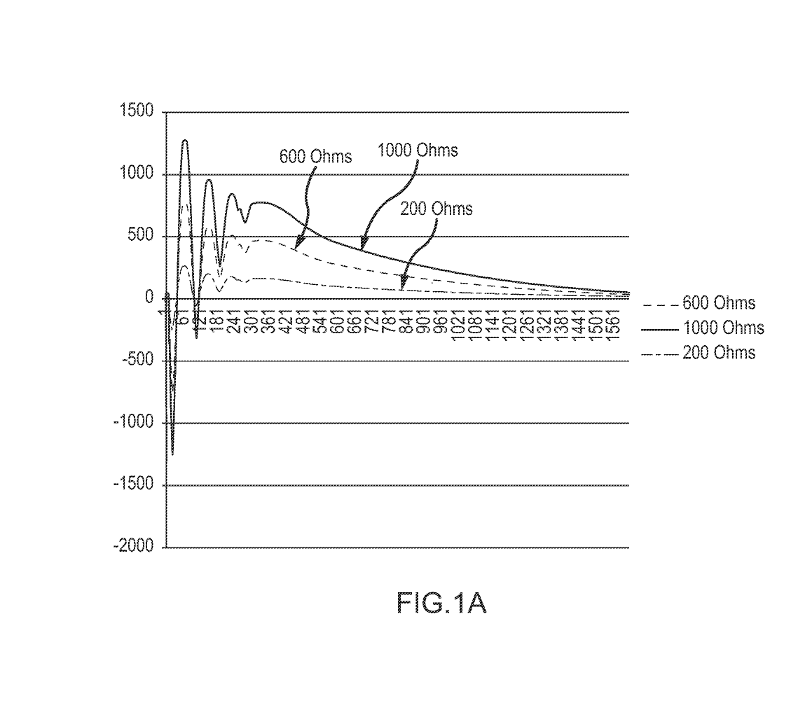

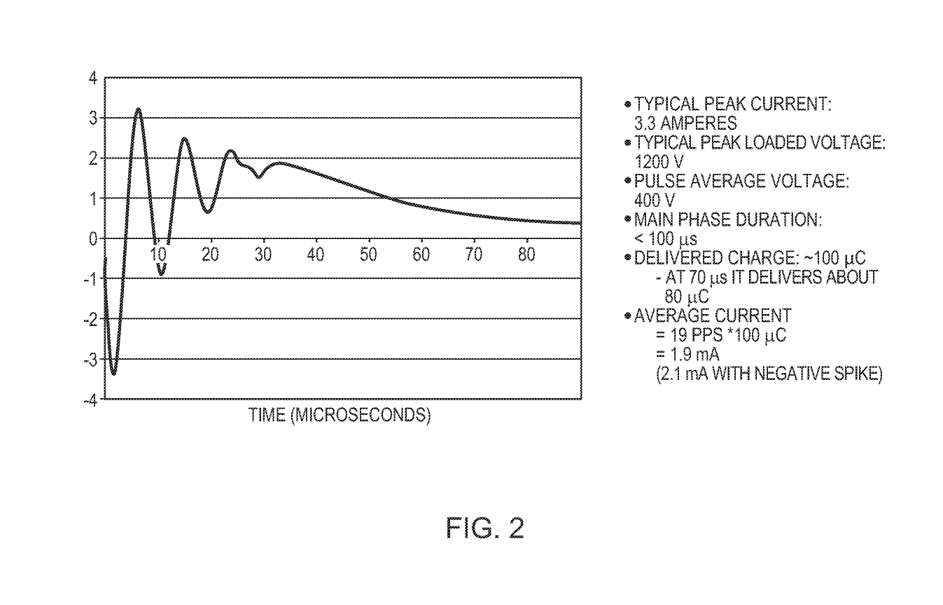

### DETAILED DESCRIPTION

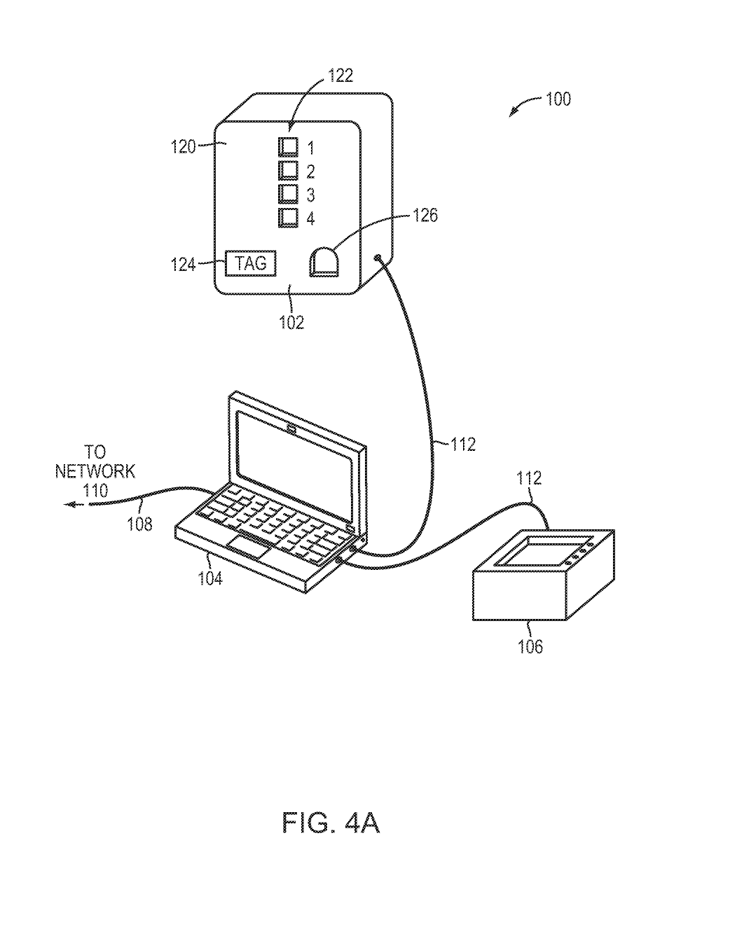

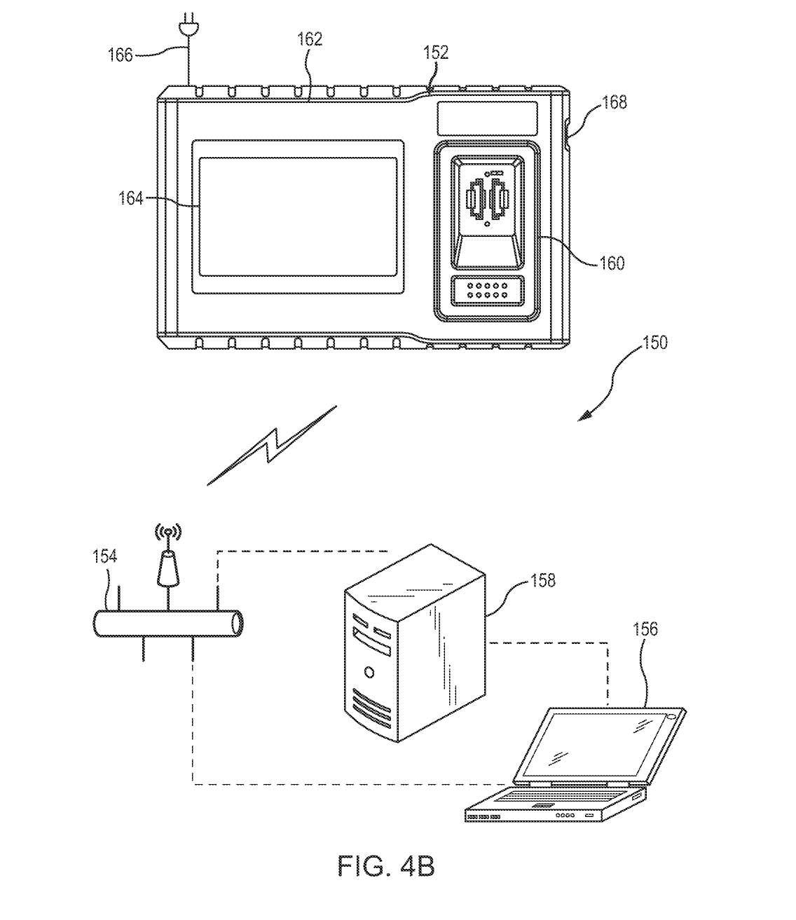

FIG. 4A depicts a schematic perspective view of a stun device testing and data storage system 100 in accordance with an embodiment of the technology. The system 100 may include a tester 102, a computer 104 of any type (desk top, hand-held, PDA, laptop, etc.), a printer 106, and, optionally, an ethernet or other connection 108 to an external network 110. The various components of the system 100 may be connected via cable connections 112 or a wireless connection (not shown) of any type. The depicted system is able to record and store captured data for analysis of waveforms. Such analysis may be supported by extensive libraries of waveforms and other analytical tools, such as single or multiple software programs for the specific purpose of analysis, as appropriate, to maintain, manage and/or verify outputs of stun devices. Moreover, reporting of data via secure data custody links can be integrated in state and federal databases for the effective tracking of device performance and safety compliance. These libraries may be maintained either within the tester 102, the computer 104, or in an external database, accessed via the network 110. The libraries of information may be accessed or updated on a regular or semi-regular basis by software utilized by the computer 104 or the tester 102. Additionally, the information obtained from the system 100 may be sent via the network 110 to an electronic information repository (e.g., the cloud) that stores, processes, analyzes, etc., information from any number of similar systems, thus quickly building a database of information to be used and accessed by all authorized users of the systems. Authorized researchers could also access the data repository to perform additional research and analysis.

In one embodiment of the technology, the data from each discharge may be stored in a first storage medium, remote from or local to the device. All other information (e.g., historical data from previously tested devices, known data from known stun devices or manufacturers, etc.) may be stored in a second storage medium. In this way, the information in the second medium may be updated on a regular or semi-regular basis (as described in further detail herein), while the information in the first medium serves as a record for all tests performed with the testing system. In certain embodiments, the first and second mediums may be a single medium for information storage. In certain embodiments, the data may be stored in a compressed format, for example, compressed to a factor of up to about 10:1. Other compression factors may be utilized.

In the system 100 depicted in FIG. 4A, the tester 102 includes a shallow housing 120 that may be mounted on a wall at shoulder height. Alternative embodiments may be configured for table-top usage, or may be dimensioned to be portable. Such portable devices may be maintained in a carrying case and may include power, communication or other cabling required to use the tester in remote locations. The front of the box presents four testing ports 122 (labeled 1, 2, 3 and 4) and two identification ports 124, 126. The operation and configurations of the testing ports 122 are described below. In some embodiments, described below, a single port may be utilized to perform the measurements described herein, with the stun device tester automatically adjusting the resistance values and/or spark gap configurations during a stun device testing procedure. A single port may be particularly desirable in certain embodiments because it reduces potential shock hazards. In other embodiments, two ports utilizing spark gaps and two ports without spark gaps may be used (adjusting the resistance values as required during a stun device testing procedure). Still other embodiments may utilize two low resistance ports and two high resistance ports (adjusting the spark gap as required during a stun device testing procedure).

In the tester 102 depicted in FIG. 4A, the four testing ports are utilized to determine a terminal model of the stun device under test. Both the voltage and current developed by a stun device may be used to determine the terminal model. Voltage V is fairly straightforward to measure directly. Current I is usually measured by observing the voltage developed across a known resistance R (or impedance), and derived using the formula I=V/R. Thus, to determine the current, R must be known. To determine the nature of the voltage source, total resistance needs to be known. The total actual resistance is the sum of the resistance of the source and the resistance of the load. The resistance of the load may be estimated by analysis or statistical measurement. In general, it has been determined that, for a stun device tester, a load resistance in the range of about 30 ohms to about 300 ohms is desirable. To predict the current developed by the stun device, the source resistance must also be determined. This can be done by measuring the voltage developed across two different, known load resistances. In one example, a first measurement is conducted with a 50 ohm load, which is associated with a first testing port 122 (port 1, for example) on the tester 102. A second measurement is conducted with a 100 ohm load, which is associated with a second testing port 122 (port 2, for example) on the tester 102. In the first measurement, 5000 volts is developed across 50 ohms; in the second measurement 6667 volts is developed across 100 ohms. The equations governing the two measurements may be simultaneously solved to determine that the source voltage is 10000 and the source resistance is 50 ohms. Thus, the two measurements (i.e., two experiments) yield two values that can be used to determine the source resistance.

The other two ports 122 (ports 3 and 4, for example) utilize a spark gap in series with the load resistance. Port 3, for example, utilizes a spark gap across 50 ohms; and port 4, for example, utilizes a spark gap across 100 ohms. Spark gaps generally have a very low resistance when conducting, accordingly, there is little appreciable increase in the load resistance. However, spark gaps may introduce transients in the stun device discharge that may affect the stimulus from the device in a potentially injurious way to a target. The behavior of spark gaps is dependent, in part, on the amount of current conducted by the spark gap. Accordingly, two of the ports repeat the measurements with two different load resistances, but also utilize the spark gaps to allow observation of their effect, if any. Spark gaps are present in certain stun devices.

The first identification port 124 may be utilized to read RFID tags on either or both of a stun device and a badge or other unique identification associated with a user. Alternatively, other readers (for example, bar code readers or other optical or tactile scanners) may be utilized. The second identification port 126 may also or alternatively be utilized to identify a user based on a biometric identifier, such as a user fingerprint. Other biometric systems (for example, voice detectors, retinal scanners, etc.) also may be utilized. A source of illumination may be associated with any or all of the elements and can be used to guide the user through the testing steps. The source of illumination may be a light bulb or light-emitting diode (LED) located within or proximate each port, for example.

The tester 102 can be used for purposes of registration and device characterization. In one embodiment of a test sequence, a user starts a stun device test by placing a finger in the fingerprint reader 126. The tester 102 responds by illuminating the fingerprint reader light. Additionally, the computer 104 may be activated to provide additional prompts to the user, or to record the testing sequence and results. Regardless, if the user is registered to use the system 100 and/or a stun device, the fingerprint reader light turns off and the light associated with the RFID reader 124 is illuminated. The user then positions the stun device by the reader 124. Successful reading of a registered stun device results in the illumination of testing port 1. The user places the stun device in testing port 1 and discharges the device. Successful reading results in turning off the light in testing port 1 and turning on the light in testing port 2. This process continues until the stun device has been successfully discharged at all four ports. The tester uses the associated computer 104 to archive the discharge data in the central repository (alternatively, the computer 104 may archive the data automatically, either at that time, or later) and, if desired, prints out a summary of the test results on an associated printer 106. The summary may include the measured average energy duration of each stimulus pulse, the number of pulses and total duration of the stimulus, an estimate of the battery condition based on the stun device's previous archived test results, changes observed within the current test, etc. Additionally, it may report the number and nature of observed variations from normal discharge. Advisory information including “Replace Battery” and “DO NOT USE” may also be included in the report. Additionally, the summary may include an image of the waveform, and/or other relevant characteristics thereof. The summary may also include an indication of whether the stun device is approved for subsequent use on a target, based on an analysis of the waveform or other discharge characteristic. The printed summary also may serve an important documentary function, creating a record of the operation of the device prior to use against a human target.

FIG. 4B depicts a schematic perspective view of a stun device testing system 150 in accordance with another embodiment of the technology. The system 150 includes a tester 152 that may communicate, via a wireless network 154, with a computer 156 and/or a remote storage database 158. Wireless communication helps reduce or eliminate the likelihood of undesirable electrical events being directed to, e.g., the computer 156, should an error occur at the tester 152 when receiving a discharge from a stun device. As described above, the tester 152 also may be a stand-alone device that performs all processes described herein. In the depicted embodiment, the tester 152 includes a single port 160 on a housing 162 for receipt of a discharge end of a stun device. The tester 152 also includes a user interface 164, in this case, a touch screen that displays a graphic user interface. A cord 166 connects the tester 152 to a source of power, such as a building power source, auxiliary vehicle power source, or other source. Alternatively or additionally, the tester 152 may include a switch 168 used to toggle power to the tester 1523. As described below, the tester 152 may be configured such that an unpowered tester 152 may still receive discharges safely, even when unplugged or powered off.

The computer 156 and/or remote storage database 158 may connect to the wireless network 154 so as to communicate with the tester 152. In other embodiments, the tester 152 may communicate directly with the computer 156 and/or remote storage database 158 via a Bluetooth, RFID, or other wireless or wired connection. In an alternative embodiment, the tester 152 may be controlled by the remote computer 156, which may display on-screen instructions typically displayed on the display 164 of the tester 152. The internal configuration of the tester 152 is described in further detail below. The tester 152 is utilized to test stun devices that have both a high discharge voltage and frequency, thus layout of the internal circuits, as well as automation of the testing processes helps ensure consistent results.

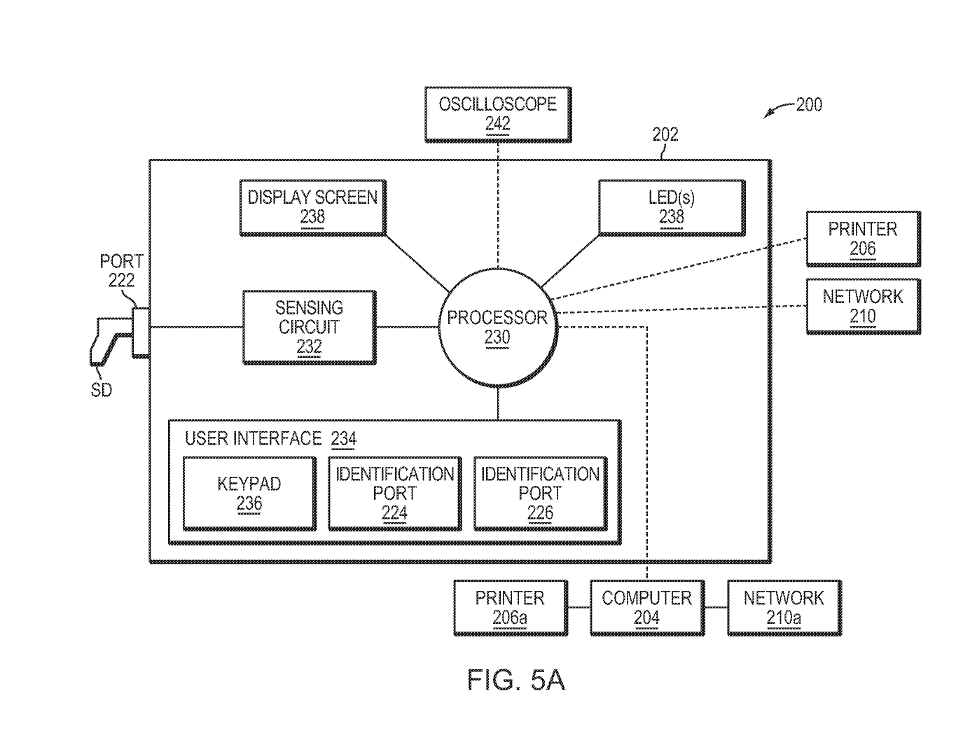

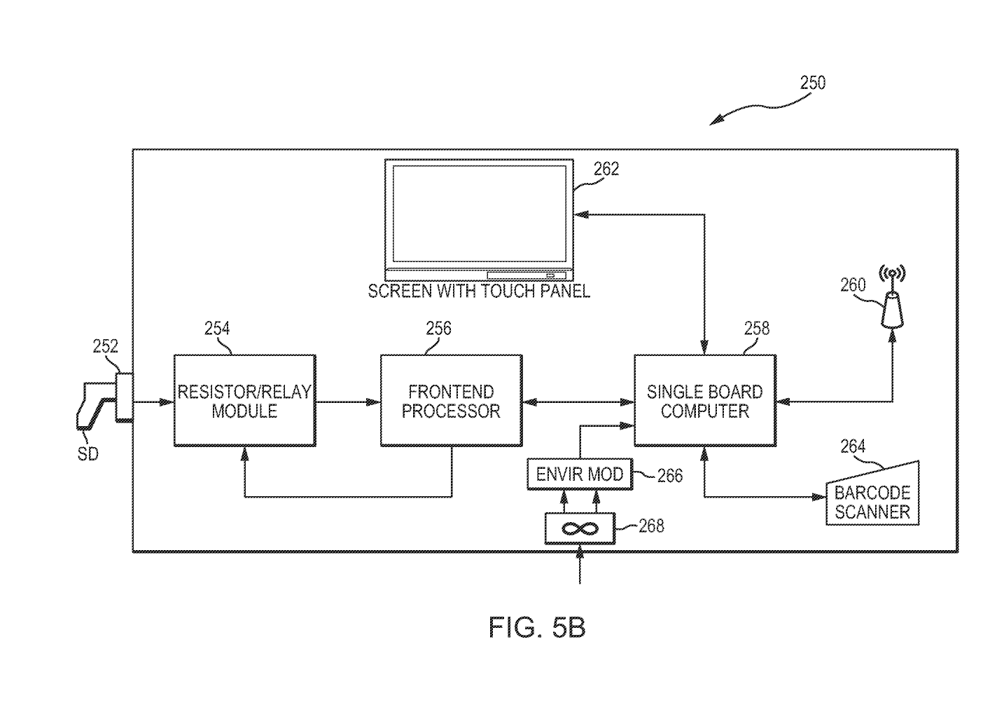

FIG. 5A is another embodiment of a stun device testing and data storage system 200. The system 200 includes a tester 202 having one or more testing ports or interfaces 222 for receiving a discharge end of a stun device SD. The tester 202 also includes a processor 230 for processing the data received from the stun device SD discharge, as well as for controlling the various elements of the tester 202, described below. The processor 230 receives information from a sensing circuit 232, which receives the discharge from the stun device SD. The processor 230 also communicates with the user interface 234, which may include one or more discrete components. One component may be a first identification port 224, as described above, i.e., a bar code scanner, RFID reader, etc. Other elements of the user interface 234 include a second identification port 226 (e.g., a fingerprint scanner, a voice recognition device, a retinal scanner, etc.). An alphanumeric keypad 236 (similar to those used on telephones) may also be utilized to enter identifying information about the stun device SD or user. In alternative embodiments, the keypad may be a complete keyboard typically utilized on a computer, either built into the tester or remote therefrom and connected by a cable. In other embodiments, a touch screen or voice recognition system having a graphical user interface may also be utilized.

The tester 202 provides information and feedback to a user via one or more integrated or remote components. For example, a display screen 238 may be utilized to present instructions, images of discharge waveforms, results, or other data to a user. In certain embodiments, the display screen 238 may be incorporated with the touch screen described above. One or more LEDs 240 may be used to provide simple instructions or feedback (e.g., “Proceed,” “Fail,” “Continue,” “In Spec,” “Out of Spec,” etc.), and a piezoelectric sounder or other sound generating device may also or alternatively be utilized. Additionally, output from the processor 230 may be delivered to a remote oscilloscope 242 or signal analyzer for further research, analysis, or testing purposes. The tester 202 may send certain results to a printer 206, which, in certain embodiments, may be integral with the tester 202. Such an integral printer may be similar to a register printer that prints to a ribbon of paper media. The tester 202 may be a stand-alone device or may be connected directly to a network or internet connection 210, as described above. A stand-alone computer 204 may also be connected to the tester 202 to collect, process, and/or store test data, or to provide diagnostic testing of the tester 202 itself. As described above with regard to FIG. 4A, the computer 204 may be connected to a stand-alone printer 206a, and/or a network 210a.

FIG. 5B depicts a schematic block diagram of a stun device testing system 250 in accordance with another embodiment of the technology. A stun device SD is inserted into a port 252 of the tester 250. The tester 250 includes a resistor/relay module 254. The resistor/relay module 254 is in communication with a processor 256. A single board computer 258 integrates the function of a wireless transmitter 260, a touch screen 262, as well as a barcode scanner 264. Additionally, the tester 250 may also include one or more environmental modules 266 (as described further below). In certain embodiments, it may be desirable for the environmental module 266 to be downstream of an air intake fan 268 to help ensure accurate readings.

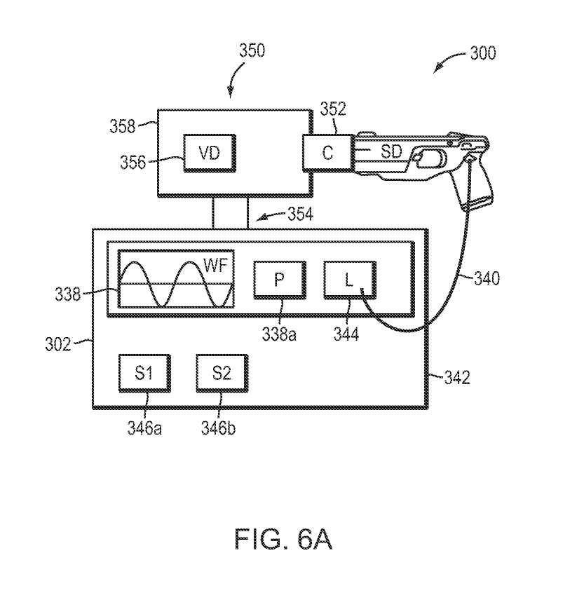

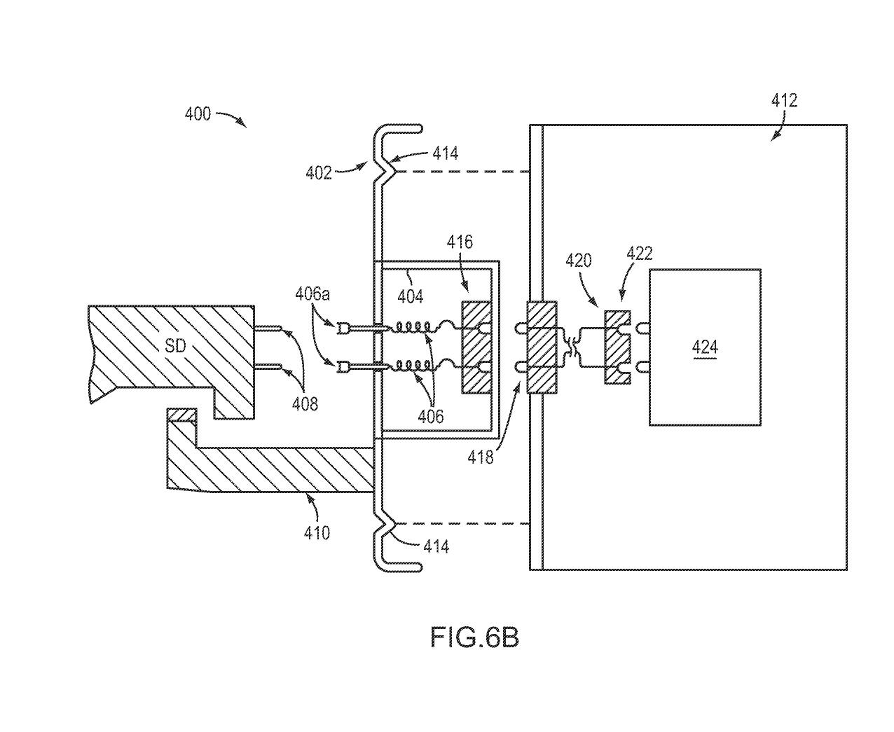

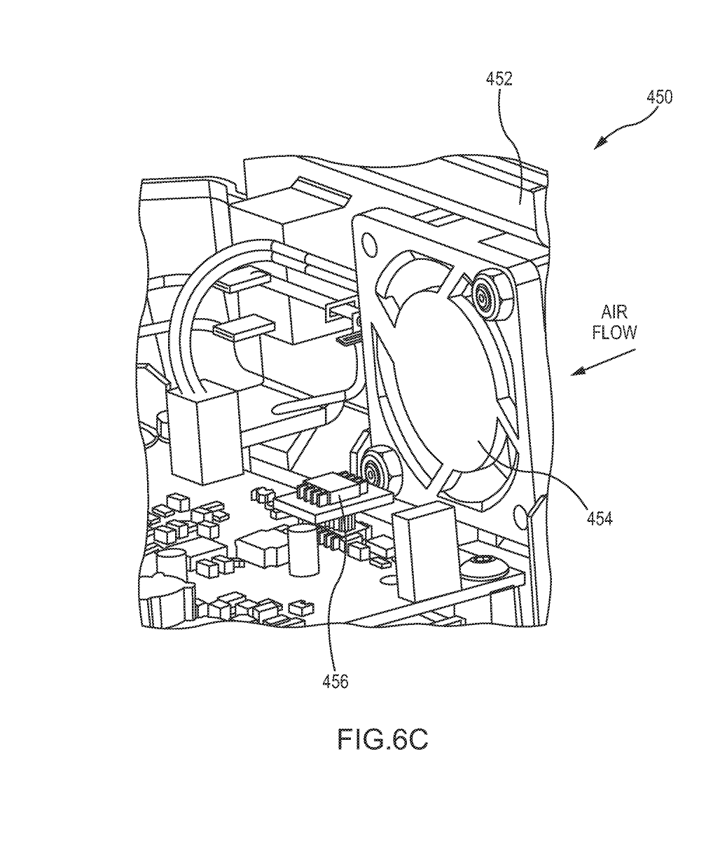

FIG. 6A depicts a schematic diagram of a stun device testing apparatus 300 in accordance with another embodiment of the technology. The testing apparatus 300 may include a stand-alone tester 302 that includes the circuits to test various stun devices SD. Additionally, the tester 302 may be connected to one or more adapters 350. Each adapter 350 may be manufactured to mate with the discharge end of a particular stun device SD via a coupling 352, and may include a common connector 354 configuration. The adapter 350 may include a voltage divider 356 within the adapter housing 358, as well as the stun device coupler 352. In certain embodiments, the voltage divider 356 may be utilized when the maximum voltage of a stun device is too high for the tester circuitry, and must be reduced to accommodate the measurement and prevent damage to the tester. While a voltage divider may not be required for several known devices on the market today, other devices exist or may be developed with specific characteristics that require modification for measurement on the safety tester. In certain embodiments, the voltage divider may be incorporated directly into the tester 302, as opposed to the adapter housing 358.

The coupler 352 connects the output leads of the device SD to the adapter 350. A coupler may be manufactured for each known stun device on the market or, alternatively, a universal coupler may be utilized to reduce costs associated with multiple custom couplers. Specifically configured couplers (or adapters, if the coupler is directly integrated into the adapter) may be required, because stun devices vary dramatically in form-factor. Some are large or small handgun formats, some are batons, and others are rectangular shapes. Some stun devices have protruding prongs and some utilize flat contact strips. Projectile-dart based stun devices should be measured with the dart accessory in place, as well as with the accessory disconnected, to verify output of the device when the external device contacts are pressed directly against the skin or penetrating the skin surface. In addition, the adapter 350 provides a high insulation factor to guard against electrical shock to the operator, since stun devices often have a high degree of arcing that can contact a nearby user during device actuation. Thus, an adapter/coupler combination is helpful to both secure a reliable connection to the tester 302 and to provide insulation to prevent electrical shock to users. The adapter or port may be liquid tolerant.

Specifically configured interfaces, ports, couplers, adapters may also include supports or other physical structure to ensure proper alignment between the stun device and the tester. An exemplary, removable interface 400 is depicted in FIG. 6B. The interface 400 includes a faceplate 402 secured to a receiving port or housing 404. Two compliant members or spring contacts 406 are secured within, and extend from, the receiving housing 404. Compliant members 406 (e.g., springs) help ensure contact between the contact tips 406a and the discharge elements 408 located on the stun device SD. The interface 400 may include a docking station or shelf 410 that provides reliable stun device SD placement and alignment. In certain embodiments, it may also enable the user to release the stun device SD during testing for safety purposes. The interface 400 may be secured to the tester 412 with screws, bolts, magnets, latches, spring clips, or other releasable coupling elements 414. Interfaces may be readily removable from the tester, allowing a number of interfaces adapted to receive specific stun devices to be used with a single tester, thereby reducing manufacturing costs.

The spring contacts 406 are connected to an interface connector 416 adapted to mate with a tester connector 418 located on the surface of the tester 412. The tester connector 418, in turn, may be wired to a PCB connector 422. The PCB connector 422 connects to a PCB 424 that performs the waveform testing and analysis. Utilizing a removable connection at the PCB enables an operator to remove the PCB 424 from the tester 412 for testing and servicing. Alternatively, a non-removable PCB may be utilized and the tester may be itself tested or updated via a USB port, a network connection, etc. The configuration depicted in FIG. 6B allows different types of stun devices to be tested on the same tester, but the tester of the present technology could also be manufactured with a dedicated built-in interface configured for a single type of stun device. Other types of interfaces are also contemplated to test stun devices and stun guns that deliver electric waveforms utilizing launched projectiles. Since launched projectiles typically utilize barbs to secure to a target, interfaces that utilize compliant or perforated materials that may be penetrated by barbs are contemplated. Such interfaces may utilize screens manufactured of conductive materials, conductive rubbers or plastics, etc.

Returning to FIG. 6A, the depicted testing apparatus 300 may include a display screen 338, that allows a user to view waveforms WF of the stun device SD discharge or other information. In certain embodiments, discharge periods for analysis can range from 1 to 45 seconds, simulating conditions of contact in the field during actual use. Such a signal capture feature P could be included along with other specific modes of signal capture and analysis for stun devices, and certain data regarding the discharge or the tester itself may be displayed for the operator on a second data display screen 338a. The displayed information may be used to aid an operator of the tester in making a determination regarding the operation of the stun device SD being tested, or regarding the operation of the tester 302 itself. In certain embodiments, however, the potentially subjective decision-making process of a human operator is bypassed in favor of a decision made by the tester 302 or an associated computer regarding the suitability of operation of a stun device SD. In such a case, one or both of the data display screens 338, 338a may be omitted from the tester 302 or reconfigured to display a status result (e.g., “OK to Use,” “DO NOT USE,” etc.).

Another feature that may be incorporated in the stun device testing apparatus 300 is the capability to measure current leakage and/or electrical breakdown from the stun device SD itself. An electrical cable/lead 340 extending from the tester housing 342 may be attached to the stun device SD to measure leakage by the apparatus 300. Information regarding the leakage may be displayed to a user via a leakage display 344 or one of the other display screens 338, 338a on the tester 302. Leakage or breakdown is dependent, in part, on the location and area of the contact providing the leakage or breakdown path, and is important to the operator of the tester 302, to prevent the operator from being incapacitated by the discharge during testing. Also, leakage can indicate a malfunction of the stun device SD. Again, not all information regarding leakage or breakdown need be presented to an operator. In such a case, the leakage display 344 may be omitted from the tester 302, and the tester 302 or the associated computer may make the necessary determinations regarding the safe operation of the stun device SD. In one embodiment, the type of leads utilized for EKG analysis of defibrillators and pacemakers may be employed to measure leakage. The apparatus 300 may also provide waveform analysis for a number of load conditions to simulate contact with differing parts of the body with differing intrinsic resistance and capacitance characteristics. Under such conditions, the internal circuitry of the stun device SD can behave in a consistent fashion to conserve the waveform for the purposes described previously.

The stun device testing apparatus 300 may also feature output from stun devices as compared against a variety of known and accepted electrical safety standards for electrical devices and for biomedical devices specifically. The apparatus 300 may incorporate one or more comparison outputs 346a, 346b, each offering a visual display or other representation of acceptable comparison and verification by the user. The testing apparatus 300 also may record individual waveforms and detailed time and date information of the tested device, and compare that information with standards based on the manufacturers' specifications, previously recorded discharge characteristics of the specific device, standards of other known devices, etc.

FIG. 6C depicts a partial perspective view of an interior portion of a housing 452 for a stun device testing apparatus 450 in accordance with one embodiment of the technology. Notably, the housing 452 includes an opening for receiving an airflow from the exterior of the housing 452. The airflow is drawn into the housing 452 by a fan 454. An environmental module 456, which may include at least one of a temperature sensor, a barometric pressure sensor, and a humidity sensor, or combinations thereof, is disposed downstream of the fan 454, such that the airflow is directed over the environmental module 456. In certain embodiments of the various testers described herein, it may be advantageous to detect and record ambient environmental conditions, which can have an effect on the testing protocols and/or test results. By locating the environmental module 456 downstream of the fan 454, the ambient temperature and humidity, for example, may be detected without the reading being detrimentally effected by heat and temperature variations due to components within the housing 452. The environmental module 456 is mounted on a header which spaces the environmental module 456 off the mainboard and into the airstream of the fan 454. This helps ensure that outside temperature, not inside temperature, is read.

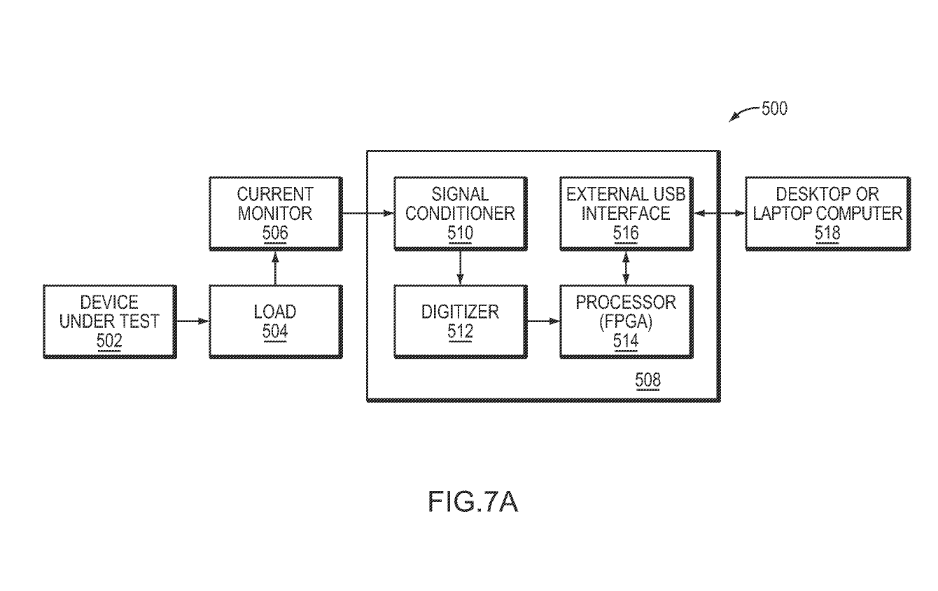

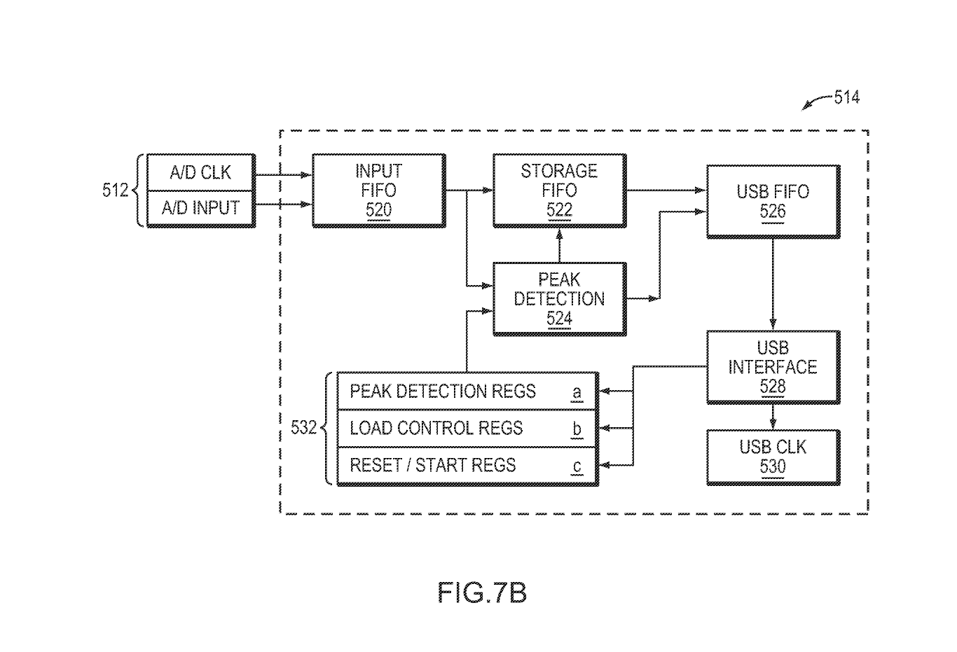

FIG. 7A is a schematic diagram of a hardware configuration of a stun device testing apparatus 500 in accordance with an embodiment of the technology. A device under test (DUT) 502 (i.e., an electric waveform delivery device) is connected to a load 504, which accomplishes at least two goals: 1) a well-known voltage and current waveform can be produced by the use of Ohm's law (Voltage=Current×Resistance), and 2) the high voltage signal level from the DUT 502 will be reduced to a level that is not damaging to the analysis circuitry contained within the testing apparatus 500. In one embodiment, a network of resistive devices may be utilized, e.g., the resistive values of an exemplary network may be 100, 250, 500 and 1000 ohm. Each different resistive value may be attached to a computer-controlled relay that may be either mechanical or electrical, depending on the anticipated energy level of the discharge impulse. The resistor and relay network is designed such that they are not mutually exclusive, thereby allowing a wide range of restive values with minimal impact on device size and cost.

The load 504 is connected to a current monitor 506, which outputs a voltage that is proportional to the current through the load 504. The voltage output of the current monitor 506 is then input to the printed circuit board (PCB) 508. The input signal is first conditioned 510 to match the input requirements of the digitizer (an analog to digital converter, A/D) 512. This conditioning includes several specific functions, including input filtering, digital attenuation, high-gain operational amplification (op-amp), and conversion operational amplification. Input filtering limits the noise bandwidth at the input to the A/D. Digital attenuation combines with the gain from the following stage (high gain operational amplification) to match the input signal level to the full-scale level of the A/D. In one embodiment, this attenuator has a range from about 1.0 dB to about 16 dB, which may be set via commands to a processor 514 or through the use of an on-board switch. The high-gain op-amp circuit is designed for a voltage gain of about ten. Coupled with the input attenuator, the output of this amplifier can be typically in a range of about 0-2V nominally. Finally, a single ended-to-differential conversion op-amp converts the signal into differential format and has an added level shift, since the original signal is DC-coupled.

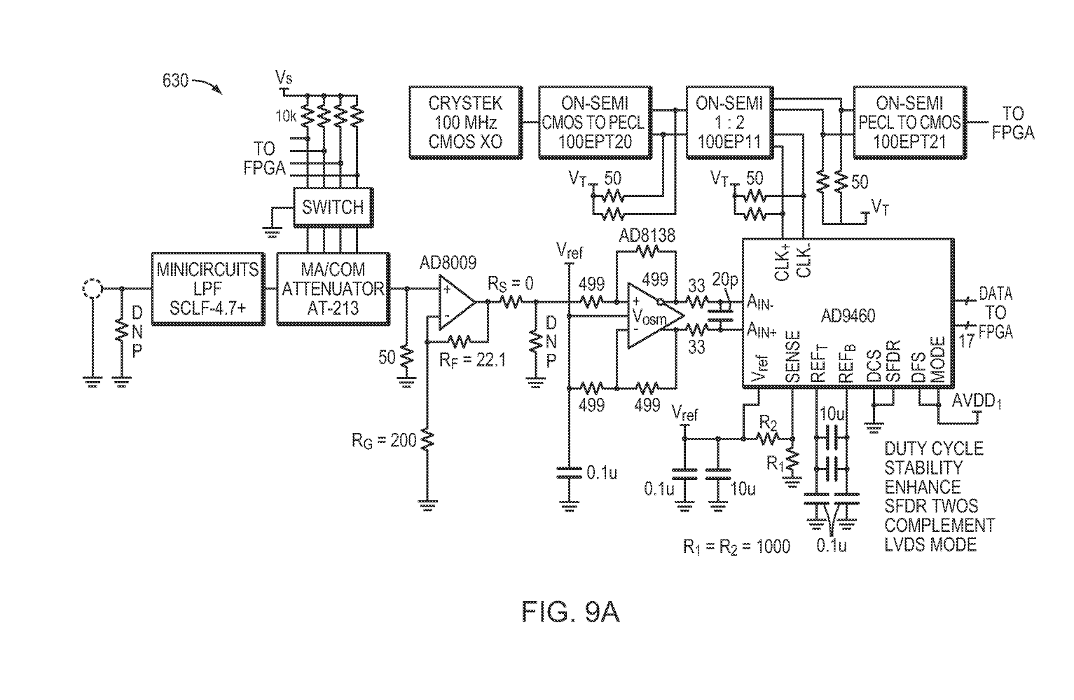

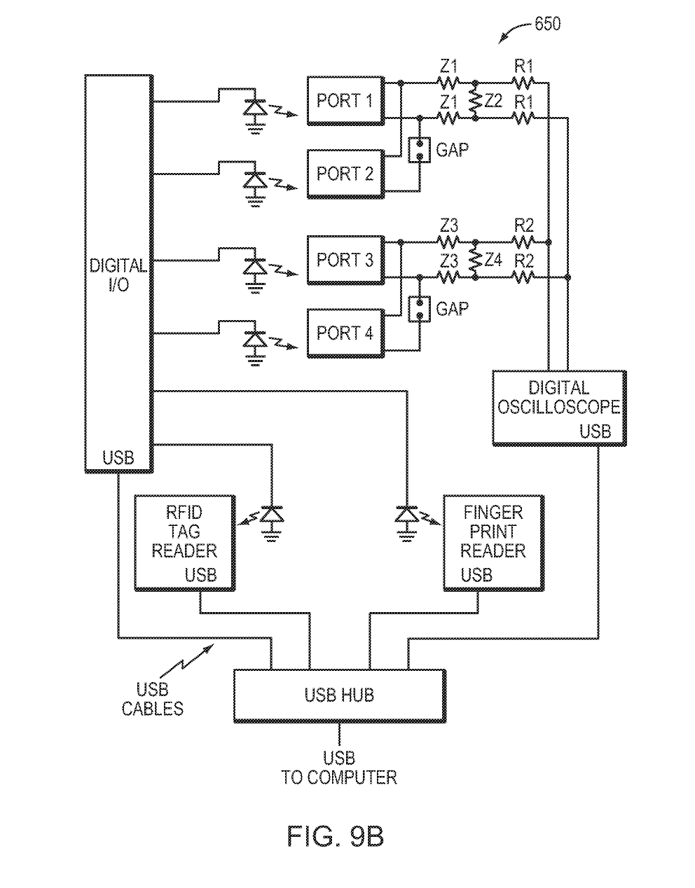

In one embodiment, the A/D 512 operates at 100 MS/s (million samples per second) with a resolution of 16 bits. This configuration provides the user with the ability to “see” the waveform in 10 nanosecond steps in time, with a total of 65,536 steps in discharge intensity. The output of the A/D 512 is passed directly to the processor 514 (which, in certain embodiments, may be a field programmable gate array (FPGA)), using low-voltage differential signaling (LVDS). FIG. 9A depicts one embodiment of a circuit 630 utilized in the hardware configuration of FIG. 7A for load 504, the current monitor 506, the signal conditioner 510, and the A/D 512.

Returning to the hardware embodiment depicted in FIG. 7A, the FPGA 514 may be manufactured by Xilinx, Inc. FPGAs allow for a wide range of data manipulation techniques while being field re-definable for future product upgrades, features, enhancement, etc. Use of an FPGA 514 provides the option of elimination of external computer control (provided sufficient processing capability is present) of the testing apparatus 500. In that case, the FPGA can perform all of the data analysis internally, handle user display functions, etc. If an external computer is utilized, however, the FPGA may be utilized only for ancillary functions, such as data handling and communications scheduling. VHDL code can be utilized to accept data from the A/D 512 continuously while being stored in an internal or external memory array. Additionally, the FPGA 514 can accept commands to stop/start a test, capture data, switch resistive loads, etc. The FPGA 514 also handles all USB 516 communications from the computer running the graphical user interface. In certain embodiments, the communications interface may be defined by the USB 2.0 standard, which is robust, familiar, and readily available in most consumer-based computing electronics.

FIG. 7B depicts an exemplary embodiment of a FPGA 514 utilized in certain embodiments of the technology. The A/D 512 delivers output to an input memory device 520 that, in the depicted embodiment, is a first in/first out (FIFO) memory to compensate for the differing clock speeds between the A/D clock and the USB clock 526, described below. Output from the input memory device 520 is delivered to both a storage device 522 as well as a peak detection device 524. The storage device 522 is also a FIFO and is described in more detail below, in conjunction with other related elements. The peak detection device 524 determines when the waveform discharged from the DUT 502 reaches a peak signal, initiating storage of the waveform information. This data is in turn output to the USB memory device 526, USB interface 528, and USB clock 530. In certain embodiments, the USB memory device 5256 may be a FIFO. The USB interface 528 changes the clock domain to the USB standard clock frequency, which is necessary to avoid loss of data for data sampled at high rates. For example, certain embodiments of the tester may sample data at 105 MHz, significantly faster than the USB clock.

Storage device 522 and USB memory device 526 provide memory space for storing data samples received from the A/D 512. In one embodiment, the storage of the incoming data samples is triggered when the peak detection circuit 524 detects a peak in the incoming waveform. Each sample may represent a fixed amount of capture time, for example, 10 nanoseconds (ns). Because the storage device 522 and USD memory device 526 contain a finite amount of storage space, the size of the storage device 522 and USD memory device 526 sets an upper limit on the total time a waveform may be captured. For example, if the storage device 522 and USD memory device 526 store 100 data samples, the total time is 100×10 ns=1 microsecond (μs). In one embodiment, the storage device 522 and USD memory device 526 store 64,000 samples, providing 640 μs of total data capture time. Also stored in the FPGA 514 are a number of registers 532 that control operation of the apparatus. These include peak detection registers 532a that control the capture of waveform data associated with the peak, and load control registers 532b that determine the testing load based, at least in part, on the type (i.e., manufacturer, model, etc.) of the DUT 502. Additionally, reset/start registers 532c control when data is taken, when the device is reset, when data capture stops, etc. In one embodiment, the FPGA 514 is able to be re-programmed via the USB interface 528.

The testing apparatus disclosed herein may be a stand-alone apparatus requiring no connection to a computer. In that case, the processor may run all the necessary analysis and present the required data/info via a screen or other components. In embodiments of the apparatus 500 that include an external computer 518, a LABVIEW™-based graphical user interface (GUI) may be utilized. LABVIEW software is available from National Instruments Corporation, of Austin, Tex. Other types of software that may be utilized include Mathematica and MatLab. The LABVIEW-based programming may be compiled as an .exe executable file, allowing operation on any Windows-based PC (or Intel-based Macs). If desired, the data displayed to the user may be a subset of the total data analyzed, such that the user is not confused by an overload of details or provided unnecessary information to perform his job. The apparatus may provide the option of delivering more information to the user for more advanced purposes.

During use, when the user selects the stun device to be tested, the program automatically switches to the correct load resistance for that stun device. The user may scan the stun device barcode or enter the stun device serial number, thus initiating a program to look up the appropriate load resistance, which may be stored locally or over a remote network. Raw data may be imported from the memory array into the program for analysis. While any waveform characteristics may be analyzed, capture and analysis of energy delivered, pulse duration, peak current, and frequency, are desirable for most stun devices. The resultant data may then be compared to known values for the particular device, and the testing apparatus may provide a pass/fail indication to the operator. The waveform and any desired data can be displayed on the user interface. LABVIEW supports saving data locally in a specified location and format, but it may also be desirable to upload the data to an internet database.

In various embodiments of the GUI, a drop down menu may be utilized for the operator to select which stun device is to be tested, or the stun device barcode may be scanned, as described above. The GUI also may utilize areas for data entry, such as serial number, customer name, test operator, etc. A pass or fail indication will illuminate after the data has been analyzed. The waveform may be displayed along with some calculated data such as frequency, peak current, etc., if desired. If available, the stun device manufacturer's expected waveform can be displayed next to the tested device waveform for a visual pass/fail confirmation. A data print out option may be available for printers connected to the computer 518.

As described above with regard to the embodiment of the tester 102 depicted in FIG. 4A, multiple ports are utilized on certain embodiments of the stun device tester. The multiple ports may be used to determine an electrical terminal model of the stun device. A terminal model is a conceptual embodiment of a mathematical equation that relates the voltage and current at a terminal pair or port of an electrical circuit. In general, a complex electrical network can be divided into a source and a destination connected by a pair of wires (otherwise known as a port). The source, destination, and even the wires themselves are conceptual. Connecting the source and destination ports constrains the voltage across the wires and the current through the wires to be equal. In mathematics, this is equivalent to solving two equations for two unknown quantities. Consider an example where the source is a stun device that can develop 10,000 volts and a target of approximately 50 ohms resistance. The current developed into the target determines the magnitude of the electric field within the target's body. Assuming the stun device has a very low source resistance, then the prediction might be 10,000 volts/50 ohms=200 amp current. If the assumption is that the resistance of the stun device is 1,000,000 ohms then the current is 10,000 volts/1,000,000 ohms=0.01 amps. Both are assumptions. Accordingly, it is desirable to know the current. Based on testing performed, observed currents in the range of 1 to 10 amps suggest source resistances of 1000 to 10,000 ohms. Determination of an electrical terminal model utilizing multiple ports of the exemplary tester depicted in FIG. 4A is described below.

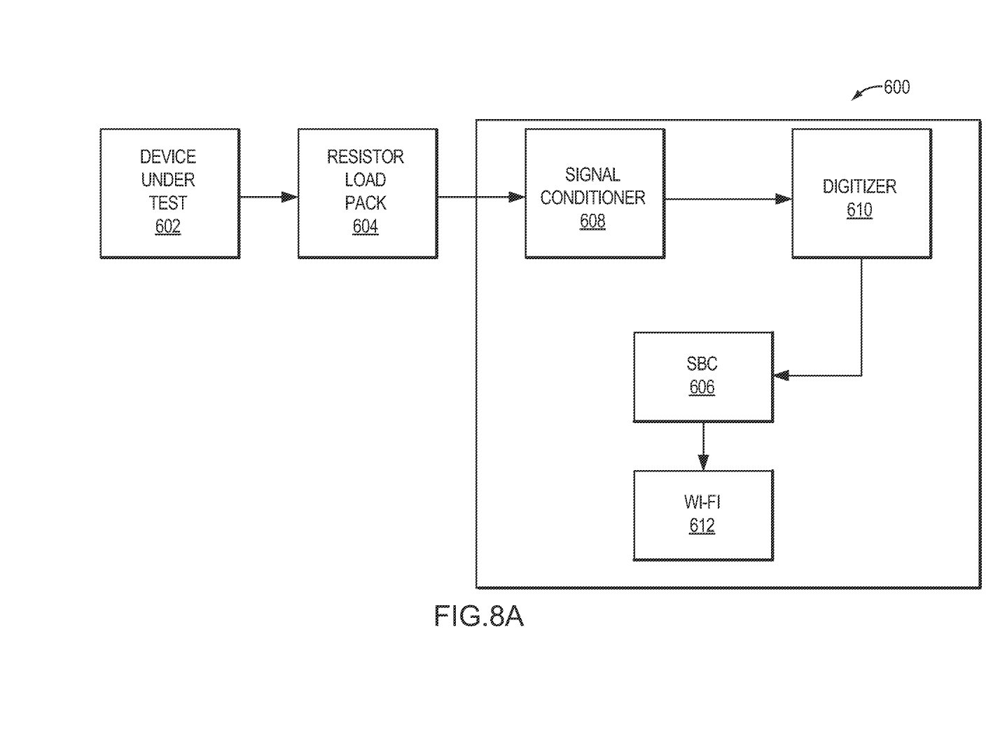

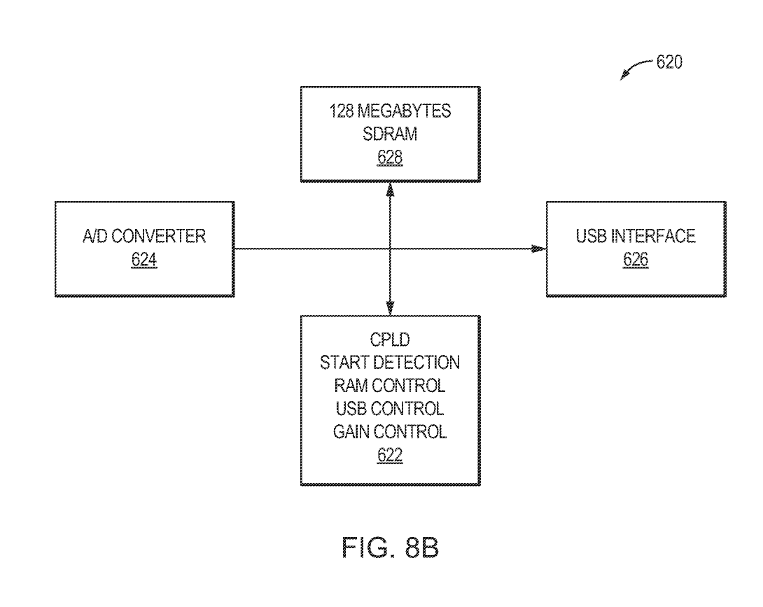

FIG. 8A is a schematic block diagram of a hardware configuration of a stun device testing apparatus 600 in accordance with another embodiment of the technology. A device under test 602 (e.g., a stun device) is connected to a resistor pack 604 through spring contacts as described herein. The spring contacts help ensure connection by engaging the device under test 602 prior to the device under test 602 being fully seated in a receptacle that receives the device under test 602. The resistor pack 604 presents a minimum load of 1000 ohms regardless of whether the tester 600 is powered or unpowered. Presentation of a minimum (or default) resistance load is a safety feature that prevents inadvertent damage to the tester 600 and/or injury to a user, should the device under test 602 be discharged into an unpowered unit. The load can be changed depending on the protocol being used to test the device under test 602, as controlled by the single board computer 606 (SBC). The output of the resistor pack 604 is a voltage reduction of about 100:1, but other voltage reductions may be utilized. The resistors located within the resistor load pack 604 are calibrated, which allows the tester 600 to calculate voltage and current discharged from the device under test 602 accurately.

A signal conditioner 608 is used to filter a discharge waveform as well as apply different gains depending on the device under test 602. The discharge-receiving circuit disposed in the signal conditioner may be high-voltage protected as an additional safety feature. A digitizer 610 samples and stores 64 million 12-bit samples. In one embodiment, the sampling rate is 10M/second. Thus, 6.4 seconds worth of data is collected. Other sampling rates may be utilized. In this embodiment, the SBC 606 is not utilized in any real-time data collection, thus reducing or eliminating the possibility of missing data due to software issues. The SBC 606 retrieves the data from the digitizer 610 and applies gain and offset corrections (which are programmed into the digitizer 610) prior to data analysis. The data analysis, as well as the raw data, may be compressed and/or stored on the SBC 606 until a data package is transmitted to a designated remote storage (for example, a computer, remote database, etc.). This data may be transmitted via a wireless module 612 or by a cabled connection. Once stored remotely, the raw data can be deleted from the tester 600 to conserve memory.

FIG. 8B depicts functions performed by the hardware configuration of FIG. 8A. A stun device testing apparatus 620 utilizes digital processing in the digitizer 610 that includes a complex programmable logic device 622 (CPLD). The CPLD 622 may perform one or more of the following functions. The CPLD 622 may control operation of the A/D converter 624, as well as signal conditioning circuitry gain from the signal conditioner 608. Additionally, the CPLD 622 may control operation of the resistor pack relays in the resistor load pack 604. If a USB chip is utilized, the CPLD 622 may control the interface 626 to the USB chip. Data flow between the A/D converter 624 and the SDRAM 628 may also be routed through and otherwise controlled by the CPLD 622. Data flow between the SDRAM 622 and the USB chip, via the USB interface 626, may be similarly routed and controlled. Additionally, the CPLD 622 may determine when data storage to the SDRAM 628 will begin, and the CPLD 622 may deliver a predefined test pattern to the SDRAM 628 to be used as built-in test equipment. In a particular embodiment, when initiated by the SBC 606 over the USB interface 626, the CPLD 622 monitors the incoming data from the A/D converter 624. When the data exceeds an absolute value as defined by the test protocol, the CPLD 622 then directs data to the SDRAM 628 until a full 6.4 seconds worth of data is captured. This data is then sent to the USB chip for use by the SBC 606.

FIG. 9B is a schematic diagram of a circuit 650 utilized in a stun device testing system in accordance with one embodiment of the technology. The depicted circuit 650 receives and processes waveforms delivered from a multi-port testing apparatus, such as that depicted in FIG. 4A, but components of the circuit 650 may also be used in other circuits and testing apparatus described herein. The testing procedures described below may also be utilized in various embodiments of the testing system described herein. Components include a LABJACK digital I/O, a Cleverscope C328A Digital Oscilloscope, an Avertec laptop computer, an HP Laserjet printer, a Zvetco finger print reader, a PhidgetUSA RFID reader, and a Belkin USB hub. All of these components are commercially available and communicate via a USB connection. Discrete electronics are limited primarily to driving LEDs and resistor-capacitor networks that match the signal received in the ports to the requirements of the digital oscilloscope. This latter requirement is further minimized by the digital oscilloscope's ability to detect and adjust itself to the presented signal. These components require no direct observation or contact by the user, although certain embodiments of the device may include options for such direct, contemporaneous observation. The digital oscilloscope operates as a data acquisition device which is observed and controlled by the connected personal computer. The LABJACK interface can generate control signals for the LEDs that guide the user during operation, as described above. The apparatus can also sense contact closures to allow simple signaling from the user, to sense proper positioning of the stun device in the ports, etc. Two modes of operation may be used, one high-speed sampling mode to capture spikes, transients and normal waveform, and a second to assess temporal patterns upon stimulus triggers of about 10 msec pulse, which is sampled and stored as a waveform. All data from a given test is then exported to a computer where detailed comparisons with stored and archival data can be made using appropriate software. Exemplary software can include statistical analysis software programs, such as SYSTAT™, manufactured by Systat Software, Inc., of Chicago, Ill. or MATLAB™, manufactured by The MathWorks, Inc., of Natick, Mass. Other component manufacturers may provide components utilized in the manufacture of the testing device. The above description does not limit similar configurations using different components.

Virtually any characteristics of the electric discharge may be measured, recorded, and analyzed by the device. While the most accurate testers may measure, record, and analyze a significant amount data regarding a waveform, more limited analysis of the waveform may be possible based on a smaller number of characteristics. In addition to capturing an image of the waveform, additional data regarding the discharge may also be collected. Certain embodiments of testing devices may test for one or more of an amplitude, a duration, a current, a voltage, an energy, or a temperature associated with the discharge. Additionally, other data may include: 1) joules per pulse, 2) total joules, 3) peak, average current for at least two different loads, 4) open-circuit voltage, 5) features of spark gap variability, etc. Waveform anomalies to be captured may include: 1) fast spikes, amplitude, rise-fall time, 2) differences in waveforms, rms, peak-to-peak, peak difference, 3) rate 5 to 60 pps, 4) variation in rate, 5) burst rate (patterned bursts), 6) duration of stimulus delivery, 7) measured battery voltage and predicted number of discharges based on battery voltage, 8) temperature of measurement log, etc.

The technology disclosed can be utilized in a variety to ways to verify a manufacturer's claim of specific waveform characteristics and as an indication of the safety of a given waveform. In the case where a manufacturer's claim of a specific waveform and linked safety or injury outcomes are defined, the disclosed technology can compare the waveform as measured against the manufacturer's reported waveform. A suitable comparison can be made in a variety of ways. In one embodiment, the tester can contain a software-based library of waveforms (as reported by the manufacturer) with established thresholds for uncertainty for the primary components of the waveform. For example, the peak current of a waveform is one diagnostic that should remain relatively constant across various loads. An uncertainty of, for example, about ±0.5 A can be established as representing an acceptable deviation from the standard, reported waveform. Higher deviations then can be flagged as outliers and signal can be delivered that the device under test may not be in specification as reported by the manufacturer. Similarly, waveform characteristics such as peak voltage, energy per pulse, cumulative current, energy, etc., can be characterized by “correct” values (i.e., conforming to manufacturer's specifications) and acceptable or unacceptable uncertainties (i.e., deviating from the specifications by an acceptable or unacceptable amount).

Additional features of stun devices, such as frequency, intensity, etc., can be combined creating classes of calculations that can also be measured, calculated, and defined by acceptable or unacceptable uncertainties. In the case of frequency, for example, deviations of approximately plus or minus 5 Hz, could be considered off of manufacturer's specification. When considering the intensity of a waveform, which in one embodiment may be defined as peak values for voltage or current and pulse duration, a similar comparison can be made referring to a reference waveform and deviations therefrom. In the foregoing cases, one example of comparing the manufacturer's stated or claimed waveform to that of a device under test can employ mathematical and statistical comparisons of data components versus load for both a reference and waveform for a specific device under test. Such comparisons can generate plots of each component versus load, for example (i.e., peak current versus load, peak voltage versus load, energy per pulse versus load, etc.). Some examples of waveform testing are described in Savard, P., Walter, R., and Dennis, A., “Analysis of the Quality and Safety of the Taser X26 devices tested for Radio-Canada/Canadian Broadcasting Corporation by National Technical Systems,” Test Report 41196-08.5RC (Dec. 2, 2008), the disclosure of which is hereby incorporated by reference herein in its entirety. In another embodiment, current root mean square (rms) values can be calculated and converted into appropriate units as defined by the “Effects of Current on Human Beings and Livestock,” IEC Publication 479-1, 3d ed., (1994); and “Effects of Current Passing Through the Human Body,” IEC Publication 479-2, 2d ed., (1987). These may then be compared to known rms values and pulse durations of other waveforms to establish safety thresholds for ventricular fibrillation. It is anticipated that, as new standards of safety for stun devices are developed, the disclosed tester can promptly employ such data and software to serve as a safety comparison with a device under test. Thus, the disclosed tester can offer a means to statistically compare a measured waveform with a claimed reference waveform and a means to determine the safety of a given waveform compared to established methods. In addition to comparing the waveform discharged by a device under test to a known manufacturer's standard waveform, the tester can also compare a waveform of a stun device of unknown origin to a database of known waveforms. This comparison can allow the tester to characterize a discharge waveform as potentially safe or unsafe by comparing its characteristics to those of other tested waveforms or manufacturer's standard waveforms that have been determined previously to be safe or unsafe.

### EXAMPLE

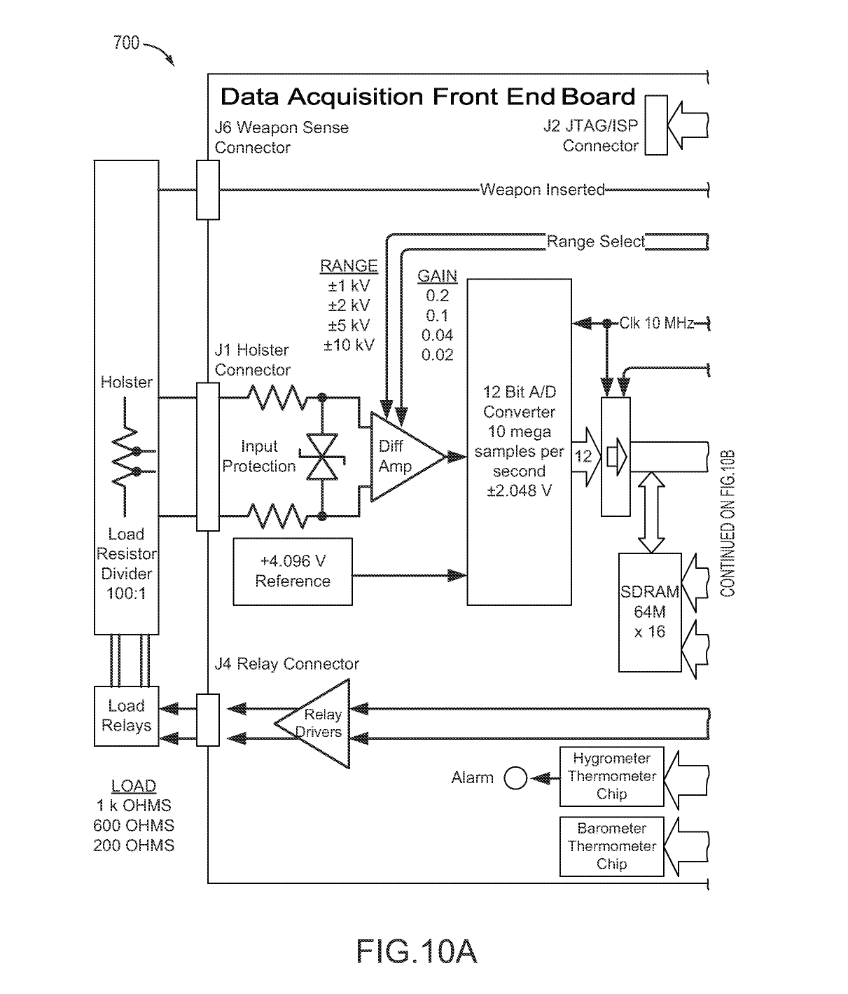

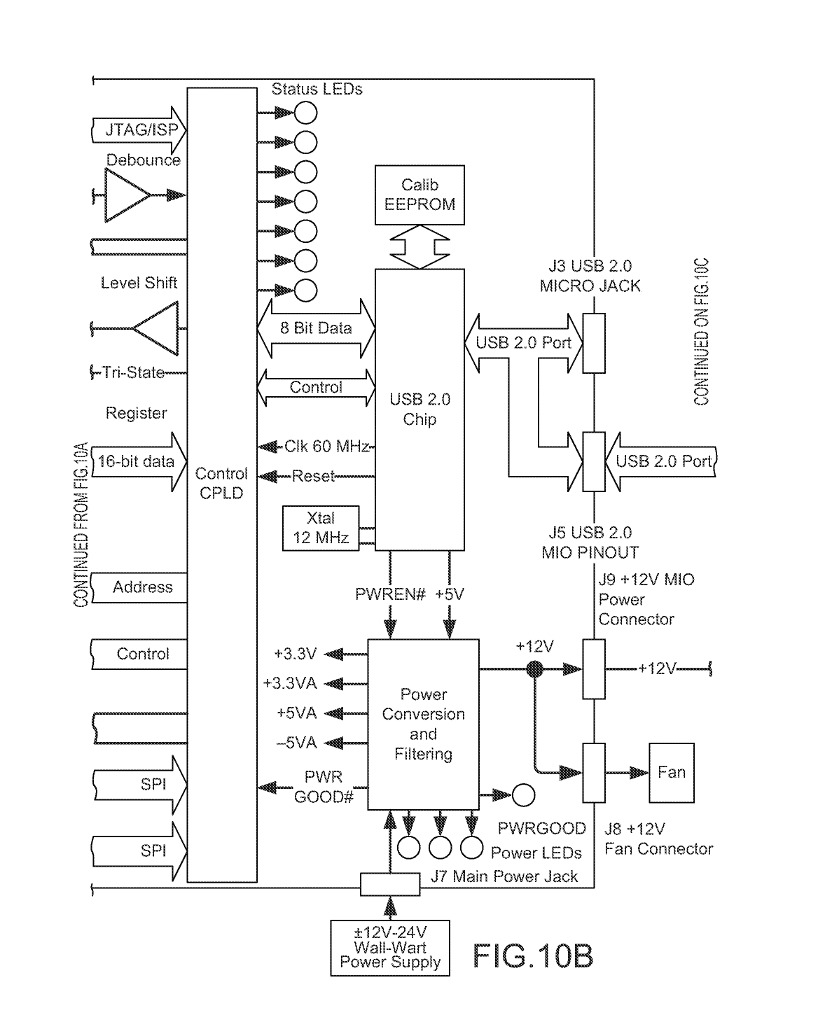

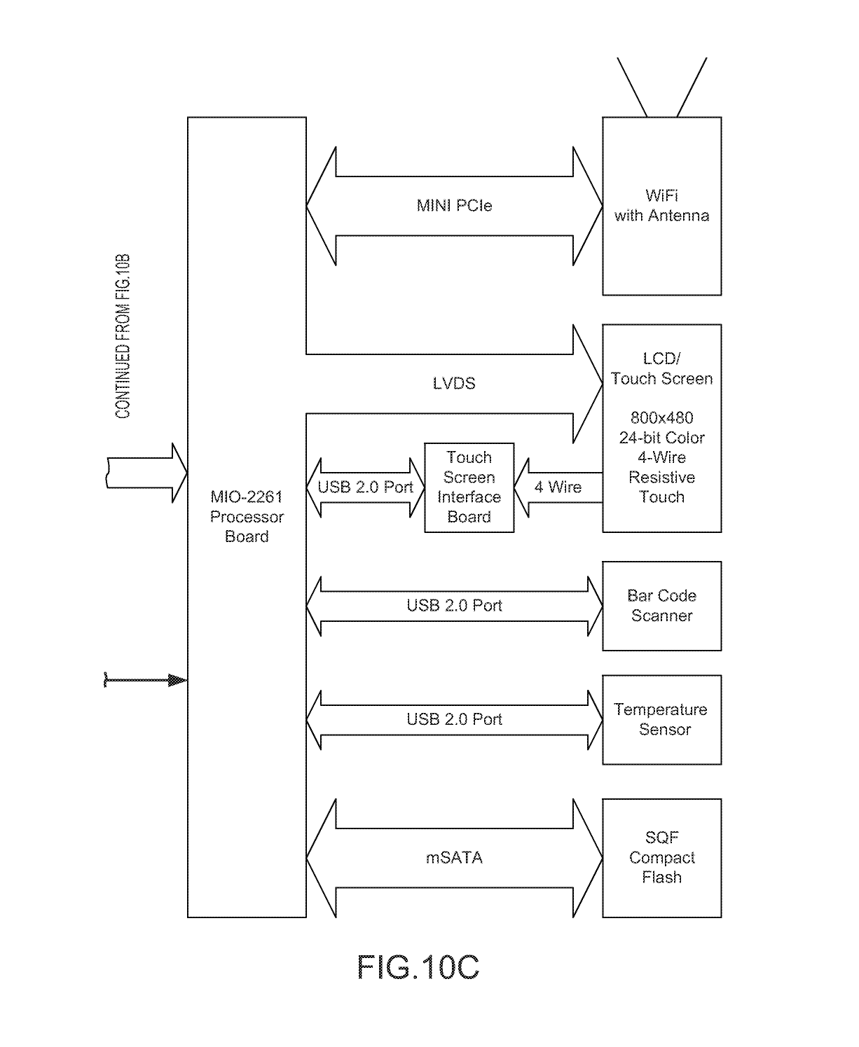

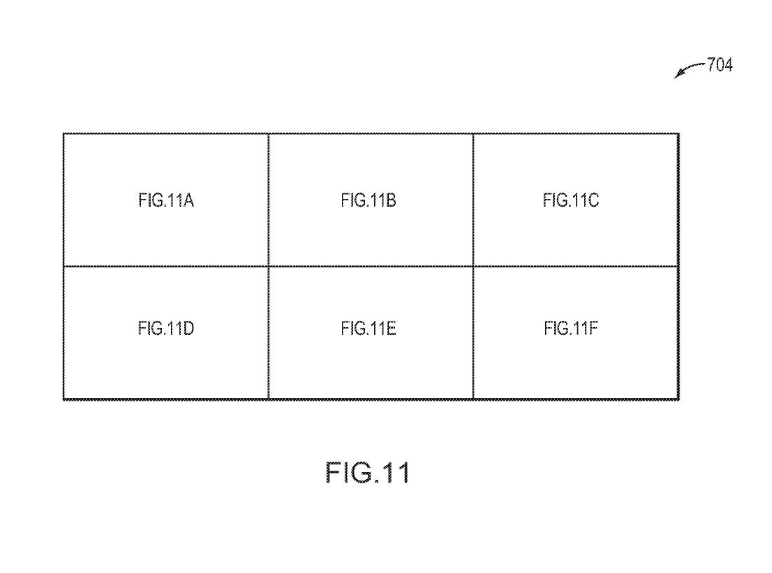

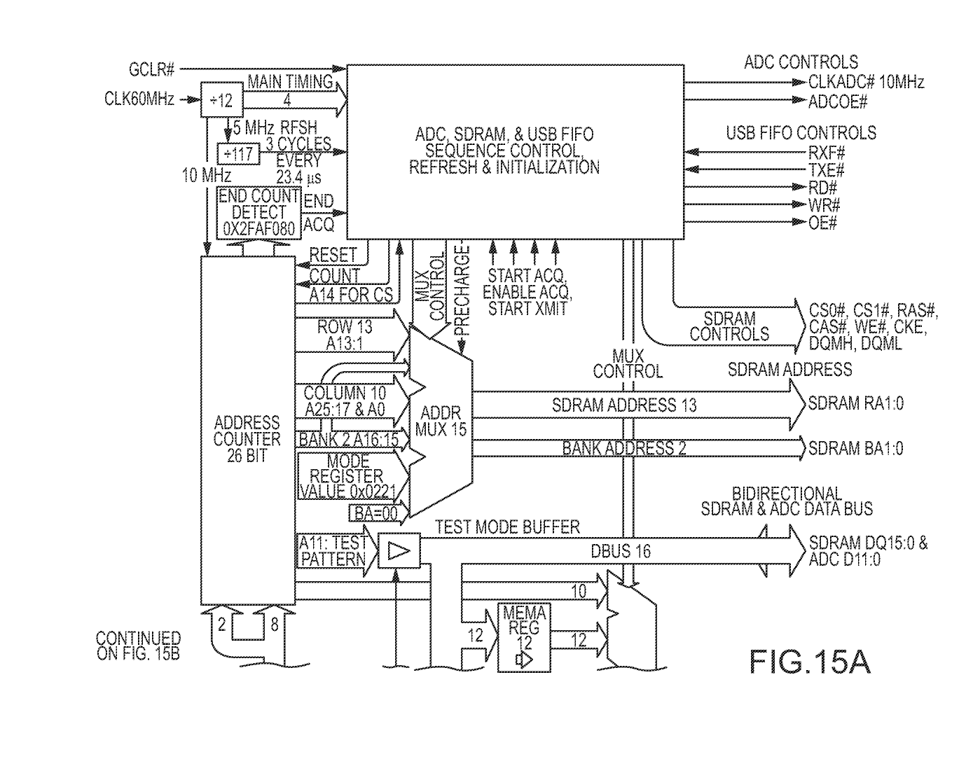

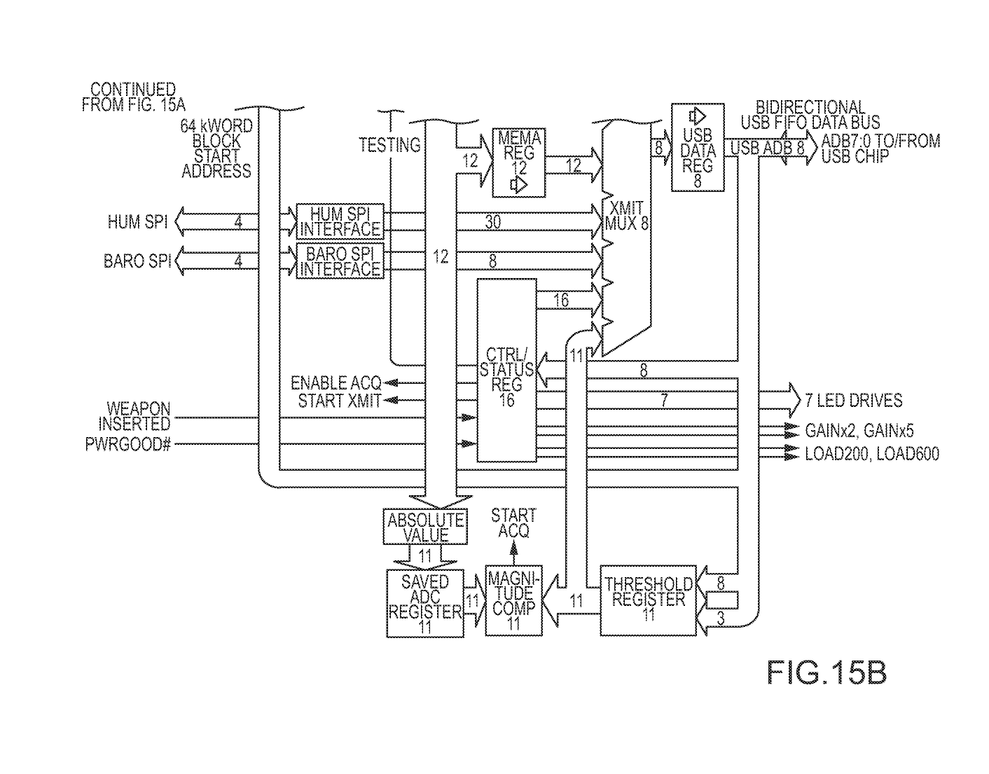

FIGS. 10-14, as well as FIGS. 15-17D, depict particular construction details of but one example embodiment of a stun device testing system. The figures and associated text are presented as an example only, as other configurations are also contemplated.

FIG. 10 is a block diagram of a hardware configuration of a stun device testing apparatus 700 in accordance with another embodiment of the technology. The front end board is a printed-circuit assembly that performs the analog data acquisition and control functions for the tester. This board contains a high speed analog-to-digital converter (ADC) configured to measure high voltage pulse waveforms, memory chips to store the acquired waveforms, a complex programmable logic device (CPLD) to manage conversion and transmission of the results to an external processor, environmental sensors, power converters, and a USB 2.0 (Universal Serial Bus) interface chip. The board is used with commercial off-the-shelf (COTS) assemblies to create the hardware for the tester 700: processor board (Advantech MIO-2261), WiFi board and antenna, touch-screen liquid-crystal display unit, touch-screen interface board, bar code scanner, and SQF compact Flash storage.

FIG. 10 also depicts a table of power consumption by supply voltage and schematic page and a full-board parts list, in addition to the tester system block diagram 700. The tester system 700 includes an interchangeable test fixture (“holster”) that accepts a variety of electro-shock weapons. The weapon is inserted into the holster and triggered by the user based on prompts from the display. The high-voltage pulse signal is terminated in a relay-selectable 3-value load resistor network on the holster, and conditioned by a four-range fractional-gain amplifier with high-voltage protection to create an analog signal in the ±2-volt range. This is fed to a 12-bit 10 mega-samples-per-second (MSPS) ADC to generate a bipolar digital representation of the measured voltage every 100 nanoseconds. The ADC operates continuously on the signal from the test fixture. On command from a control register, when the ADC output indicates that the weapon is firing, 6.4 seconds of samples (64,000,000 samples) are stored in a pair of memory chips (Synchronous Dynamic Random-Access Memory, SDRAM). At the end of the acquisition period, the processor board reads the data in 32 k word blocks via a high-speed USB 2.0 link for further processing. A CPLD manages the memory timing, the acquisition of the block of data, and the transmission of the blocks to the processor.

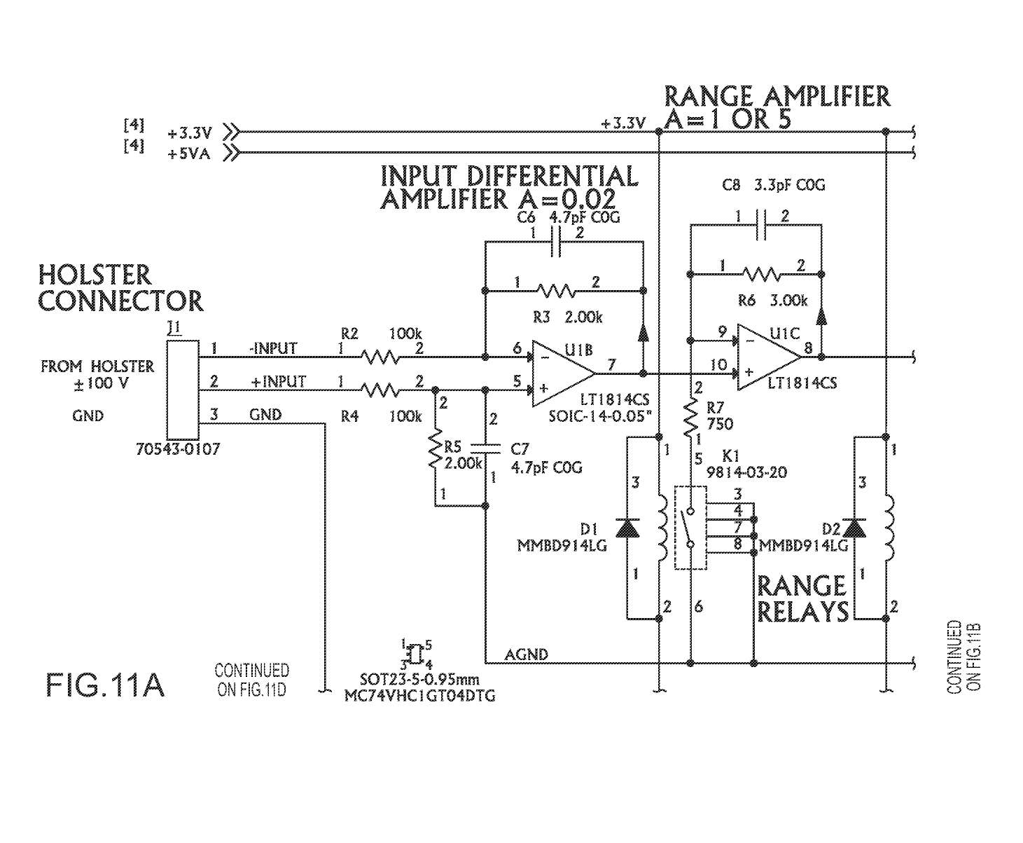

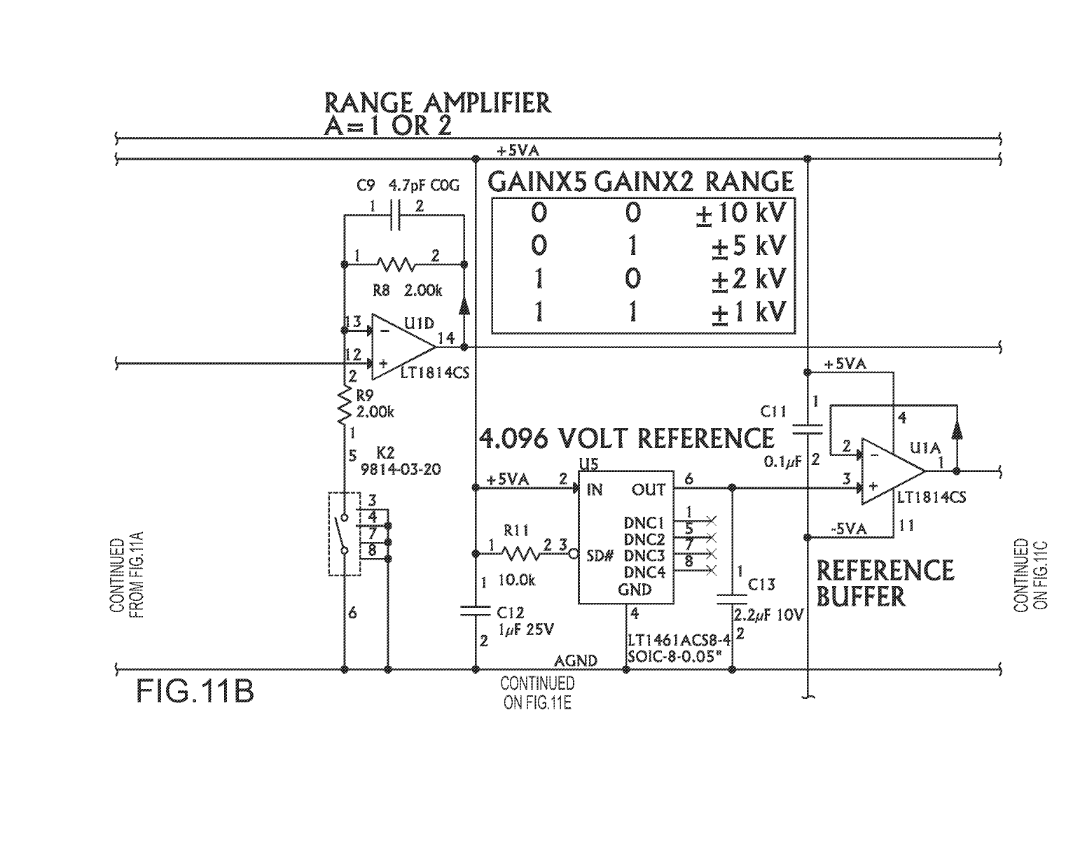

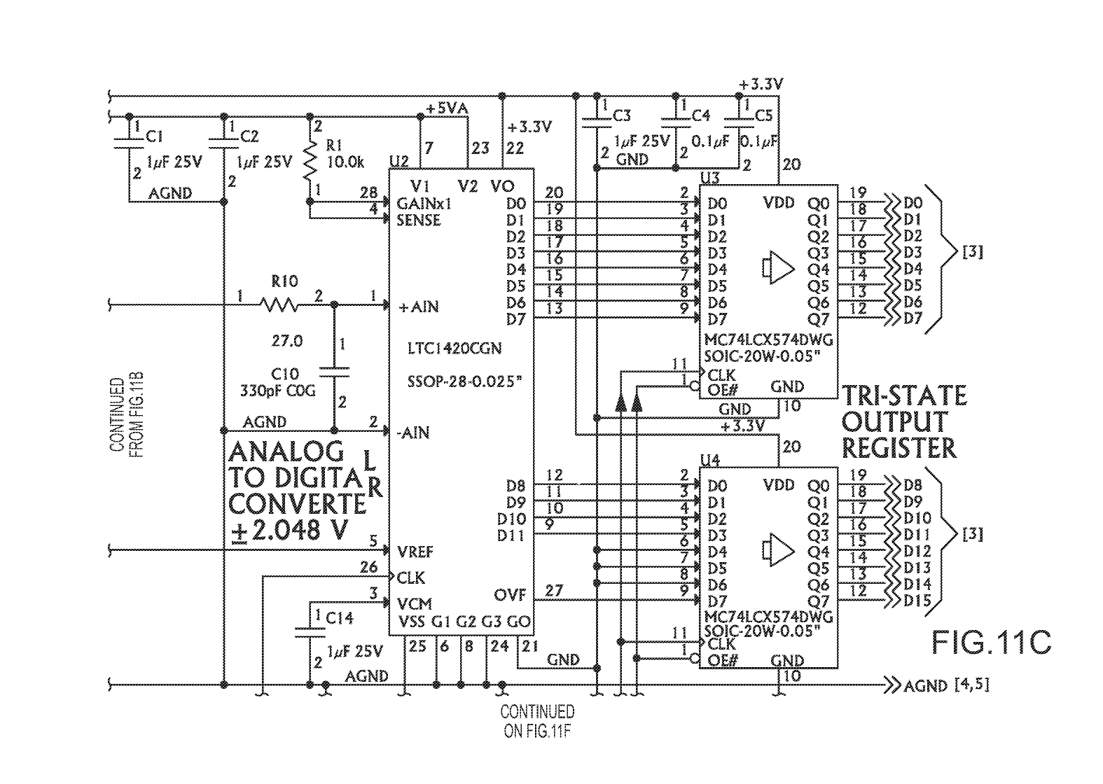

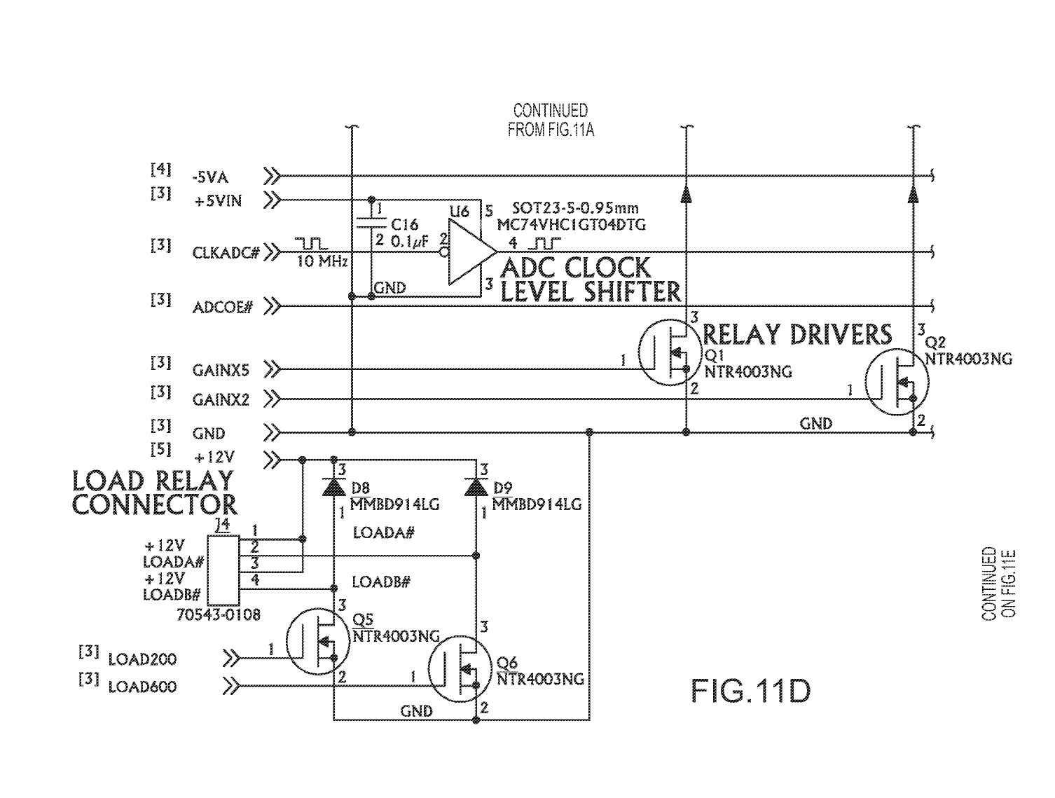

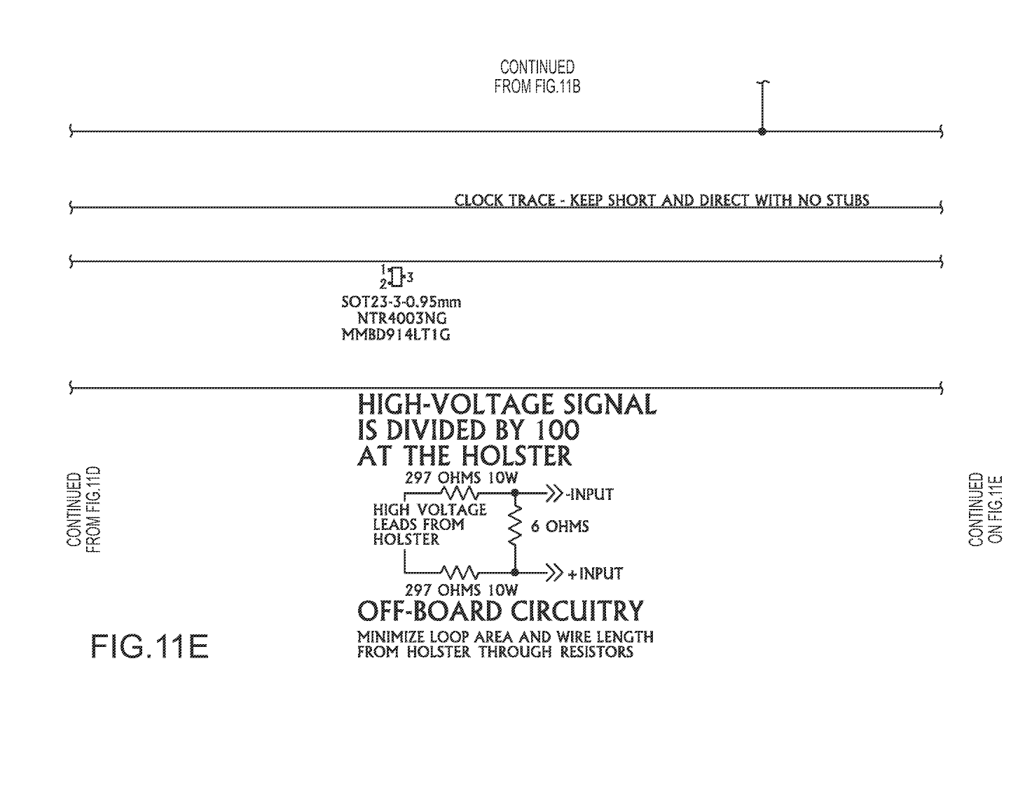

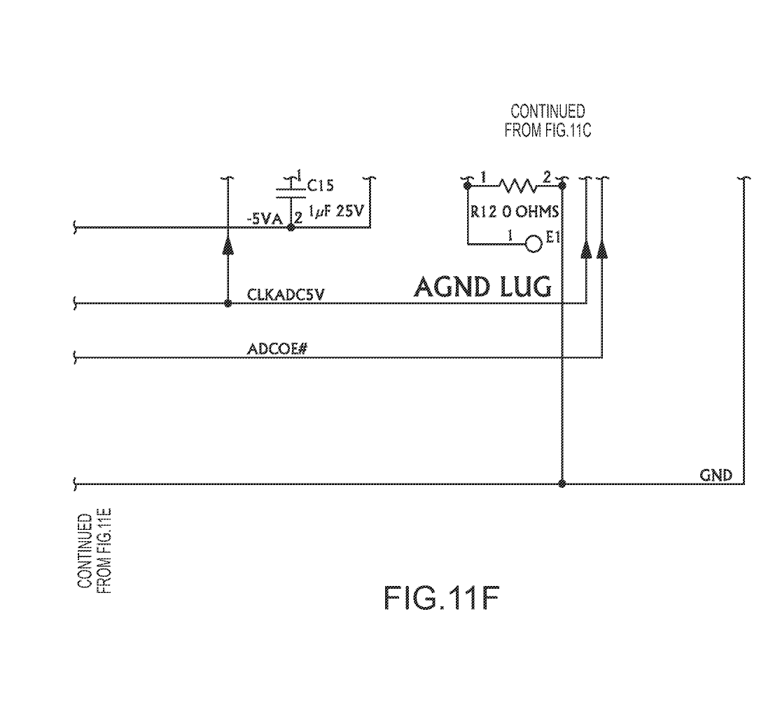

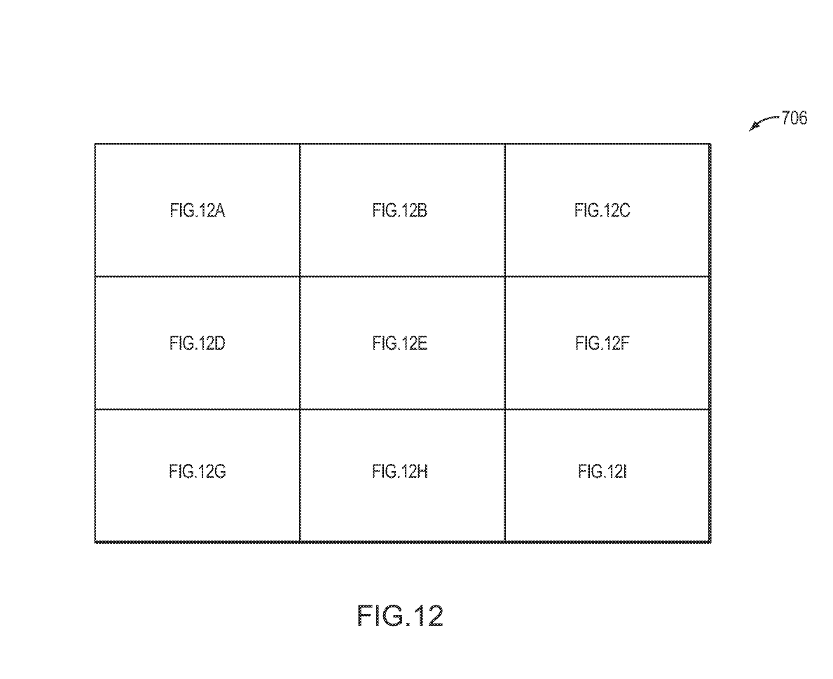

A pair of environmental sensor chips (also referred to herein as environmental modules) measure ambient temperature, humidity, and barometric pressure. The results are transmitted to the CPLD by SPI (Serial Peripheral Interface), and are made available in USB-readable CPLD registers. Power to the unit is routed through a filter/rectifier network and a buck-boost power converter, so any input voltage between 12 and 24 volts of either polarity can be used without damage or interruption. This supplies regulated 12 volt power to the MIO-2261 Processor Board. Once powered-up, the MIO in turn supplies the +5 volt power demand of this board via the USB port. Other power conversion and filtering stages on this board convert USB +5 volt power to digital +3.3 volt power for the CPLD and quiet bipolar 5 volt analog supplies for the ADC. Also in the tester system 700 are a precision reference voltage for the ADC, a small electrically-erasable programmable read-only memory (EEPROM) to configure the USB interface and store software calibration constants, a 12 megahertz (MHz) crystal oscillator for the USB chip that produces a 60 MHz system clock, a Joint Test Action Group (JTAG) test port for in-system programming (ISP) and testing of the CPLD, and a set of diagnostic light-emitting diodes (LEDs). The components depicted in FIG. 10 are described further in FIGS. 11-14, below.

FIG. 11 is a schematic diagram of a front end circuit 704 utilized in the hardware configuration of the tester 700 of FIG. 10. FIG. 11 depicts the circuitry to scale the input signal, the ADC and its reference, and a set of digital output registers to present the digitized signal to the CPLD.

High Voltage Divider. A high-voltage tolerant non-inductive resistor network at the holster terminates the high-voltage signal to simulate the load of a human subject. The value of the load resistor is selectable using a pair of relays. With both relays open, the load resistance is 1 k ohm. With the LOAD600 relay closed, the load resistance is 600 ohms. With the LOAD200 relay closed, the load resistance is 200 ohms. The resistor network divides down the high-voltage signal by a factor of 100 to a maximum of ±100 volts so it can be handled on the front-end board.

Protected Differential Input Amplifier. The leads from the holster attach to connector J1 at the high-voltage end of the circuit board. The divided voltage is fed through resistors R2 and R4 to a differential amplifier made from a high-speed operational amplifier (opamp) U1B, where feedback action keeps the opamp input terminals close together and within ±2 volts of ground. This keeps the high voltages out of the remainder of the circuit. In the event of an out-of-range voltage input, back-to-back diodes within the opamp combined with the high (100 k ohm) resistance of the resistor chain work to clamp the voltage spike and prevent it from damaging any of the semiconductor circuitry. U1B is arranged as a differential amplifier with a fractional gain of 0.02 ( 1/50) to the incoming analog signal. In combination with the 100:1 division at the holster termination network, this gives a total gain of 0.0002 ( 1/5000) to the input stage. Capacitors C6 and C7 limit the frequency response of the amplifier to 17 MHz to limit noise and prevent oscillation. For the maximum input range of ±10 kilovolts, U1B output is in the ±2 volt range.

Range Selection Amplifiers and Relays. This signal is fed to a pair of non-inverting amplifiers U1C and U1D with a combined precision gain of 1, 2, 5, or 10. Gain is selectable with two long-life reed relays, driven by Q1 and Q2 with signals from the CPLD. When the relay is closed, the stage is a noninverting amplifier with gain determined by the resistors. When the relay is open, the stage becomes a unity-gain follower. When the input range is ±1 kilovolt, the output of U1B is ±200 millivolts. Both relays are closed, so U1C has a gain of 5 and U1D has a gain of 2 to boost the signal to ±2 volts. When the input range is ±2 kilovolts, the output of U1B is ±400 millivolts. K1 is closed so U1C still has a gain of 5, while K2 is open so U1D now has a gain of 1, and the signal is boosted to ±2 volts. When the input range is ±5 kilovolts, the output of U1B is ±1 volt. K1 is open so U1C now has a gain of 1, while K2 is closed so U1D still has a gain of 2, and the signal is boosted to ±2 volts. When the input range is ±10 kilovolts, both relays are open so the gain amplifiers have a combined gain of 1, and the signal remains at ±2 volts. At power-up, both relays are open to select the lowest gain and highest range. So the output of U1D is in the ±2-volt range regardless of the input range. All stages are noninverting, so the output signal has the same phase as the high-voltage input. Since the actual input range of the ADC is ±2.048 volts, there is a 2.4% headroom to allow software to calibrate out accumulated errors. If the wrong range is selected, the output voltage of U1D either will be too low, or will clamp at the power supply rails. So the reading will be wrong but no damage will be done. The output of U1D is fed into a simple 18 MHz filter consisting of R10 and C10 to suppress high-frequency noise.

Analog to Digital Converter. U2 is the ADC, an LTC1420C from Linear Technology. This chip is designed to convert at a maximum rate of 10 MSPS. It is clocked at 10 MHz and does a conversion on every clock pulse. The conversion is pipelined so that the value presented at the digital outputs is 3 clocks behind the analog input value, but this is of no consequence since the converter operates continuously. The output of the ADC is a 12-bit two's complement binary number, with an additional overflow bit to indicate if the input signal is out of range, meaning that the output value is unreliable.

Output Registers. The output word is fed to a pair of 74LCX574 tri-state registers. The output word is registered using the same 5-volt clock as the ADC. The register outputs are presented to the CPLD and SDRAM. A test mode (described later) uses a signal from the CPLD to tri-state disable the outputs of the registers, so the CPLD can substitute a predictable test count pattern for storage into the SDRAM. This allows for easier debugging.

Analog Grounding. The ADC and opamps operate from ±5 volt analog supplies, filtered to keep supply noise low. A separate analog ground (AGND) is used to prevent digital switching currents from circulating in the ground plane and causing errors in the reading. This AGND is connected to the digital ground at only one point, zero-ohm resistor R12. The PC board ground and power planes are split between digital GND and AGND to prevent capacitive interaction and noise transfer between analog and digital signals and supplies.

Voltage Reference. Although the ADC contains a stable internal reference voltage circuit, its absolute accuracy can be improved by providing an external precision reference voltage source (U5). U5 is an LT1461AC-4 from Linear Technology; its 4.096-volt output is pre-trimmed to ±0.04% absolute accuracy. This is buffered by U1A with a gain of +1 and fed into the ADC's reference voltage input. The buffer amplifier helps isolate the reference from the low (1 k ohm) input impedance of the ADC, and from any switching currents present at the ADC input. The ADC is arranged so that the output code represents 1 millivolt per count, from −2.048 volts to +2.047 volts.

Calibration. Even though U4 is very accurate, there are accumulated error sources throughout the circuit (such as resistor tolerances and ADC inaccuracies) that can add up to produce significant errors in both the full-scale (range) reading, and the zero-volts-in (offset) reading. So calibration runs are used to determine appropriate software calibration factors for each range, which are then stored in the EEPROM. To calibrate the circuit, the highest range is selected. The high-voltage input terminals are connected together and the software offset value for a zero reading is adjusted. Then a precision +100 volt reference is connected across the high-voltage input terminals, and the software range value is adjusted for a reading of +2.000 volts (0x7D0). This procedure is repeated with the other three ranges using the appropriate input voltages of +50, +20, and +10 volts.

ADC Clock. A 3.3-volt 10-MHz inverted clock from the CPLD is generated with the proper phase so that the register output word appears with adequate timing margin to be captured by the SDRAMs and CPLD. This 3.3-volt clock is inverted and amplified to 5 volts by U6, a 74VHC1GT04 level-shifter gate, and fed to the ADC and output registers. The ADC uses a 5V-level clock when running from bipolar supplies. The 74LCX574 registers are guaranteed to be 5 volt tolerant at the inputs, allowing for use of the same clock to recover the data as the ADC uses to produce it. This eliminates timing delays and allows the ADC to run at its maximum speed.

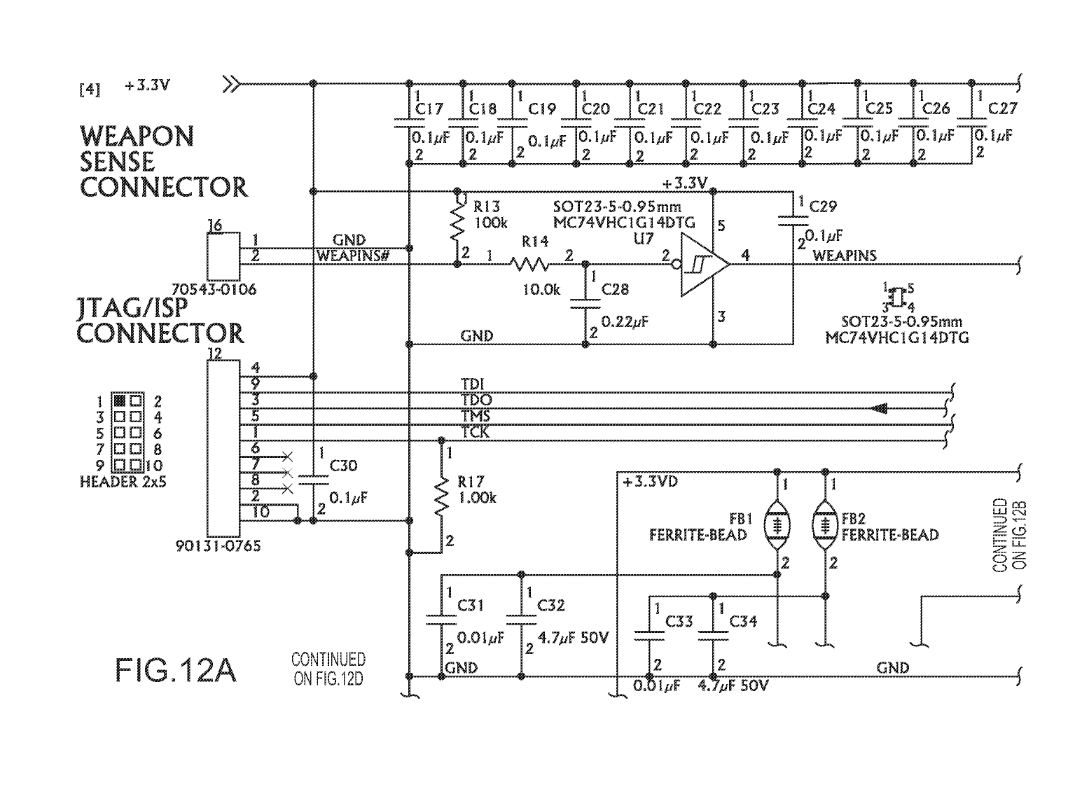

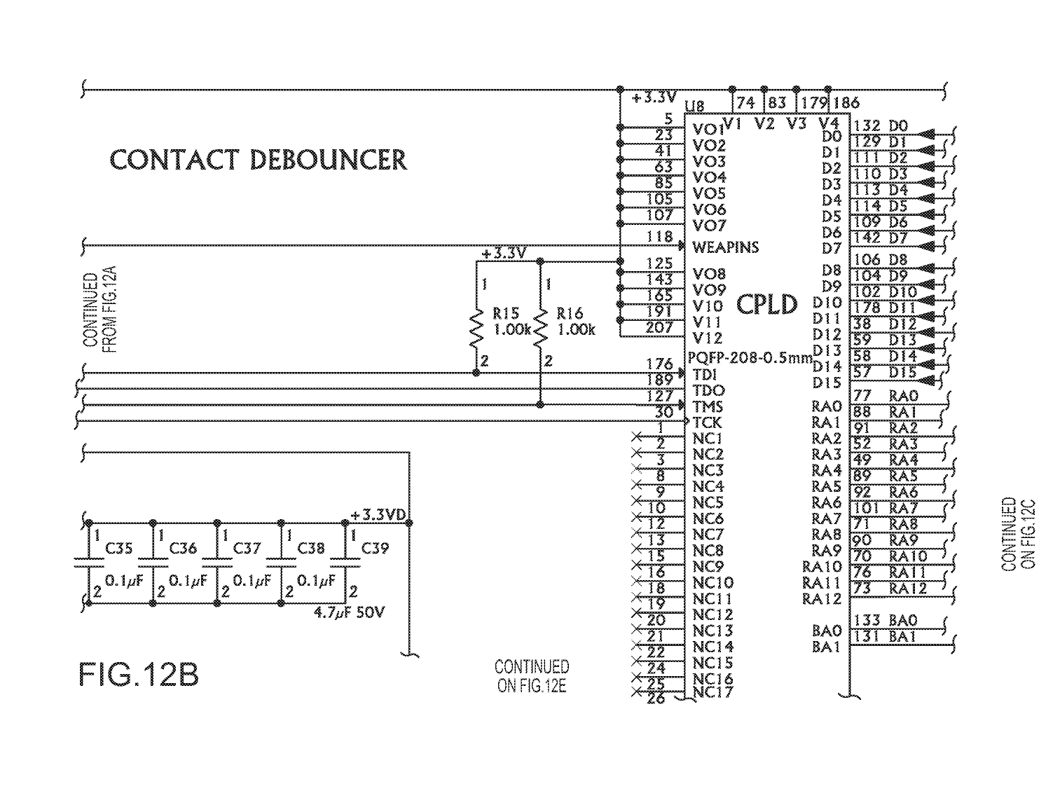

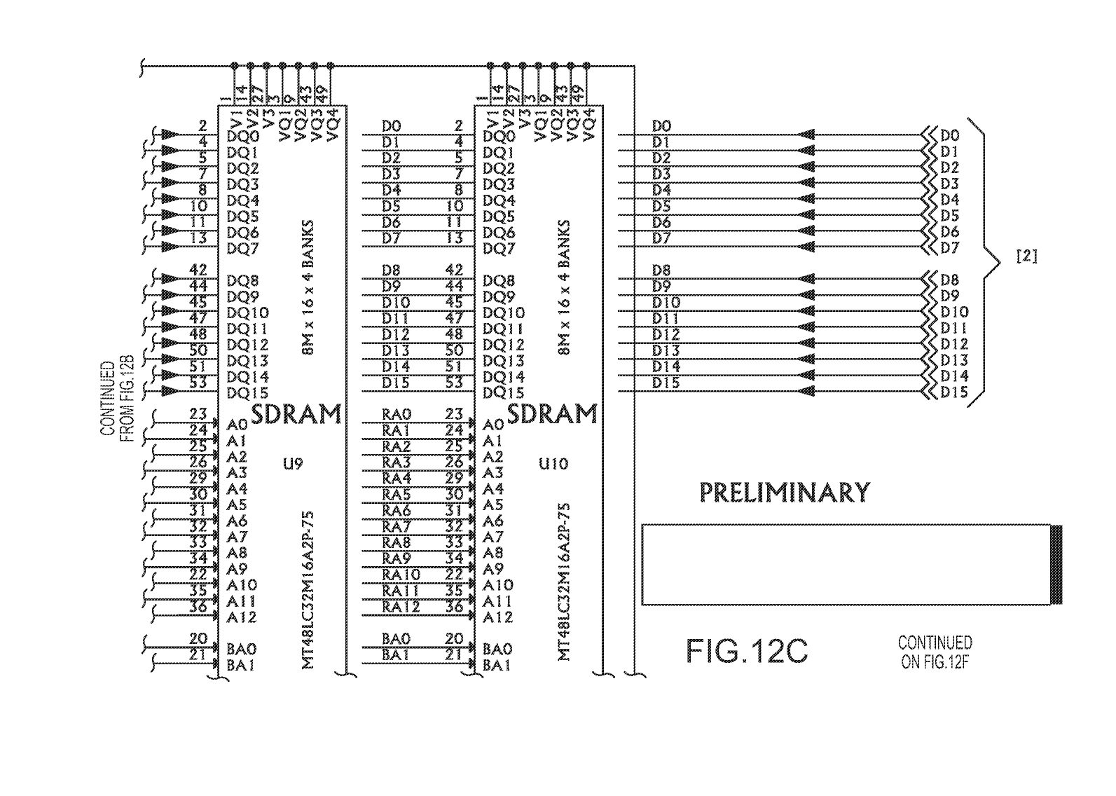

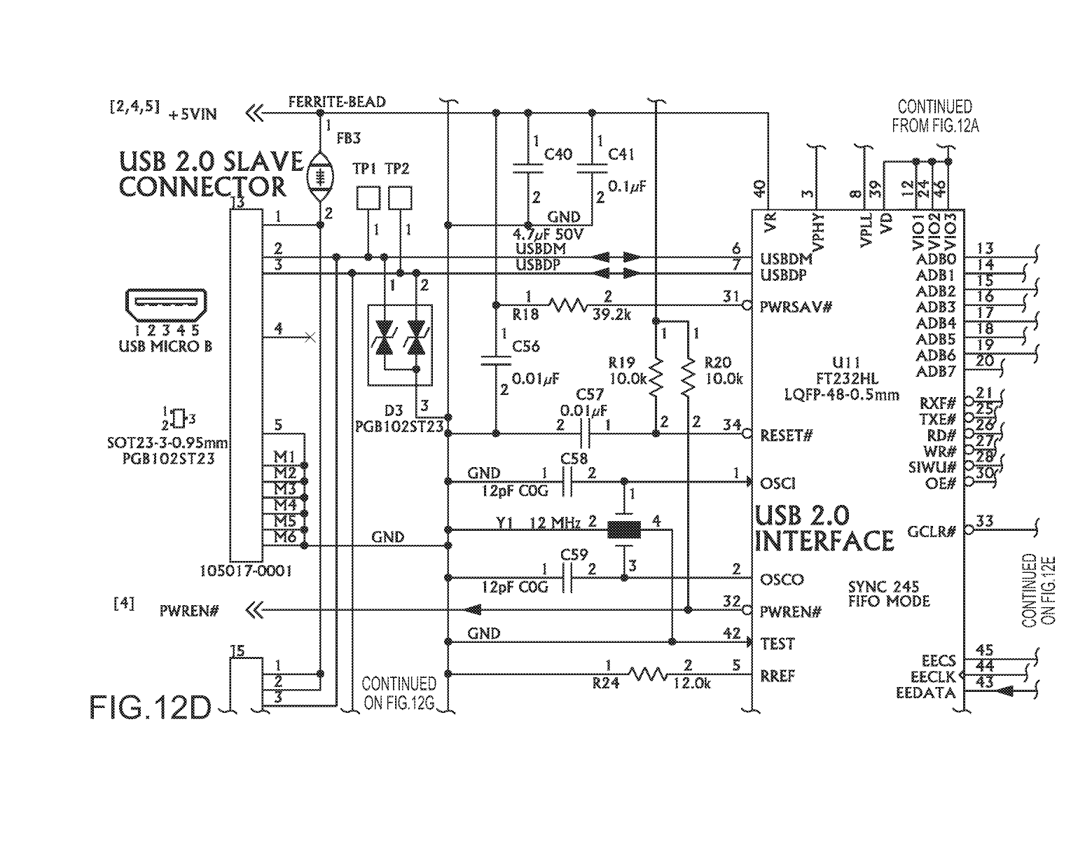

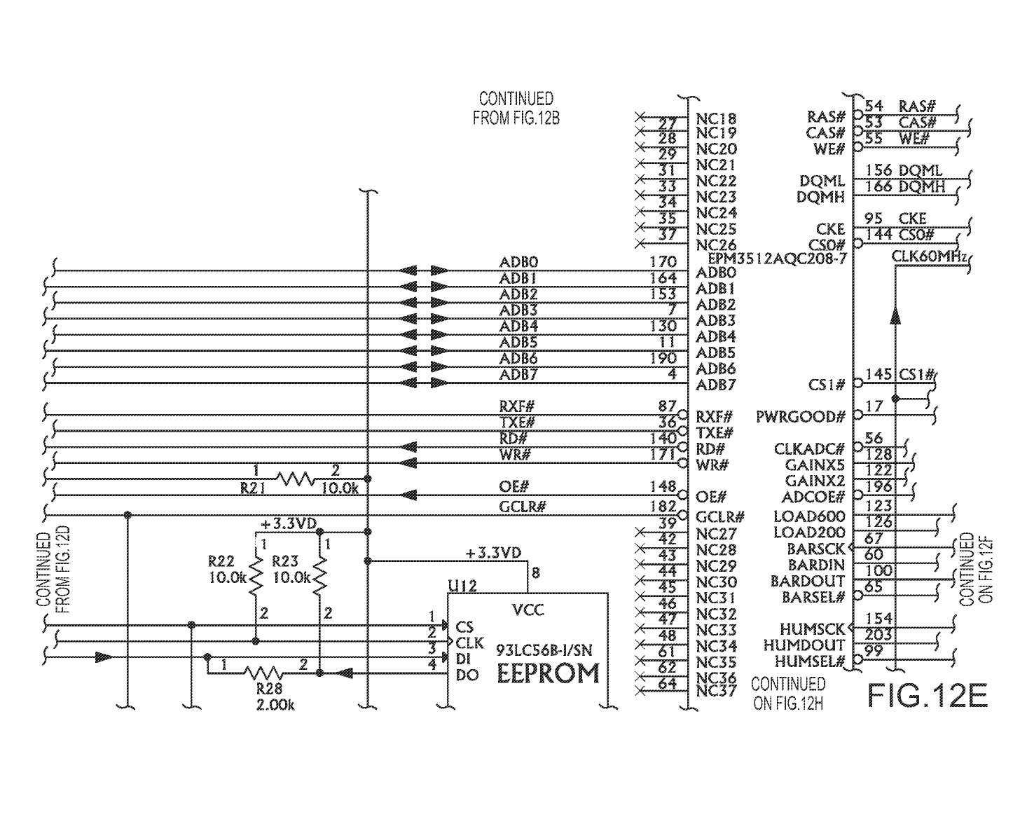

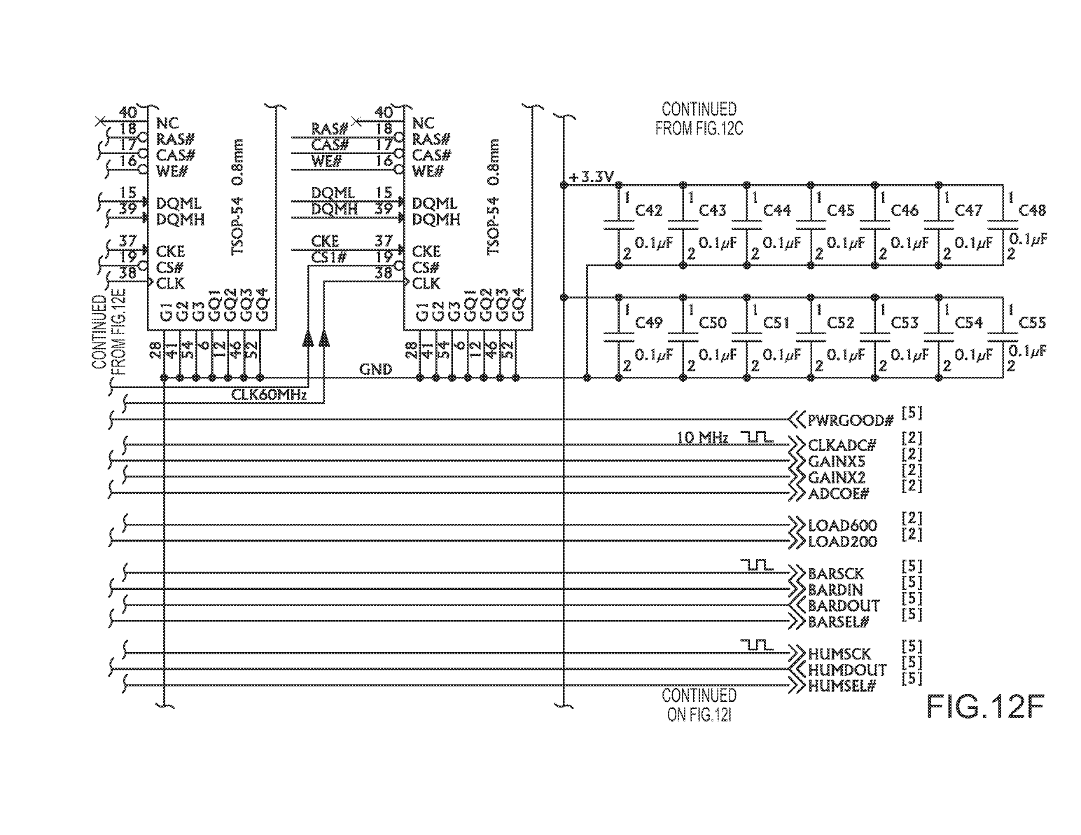

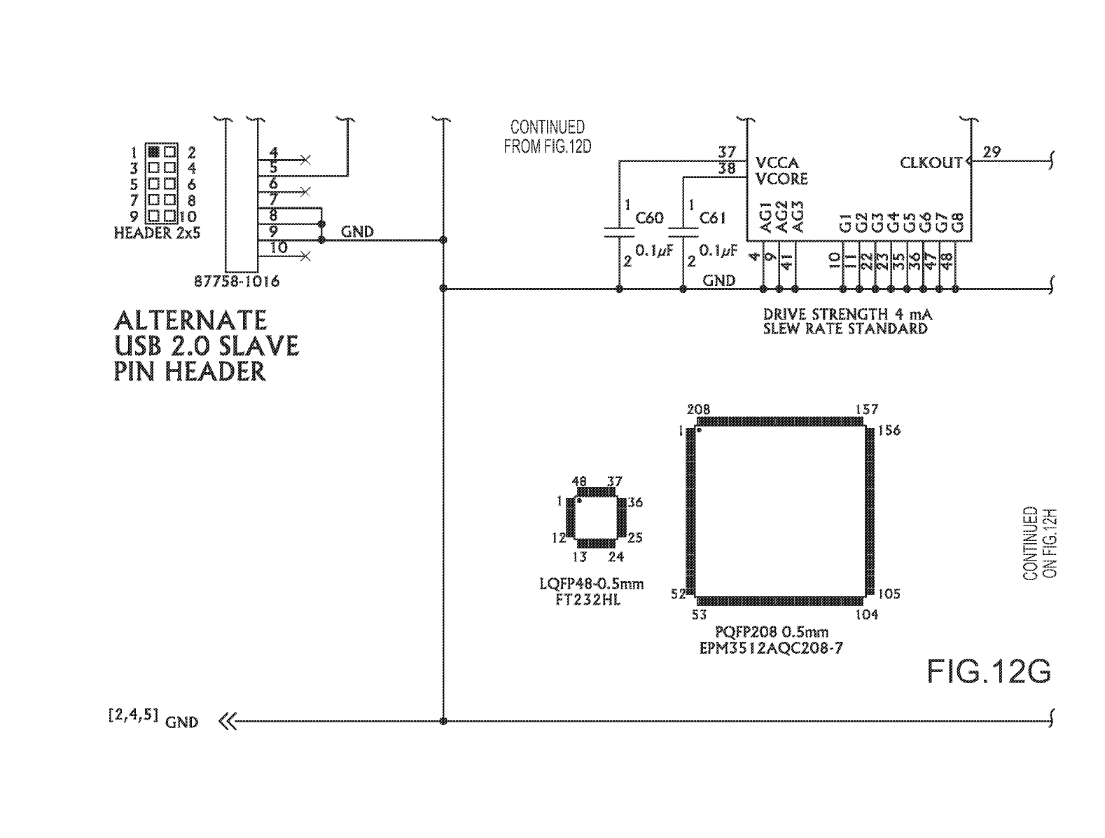

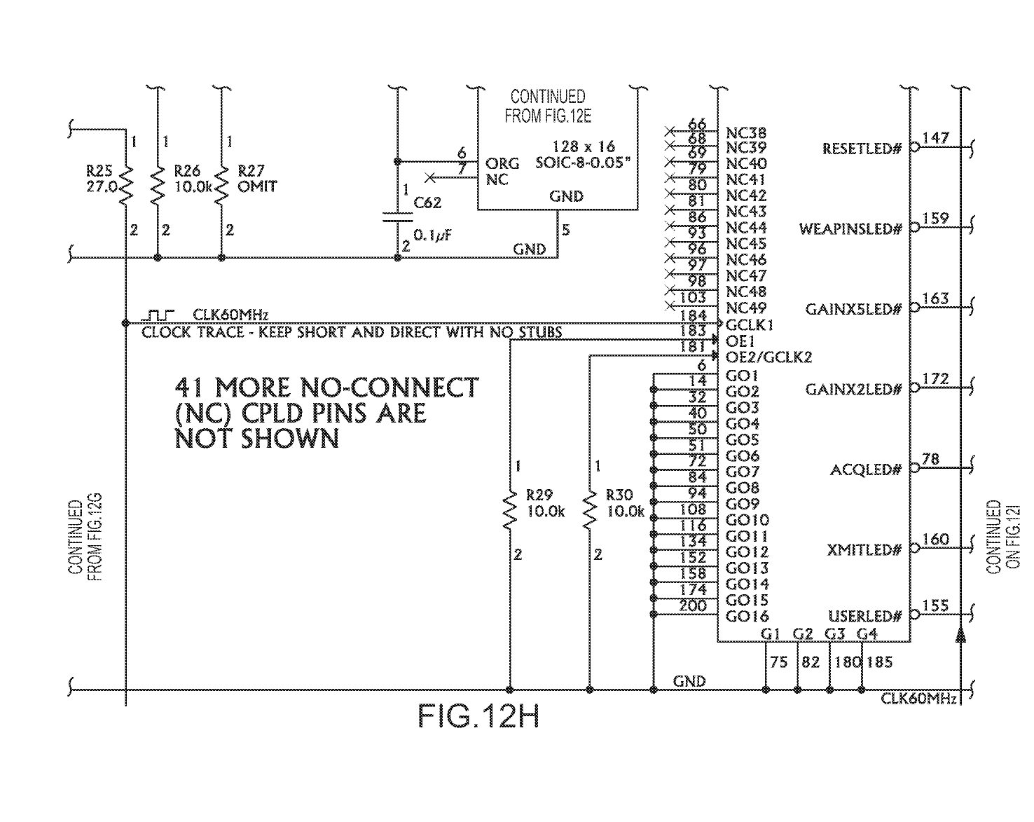

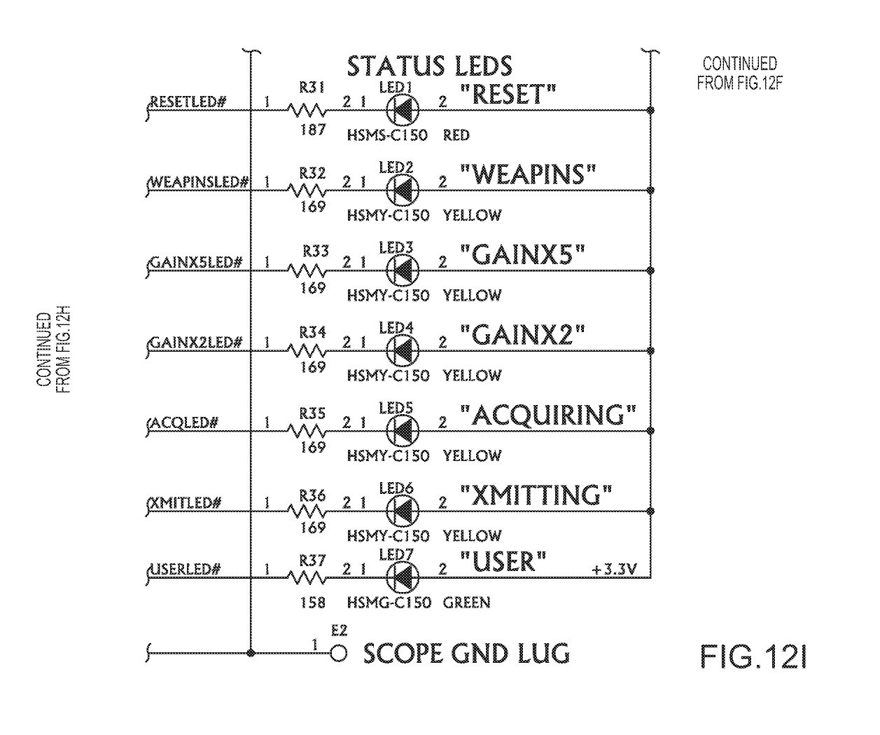

FIG. 12 is a schematic diagram of control circuit 706 utilized in the hardware configuration of FIG. 10. SDRAM, CPLD, and USB interface. FIG. 12 depicts the SDRAMs used for storing the data block, the CPLD that controls acquisition and transmission of the data block, and the USB 2.0 interface chip that transmits the data to the processor.

Complex Programmable Logic Device. U8 is an EPM3512A CPLD from Altera. It contains 512 logic macrocells in a 208-pin package. It is programmed with the logic via JTAG/ISP connector J2, but, unlike an FPGA, once programmed it retains the data pattern when power is removed. The CPLD is clocked at 60 MHz and contains all the logic to manage the ADC, SDRAM, and USB FIFO: data acquisition and storage, data readout and transmission, test mode, environmental sensor interface, and control/status registers.

Synchronous Dynamic Random Access Memory Chips. U9 and U10 are MT48LC32M16A2P-75 SDRAMs from Micron Technology. Each chip is configured as 33,554,432 (32M) sixteen-bit words and is clocked by the same 60 MHz clock as the CPLD. SDRAM is based on the familiar dynamic random-access memory (DRAM) chip architecture, but with a synchronous clocked interface—so the input control signals such as RAS# and CAS# no longer asynchronously and directly strobe in addresses, but instead are set up to be active on a specific clock edge, and are encoded to operate the SDRAMs. The CPLD is responsible for managing the address, data, and control input signals to the SDRAM (CS#, RAS#, CAS#, and WE#) to perform the required SDRAM functions of writing, reading, precharging, refreshing, and initialization. All accesses to the SDRAM are 16 bits wide, so the byte masking signals DQML and DQMH are strapped inactive within the CPLD.

An example CPLD clock diagram is provided for reference in FIG. 15. SDRAM Timing. The SDRAMs are operated on a fixed 200-ns period consisting of 12 clocks at 60 MHz. This allows time for one SDRAM read or write cycle per period. During data acquisition, a one-RAS two-CAS two-single-writes cycle writes two 16-bit words into the SDRAMs. During data transmission, a one-RAS one-CAS read-burst-of-two cycle reads out two 16-bit words from the SDRAMs. Doing two reads or writes in each 200 ns period allows the peak throughput to be 10 MHz, same as the ADC acquisition rate; read and write use different timing mechanisms to allow for differing data setup time requirements. During refresh, three refresh operations are accomplished in the 200 ns cycle.

SDRAM Write Cycle. For writing data, half of the address is presented and CS# and RAS# are activated in time for the second clock edge. This is followed by the other half of the address, CS#, CAS#, and WE# activated for the fourth clock edge. The first word of ADC data has been stable at the ADC register output and the bidirectional SDRAM data pins since the first clock edge. That word is written into the SDRAM on the fourth clock edge. The address is incremented while the ADC updates the data register with a new conversion result, and a second CS#, CAS#, and WE# are activated for the eighth clock edge, when the second word of ADC data is written into the SDRAM. On the twelfth (last) clock edge of the cycle, CS#, RAS#, and WE# are activated to precharge all columns of the SDRAM in preparation for the next access.

SDRAM Read Cycle. For reading data, half of the address is presented and CS# and RAS# are activated in time for the second clock edge. This is followed by the other half of the address, CS#, and CAS# activated for the fourth clock edge. The first word of read data appears as output on the bidirectional SDRAM data pins on the sixth clock edge, when it is latched into a register within the CPLD. The address is incremented both internal and external to the SDRAM, and a second word of data is read from the SDRAM and latched into a second register on the seventh clock edge. On the twelfth (last) clock edge of the cycle, CS#, RAS#, and WE# are activated to precharge all columns of the SDRAM in preparation for the next access.

SDRAM Refreshing. A read, write, or refresh operation occurs for each of the 8192 rows every 64 milliseconds to refresh the SDRAMs. SDRAM read cycles during transmission can only happen on alternate 200 ns memory cycles due to USB FIFO timing restrictions (see below) which allows opportunities for a refresh cycle. However, acquisition uses every available SDRAM write cycle during the full 5 second acquisition time. Since the SDRAMs are flat-out doing the write burst, there is no time during acquisition for separate refresh operations. Thus, the addressing of the SDRAMs has been arranged so that acquiring (or transmitting) a block of data automatically refreshes the memory array. Address bits 1 through 13 from the address counter select the row, address bit 14 selects the chip, and address bits 15 and 16 select the bank address. That way, every time 128 k words are sequentially written or read, all 8192 rows, both chips, and all four banks within each chip are refreshed. Address bit 0 can't be used for refresh; it needs to be the LSB of the column address so that burst (internally incremented) read addressing matches non-burst (externally incremented) write addressing.

When the memory is not acquiring or transmitting data, a burst of three refresh operations is performed on every 117th cycle (117×200 ns=23.4 microseconds). For a refresh operation, CS#, RAS#, and CAS# of both SDRAM chips are all activated for the second, sixth, and tenth clock edges of the 200 ns cycle. There is no need for a precharge after a refresh operation. The SDRAM chip internally takes care of incrementing the refresh address, so all 8192 rows are refreshed every 2731 refresh cycles, or 63.9 milliseconds.

SDRAM Initialization. The SDRAM must be initialized on power-up. A sequence of initialization steps is performed by a counter in the CPLD: CKE is initially held low with refresh operations disabled, then after the power and clock are stable and a delay elapses CKE is set high and left there, then a precharge-all is performed on both SDRAM chips, then refresh cycles are started, then after several refresh cycles have occurred the mode registers in both SDRAM chips are loaded via the address pins to select the operating mode (the value loaded is 0x0221, which selects standard single-access per CAS [not burst] write cycles, and a burst-of-two read cycle with a CAS latency of 2 clocks). After this, the SDRAM is ready for normal data access operations, and refresh cycles continue on schedule.

Data Acquisition. The ADC is continuously converting the analog signal from the test fixture. When acquisition has been enabled in the control register and the CPLD is not acquiring or transmitting data, the CPLD continuously monitors the absolute value of the digital data from the ADC and compares it to an internal programmable threshold register value containing a positive data value. When the incoming ADC data exceeds the programmable threshold, signifying that the weapon has begun firing, the CPLD enters “acquiring” mode. In “acquiring” mode, two 12-bit ADC values (with the overflow bit appended in bit 15) are written into the SDRAM every 200 ns, while the address is incremented. After 50,000,000 words have been written, “acquiring” mode ends.

Data Transmission. When “acquiring” mode has ended, the data is available to be read by the processor. The processor requests a 32 k word block of data by setting bit 3 of the control register at address 0xf4, which clears when the block transmission starts. Before requesting a transmission, the processor may optionally specify the starting address of the block by loading the “block start” register at address 0xf1. If that register is not loaded, read out starts with block zero and continues in sequential block order through the entire memory. While the block is being transmitted, the CPLD is in “transmitting” mode. In “transmitting” mode, each pair of data words is read out of the SDRAM and transmitted via the USB to the processor. The next pair of words from the SDRAM is read as soon as the previous pair of words has been transmitted, so there is a continuous flow of data to the USB FIFO.

Normally the FIFO interface is only fast enough to read two words on every other memory cycle, for a peak transmitted data rate of 5 MHz. If the FIFO is not emptied promptly, its TXE# flag is negated and memory reads are suspended until there is again room in the FIFO. When transmission of the 32,768 words in a block is complete, “transmitting” mode ends. Software may request blocks sequentially or in random order, and may ask for a block to be re-transmitted.

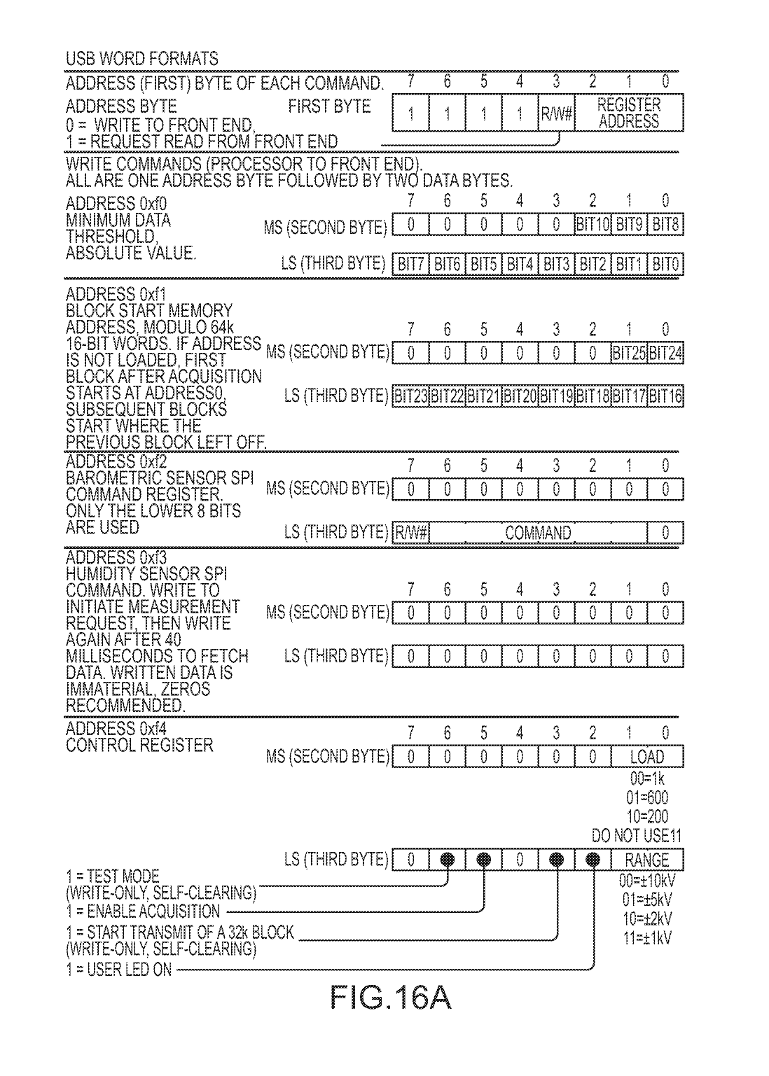

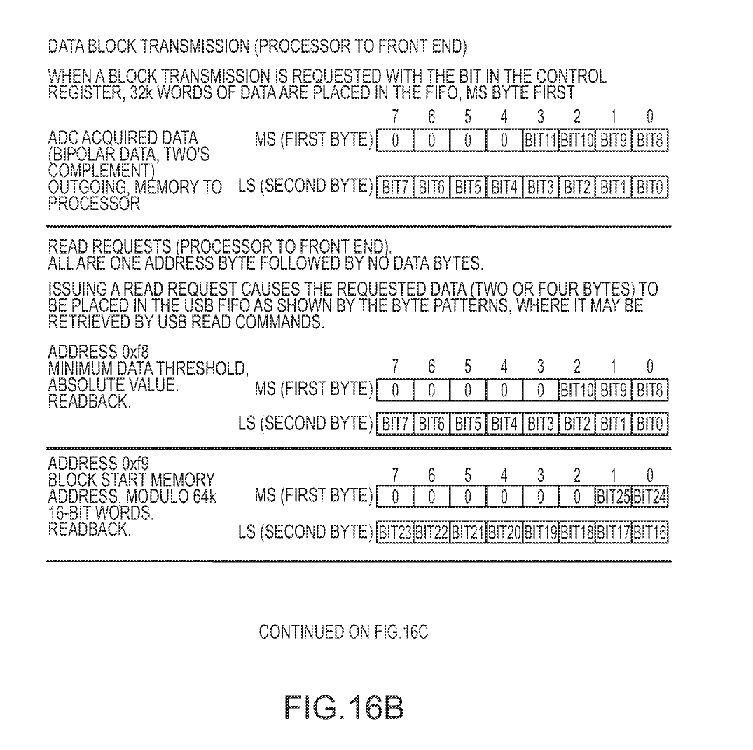

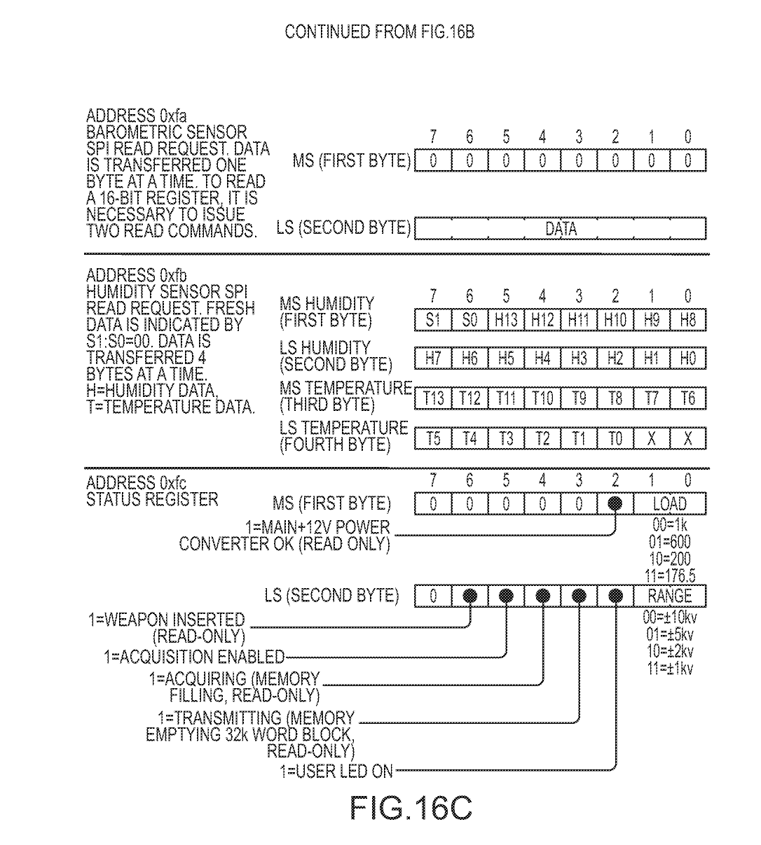

An example addressing scheme is depicted in the “USB Word Formats” diagram of FIGS. 16A and 16B. USB Access To CPLD Registers. The USB FIFO interface is 8 bits wide with no address information. Each command coming over the USB into the CPLD has an initial address byte containing a 3-bit register address and a read/write bit. The upper four bits of an address byte are all ones to assist in re-synchronizing in case sync is lost; none of the upper bytes (at least) of write data will have this pattern. This allows for up to eight write commands and eight read requests, providing sufficient capacity and room for expansion if desired.

For each write command, the address byte is followed by two data bytes, MSB first, although at some addresses some or all of the data will be ignored. Since there is no longer a need for upper bit coding, the data is now aligned in right justified natural binary form. For a read request, there are no data bytes following the address byte. Sending a read request causes the CPLD to place the requested data (two or four bytes) in the USB FIFO where it may be retrieved by USB read commands. A read request to the humidity sensor at address 0xfb returns four bytes in the FIFO; all other read requests (0xf8 for Threshold Register, 0xf9 for Block Start, 0xfa for Barometric Sensor, 0xfc for Status Register) return two bytes in the FIFO.

A write to address 0xf0 (Threshold Register) stores the 11-bit value in a threshold register within the CPLD, used to set the incoming signal threshold for starting data acquisition; this value may be read back with a request to 0xf8. A write to address 0xf1 (Block Start Memory Address Register) is stored in the address counter, used to set the starting memory address for a block data transmission; this value may be read back with a request to 0xf9. Use of 0xf2/0xfa for the barometric sensor and 0xf3/0xfb for the humidity sensor are detailed below.

The control and status registers are a pair of 16-bit registers located within the CPLD. The control register (from the processor to the front end), written at address 0xf4, contains persistent bits to select holster load resistance, select ADC range, and control a user LED. It also contains self-clearing bits to enable acquisition, initiate transmission of a block, or initiate test mode. The status register, read back at address 0xfc, contains readback bits for the persistent control register bits, plus additional read-only status bits to reflect the state of the main power converter, weapon inserted, acquisition enabled, acquiring, and transmitting mode. When test mode is selected, the output word from the ADC registers is disabled, and the CPLD substitutes the lower 12 bits of the SDRAM address on the bidirectional data lines. This results in a predictable incrementing pattern being written into the SDRAM during acquisition, in lieu of the ADC data. The incrementing pattern resembles a sawtooth waveform, and can be useful for debugging the data acquisition and USB operations. The “test mode” bit is write-only, and clears itself at the start of the data acquisition. “Weapon inserted” is detected with a mechanical switch in the test fixture, connected to this board via J6 in FIG. 12. It presents a contact closure to digital ground. R13 converts that contact closure to a 3.3-volt logic signal, which is filtered with R14, C28, and 74VHC1G14 Schmitt trigger gate U7 to remove contact bounce. It is readable as read-only bit 6 of the status register at address 0xfc.

Returning to FIG. 12, U11 is an FTDI FT232H USB 2.0 interface chip. USB Interface Chip. This chip bidirectionally interfaces a high-speed USB port to the CPLD via a synchronous FIFO interface. The USB port connects to either J3 (a USB micro-B connector) or J5 (a 10-pin 2 mm header with MIO pinout). Two connectors are provided to allow use of either dual-USB-port connector on the processor board. D3 is a surge suppressor across the USB data contacts, while ferrite bead FB3 filters the USB 5-volt supply for use by the front-end board. FB1 and FB2 respectively filter the PHY and PLL supplies to the FT232H. Y1 is a 12 MHz crystal configured as an oscillator with U11. An internal PLL (phase-locked loop) multiplies the frequency up to 480 MHz for USB use, and also provides a 60 MHz clock output for synchronous FIFO use. This 60 MHz clock feeds the CPLD and both SDRAMs via a single series termination resistor and three equal length PC board clock traces. When receiving data from the USB to the front-end board, U11 activates RXF# and provides the incoming data on the ADB[7.0] bus when the CPLD asserts OE# and RD#. To transmit data on the USB, the CPLD looks for the TXE# flag to be active and sends the data on the ADB[7..0] bus when it asserts WR#.

10 MHz transmission is used. Logic within the CPLD sequences the FIFO controls, but the programmer should avoid trying to interleave USB reads and writes, or data and status reads, to attempt to avoid data scrambling. In general, transfers to or from control register, block start register, threshold register, environmental sensors, or status register should be done one at a time when a data block transmission is not in progress. USB operations (except for writing the block start register) may be performed during data acquisition.

Electrically Erasable Programmable Read-Only Memory. U12 is a serial EEPROM, required to use the synchronous FIFO mode of the FT232H. It contains configuration information for the FT232H. There is additional space in this EEPROM, which the program uses to store calibration constants for the four analog ranges. The EEPROM is programmed via software in the processor at initial setup and at calibration time, and retains its data when power is removed.

Diagnostic LEDs. A set of seven diagnostic LEDs is provided to indicate the operating mode, ADC range, weapon inserted, and the user LED, as well as the status of RESET. The CPLD is globally reset by an external GCLR# signal from a GPIO pin on the FT232H. This allows software to reset the front end board independent of the power-on reset. GCLR# is pulled down by R26 so this board is held in the reset state at power-up until the FT232H is configured.

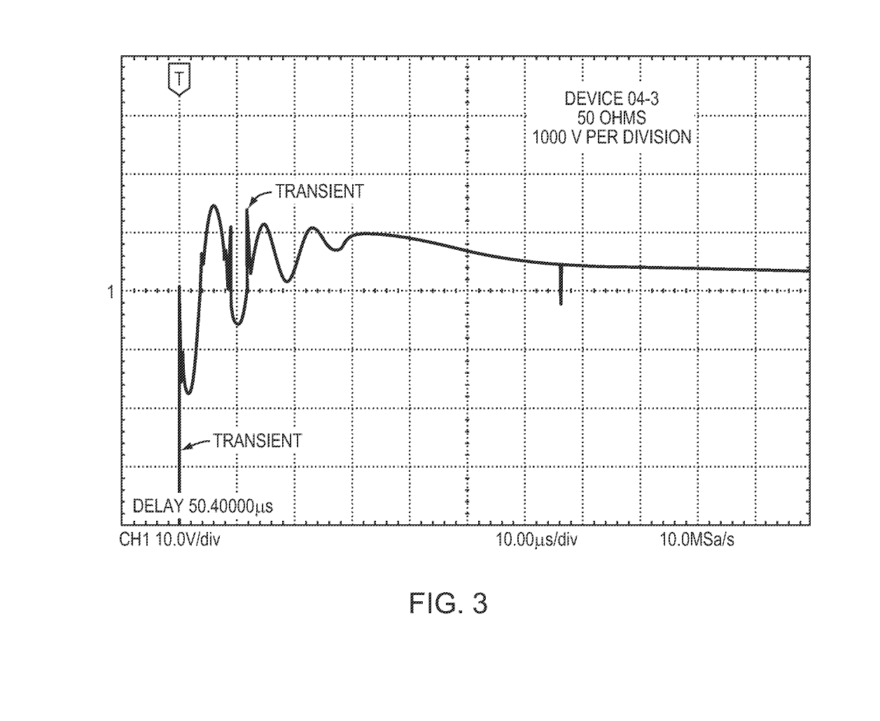

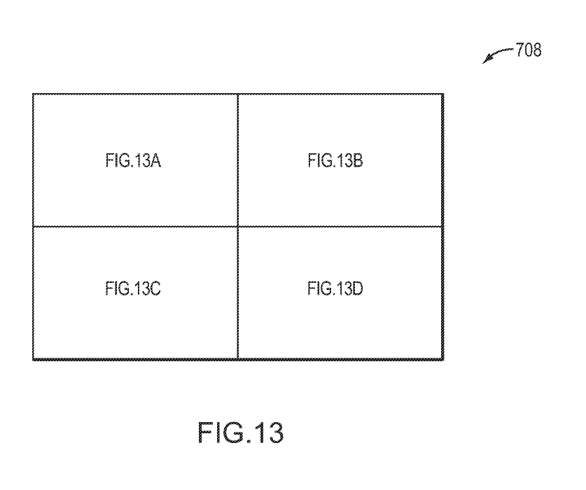

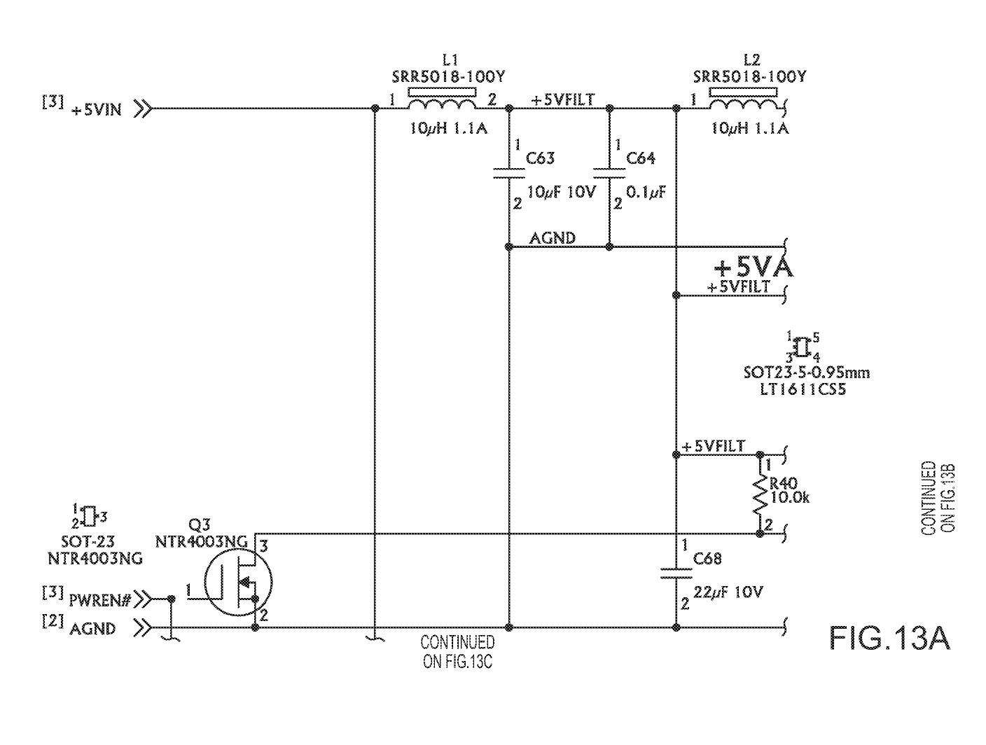

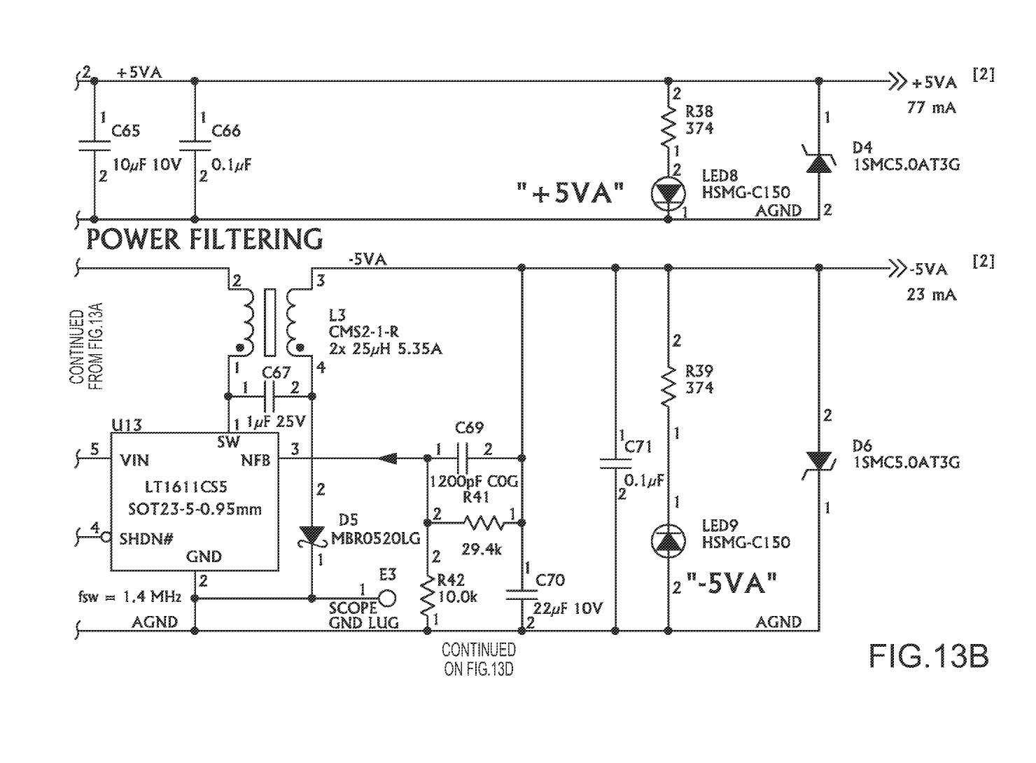

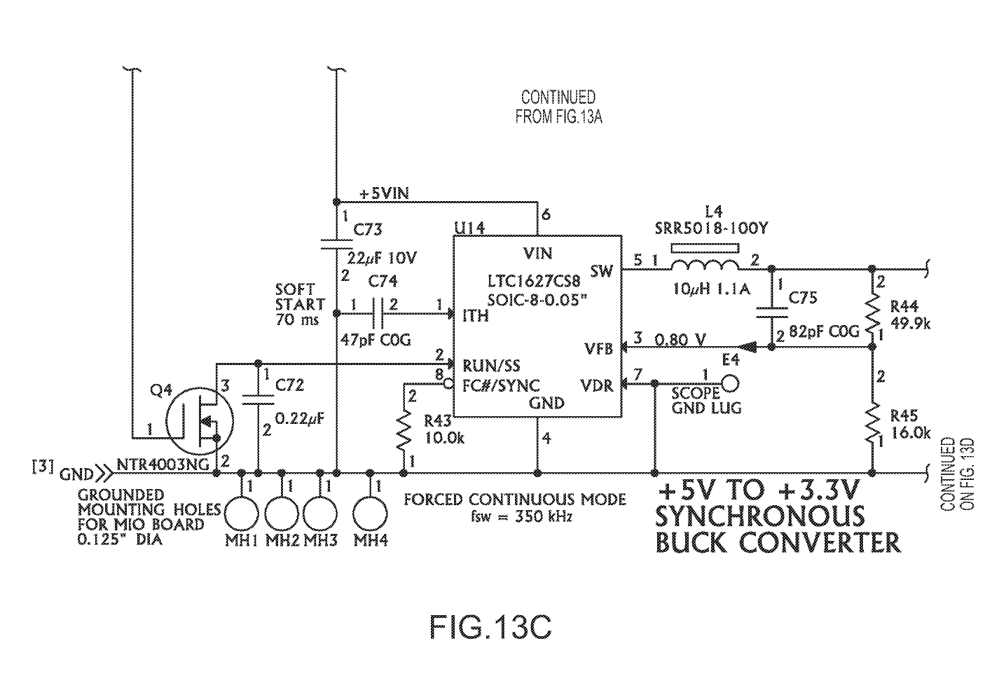

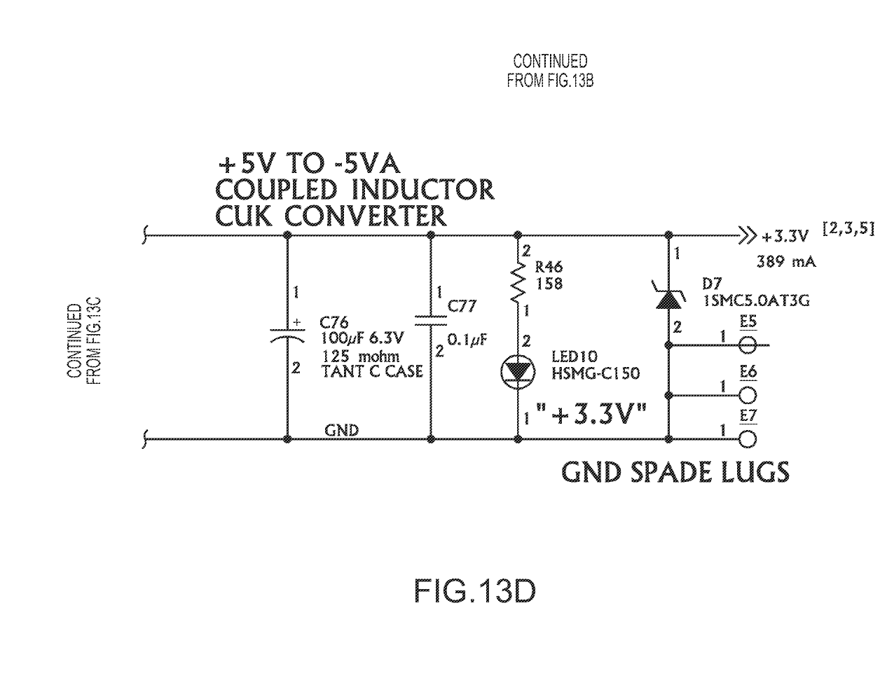

FIG. 13 is a schematic diagram of a power circuit 708 utilized in the hardware configuration of FIG. 10. Onboard Power Supplies. FIG. 13 depicts the filtering, conversion, and distribution for the power used on the board. The USB interface supplies a single digital +5 volt supply to this board through MIO-pinout USB connector J5 and FB3, shown in FIG. 3. (For debugging purposes, a standard micro USB connector, J3, is also provided.)

Onboard Power Filtering. +5VIN supplies maximum 120 mA directly to the digital circuitry, mostly the FTDI chip. The +5VIN supply is also used to generate a +3.3V digital supply at 400 mA maximum. +5VIN is filtered to provide the +5VA analog supply referred to AGND to the ADC and opamps, which has a maximum calculated output load of 80 mA. The filtered +5VIN is also used to generate the −5VA supply at 25 mA maximum.

+3.3 V Converter. U14 is an LTC1627C buck regulator from Linear Technology. It is configured as a synchronous buck converter using inductor L4. The converter operates continuously (after USB enumeration) with a 350 kHz switching frequency. R44, R45, and C75 are the feedback network, chosen to provide an output voltage of +3.3 volts (referred to digital ground) to the CPLD, SDRAM, and the rest of the logic.

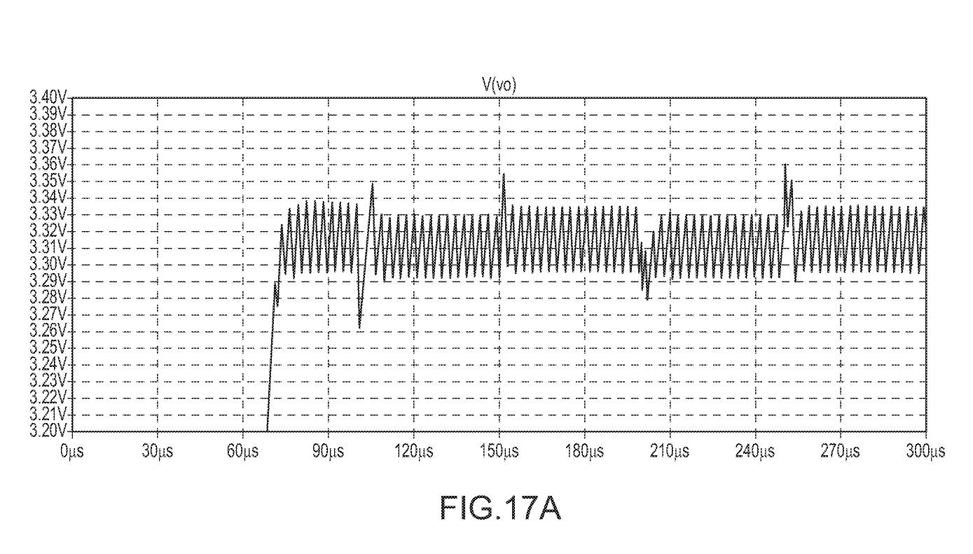

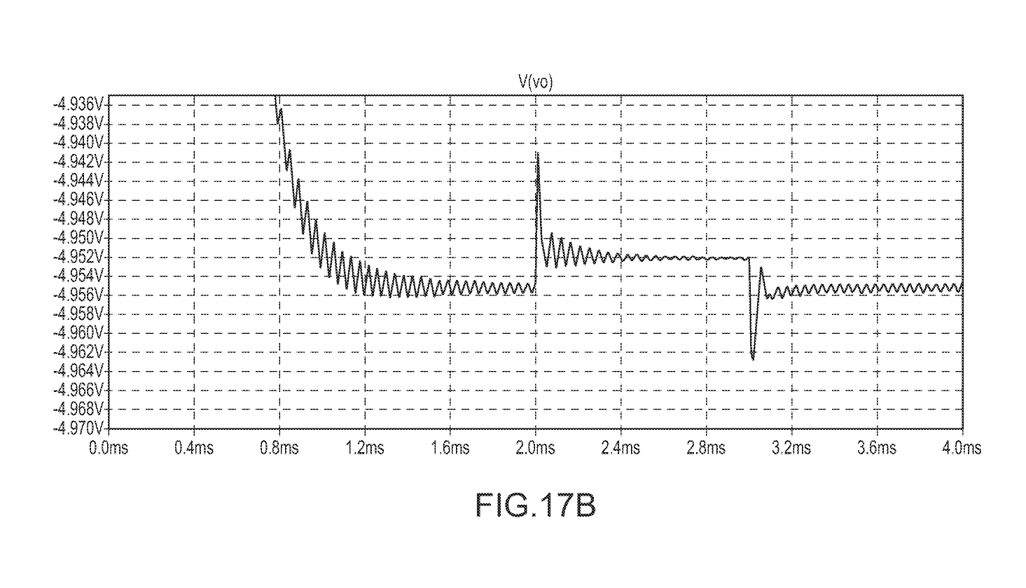

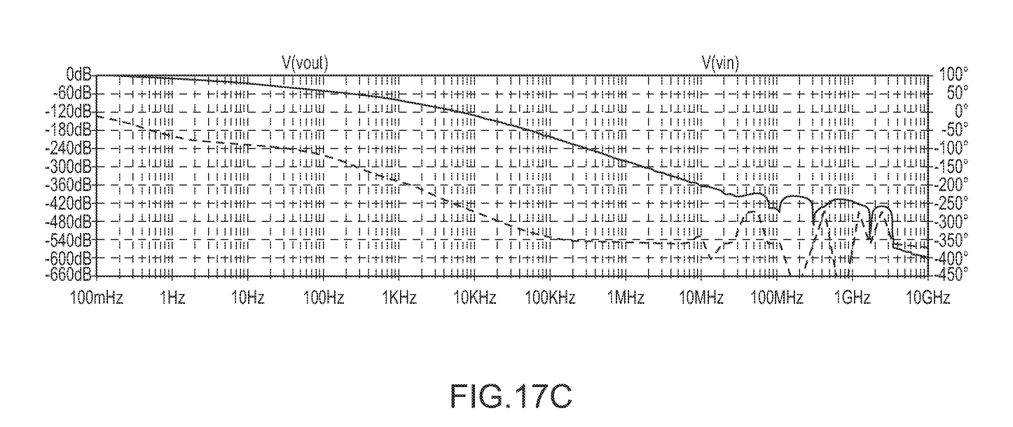

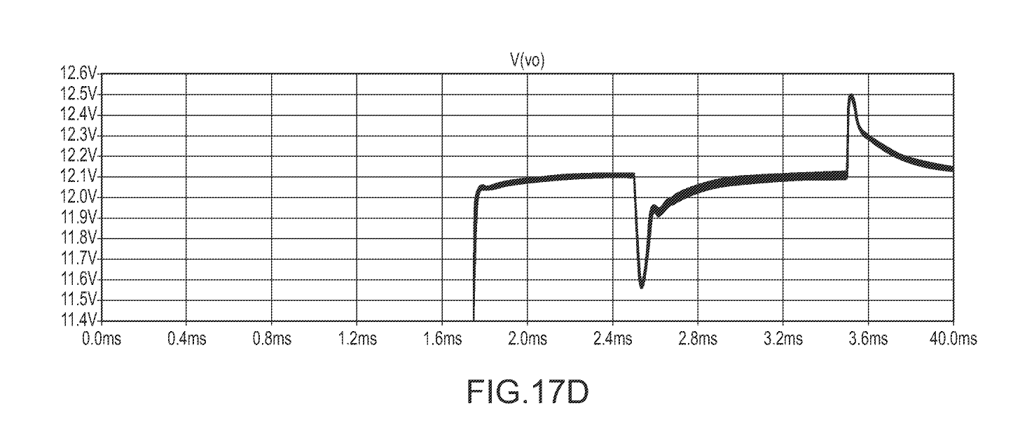

The result of the LT-Spice simulation for the LTC1627C showing the output voltage response to a 150-400-150 mA output load step is shown in FIG. 17A. The load add transient is 50 mV, the DC output shift under load is about 5 mV, the load dump transient is 50 mV, and ripple is about 40 mV peak-to-peak.

Returning to FIG. 13, U13 is an LT1611C inverting switching regulator from Linear Technology. It is configured as a coupled-inductor Cuk converter using coupled inductor L3. (The symbol looks like a transformer, but the difference is that a transformer has energy flowing through from one winding to the other, while a coupled inductor alternately stores energy in the core using one winding, and releases energy using the other winding.) This circuit configuration provides low switching noise on both input and output, due to its continuous (triangle wave, non-pulsating) input and output current. The converter operates continuously (after USB enumeration) with a 1.4 MHz internal switching frequency while +5-volt power is supplied. R41, R42, and C69 are the feedback network, chosen to provide an output voltage of −5 volts referred to AGND. The output load on the −5VA supply is calculated as 23 mA max.

The result of the LT-Spice simulation for the LT1611C showing the output voltage response to a 10-50-10 mA output load step is shown as FIG. 17B. The load add transient is 14 mV, the DC output shift under load is 3 mV, the load dump transient is 11 mV, and ripple is about 1 mV peak-to-peak.

Returning to FIG. 13, to reduce current draw on the USB supply during USB enumeration, both the +3.3V and −5VA converters power-up in the off state, determined by PWREN#, a signal from the FT232H. Once enumeration is done, PWREN# goes active-low and turns on both converters by opening Q3 and Q4. Calculated load on the USB supply is maximum 530 mA, just a bit over the allowed 500 mA, but since there is a captive load on the processor and it is not operating over the full temperature range, operating slightly above the limit is acceptable. All three supplies have green LEDs to indicate voltage present, and all three supplies have Trans-Zorb zener transient suppressors to protect the loads from accidental arcing from the high-voltage pulse input.

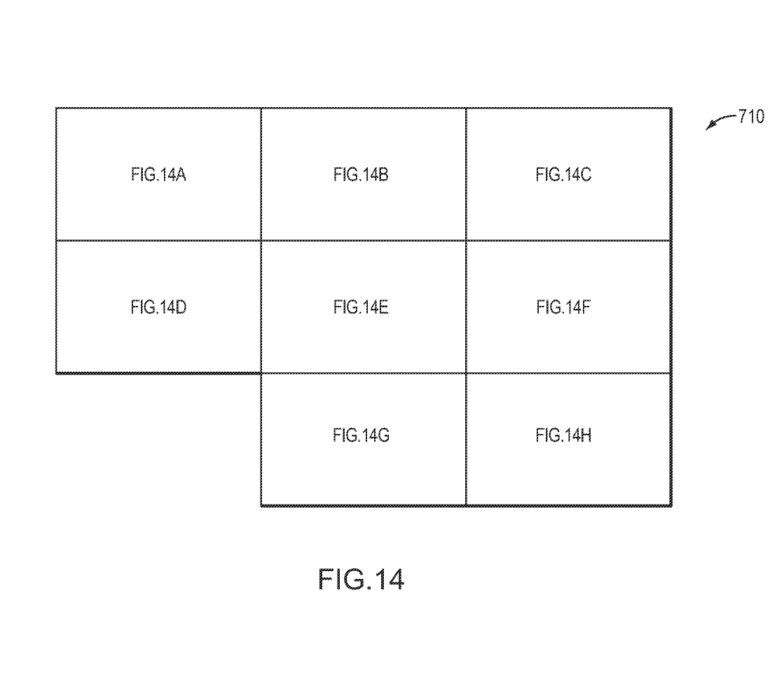

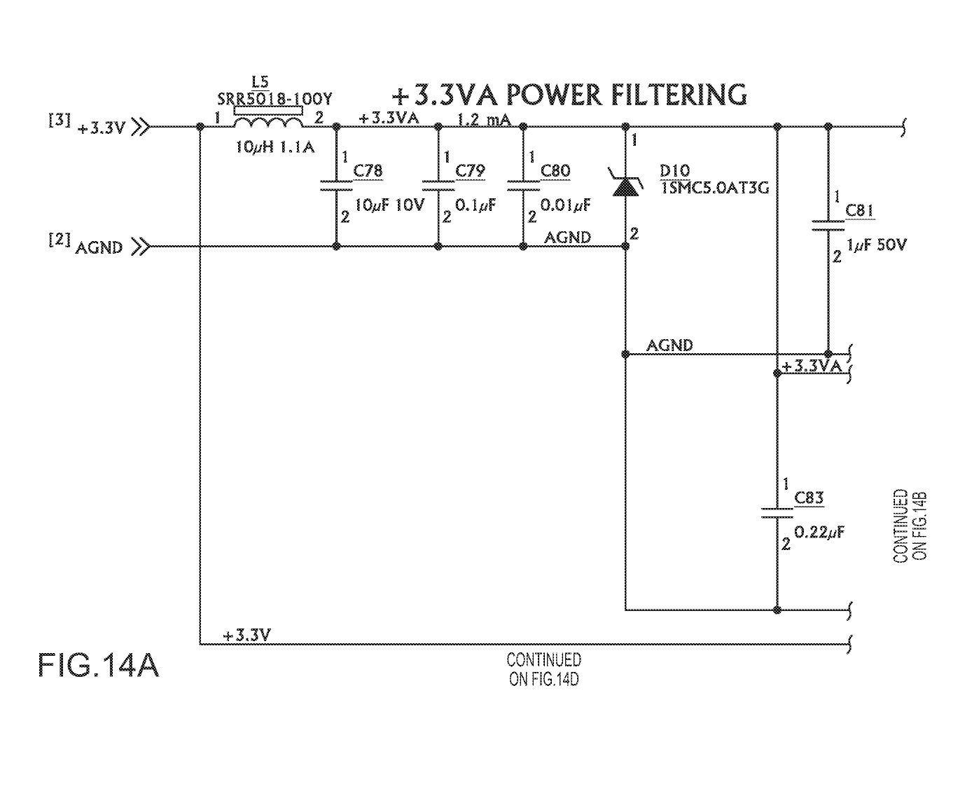

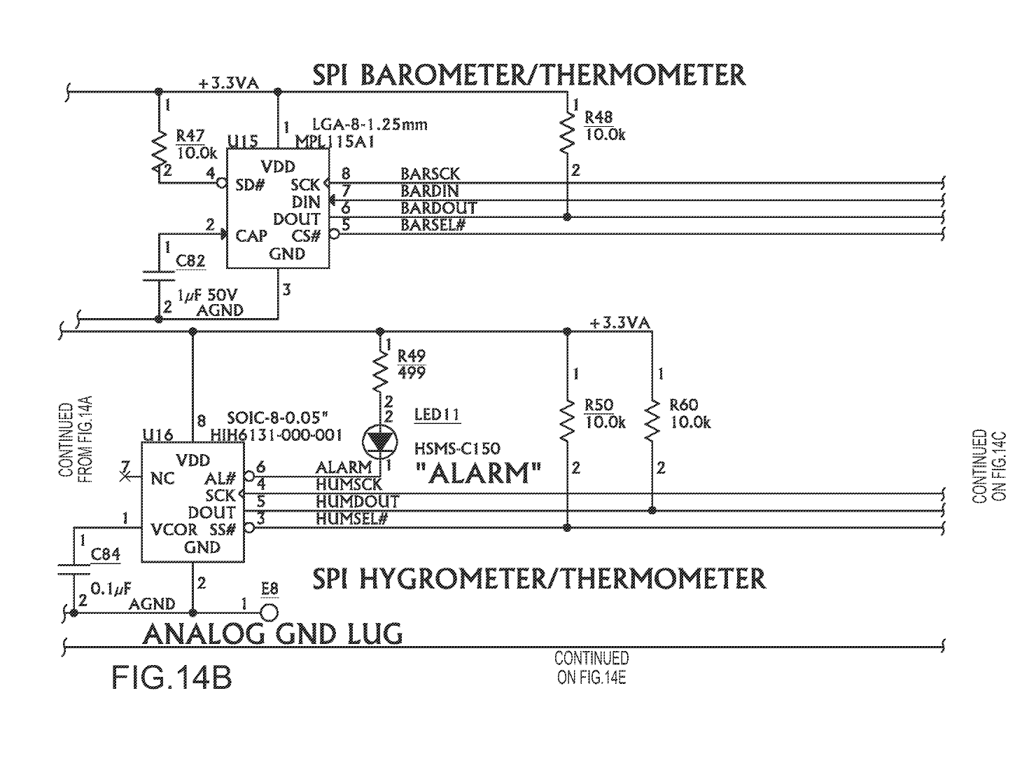

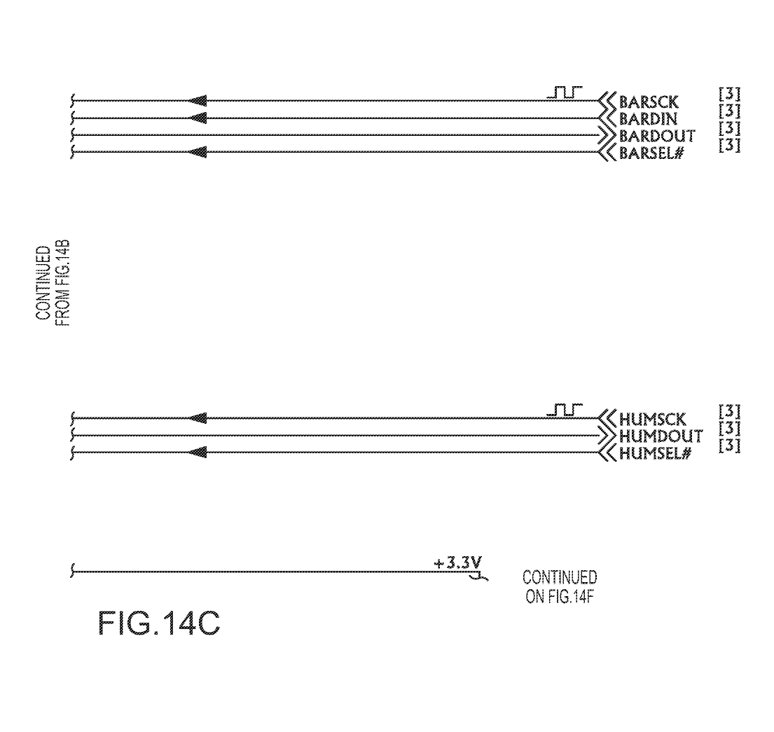

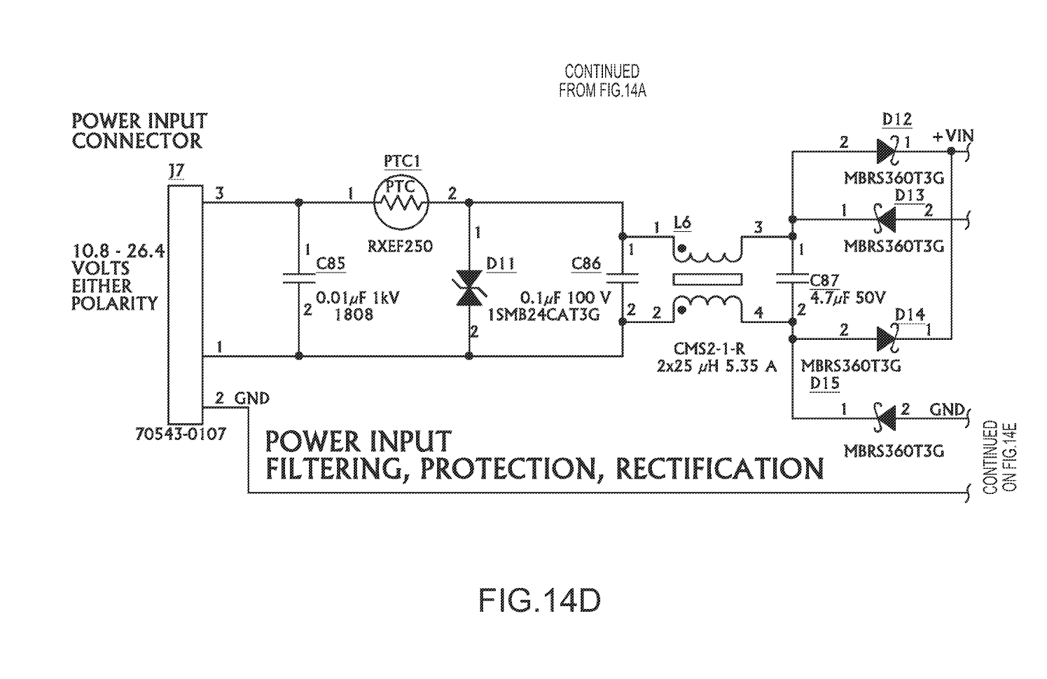

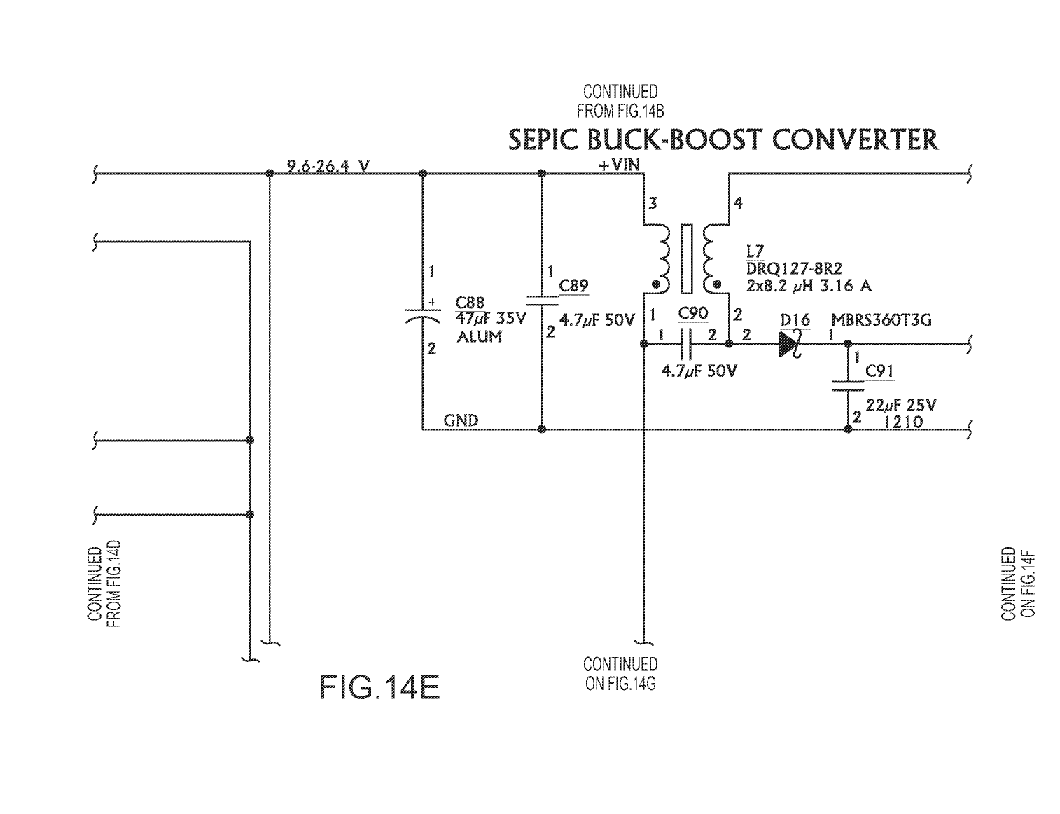

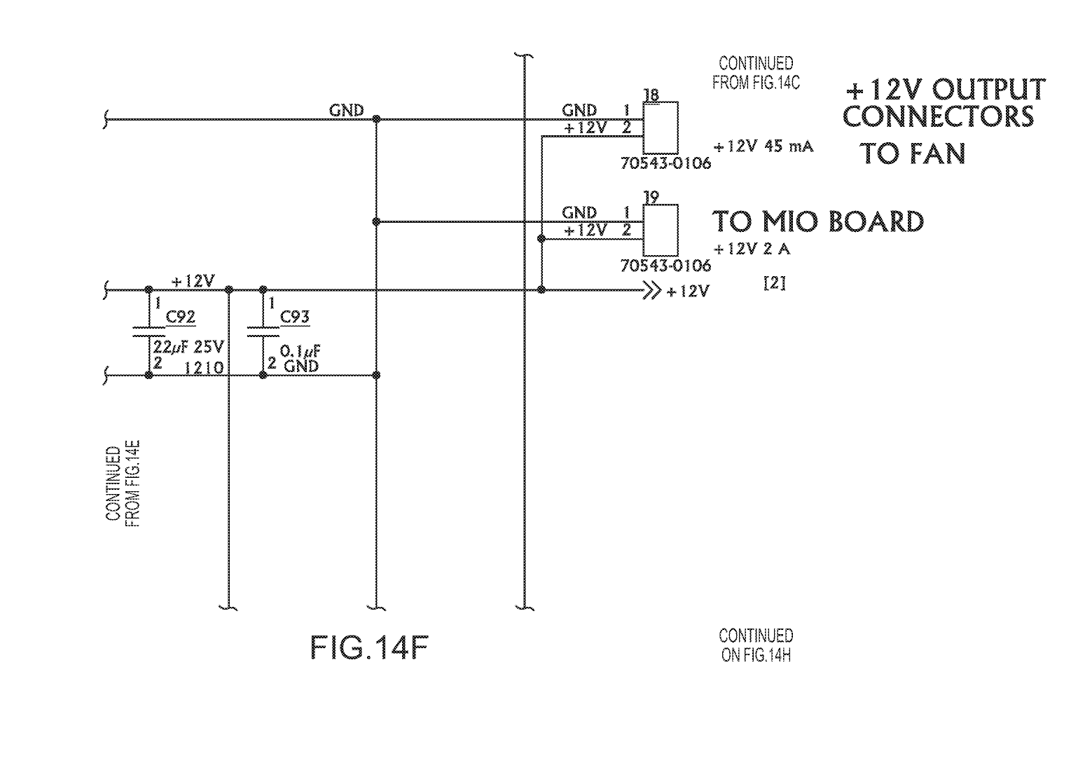

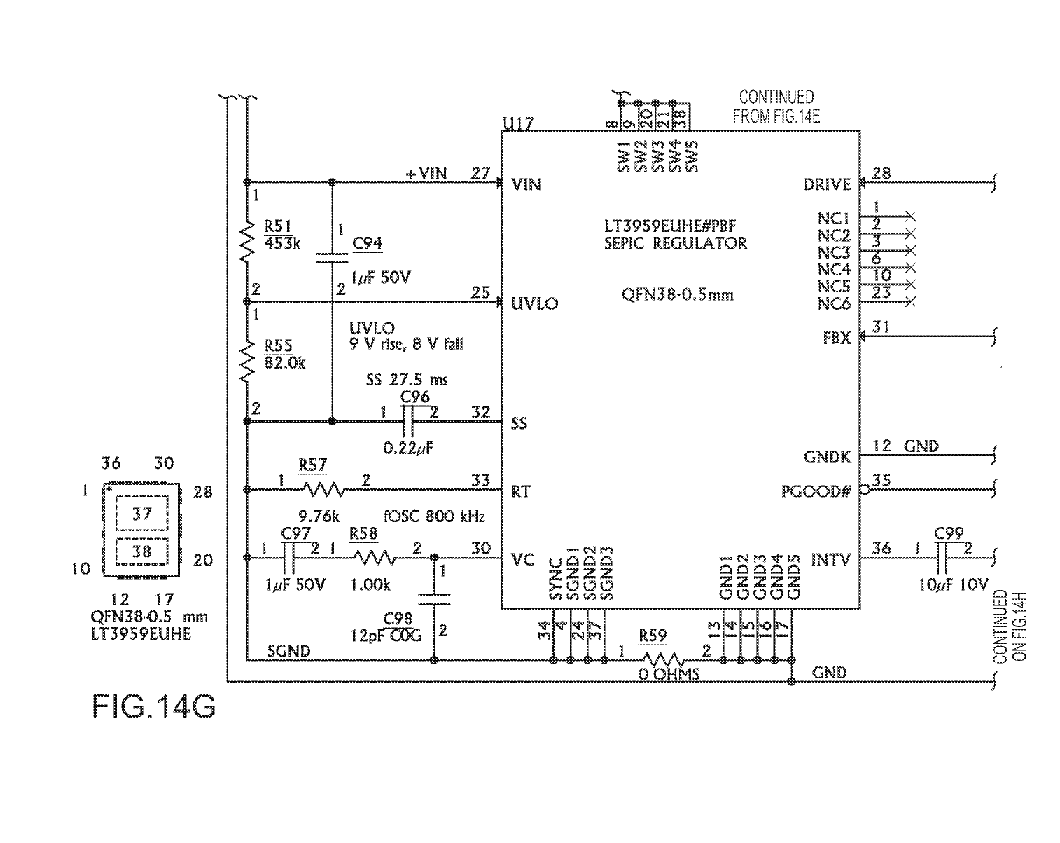

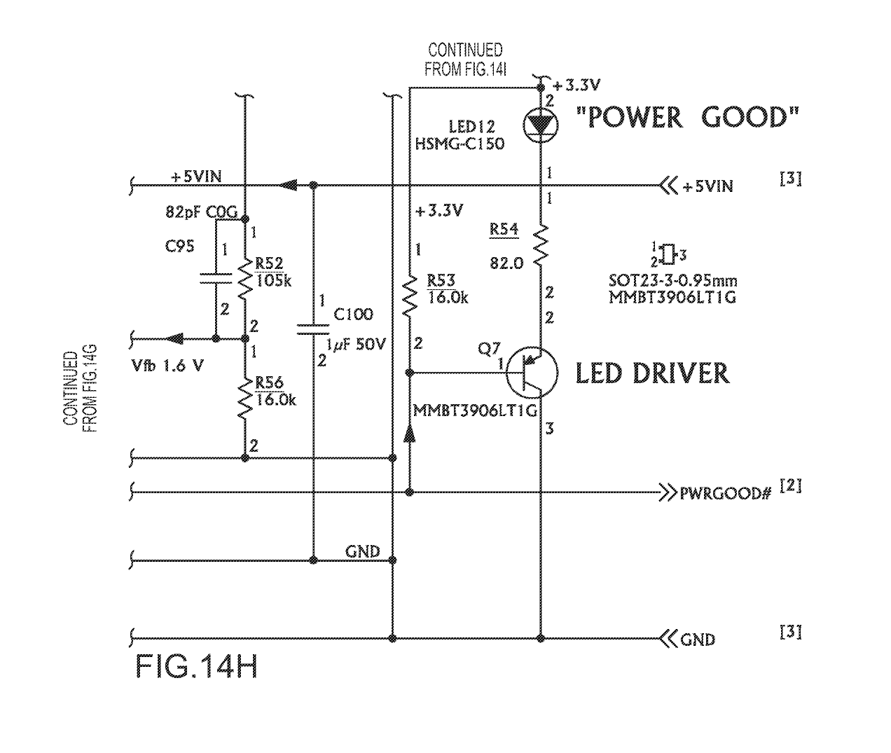

FIG. 14 is a schematic diagram of a sensor circuit 710 utilized in the hardware configuration of FIG. 10. Sensors and Input Converter. FIG. 14 depicts two environmental sensors and a buck-boost input power converter.

Analog 3.3V Supply. L5 and C78 through C80 filter the digital +3.3-volt supply and refer it to analog ground to produce a quiet +3.3VA at 1.2 mA for use by the environmental sensors. D10 is a Trans-Zorb zener transient suppressor to protect the load from accidental arcing from the high-voltage pulse input.

Barometer/Thermometer Chip. U15 is a Freescale MPL115A1 SPI barometer/thermometer chip, allowing readings of the atmospheric pressure and temperature in the enclosure. C81 and C82 are bypass capacitors, while R48 is a pull-up resistor for the open-collector DOUT line. The chip is always enabled. The chip has a bidirectional SPI interface. The SPI signals are driven and received by logic within the CPLD. To issue a command to the barometer chip, the command is written as LSB data to address 0xf2. The first (high-order) data byte of the 16-bit transfer is ignored, and the second (low-order) data byte contains the command (with bit 0 set to 0, and bit 7 set to 0 for chip write or 1 for chip read). A chip write command is used to start conversion. Chip read commands are used for initially retrieving compensation coefficients and for reading the pressure and temperature results of a conversion.

Upon a chip read command, the indicated byte is read from the chip into a register in the CPLD. The serial data may take 5 microseconds to transfer. A read request to USB register address 0xfa is then used to get the upper byte of actual data into the USB FIFO. The chip's SPI interface is 8 bits wide and all of the data to be read out of the chip is 16 bits wide, so this procedure must be repeated with the subsequent read command to get the lower byte. Note that all read data are left-justified and padded with zeros on the least significant end. Table 2 depicts a translation of the available commands:

TABLE 2
Available Command Translations

| | | |
|---|---|---|
| 0x24 | write | Start conversion |
| 0x80 | read | Pressure result MSB |
| 0x82 | read | Pressure result LSB |
| 0x84 | read | Temperature result MSB |
| 0x86 | read | Temperature result LSB |
| 0x88 | read | a0 coefficient MSB |
| 0x8a | read | a0 coefficient LSB |
| 0x8c | read | b1 coefficient MSB |
| 0x8e | read | b1 coefficient LSB |
| 0x90 | read | b2 coefficient MSB |
| 0x92 | read | b2 coefficient LSB |
| 0x94 | read | c12 coefficient MSB |
| 0x96 | read | c12 coefficient LSB |

Once the chip powers up, read commands 0x88 through 0x96 are used to read the coefficients for compensation. (This data varies from chip to chip, but doesn't change on powering down or up. So where it's easier on software to store the coefficients in the local EEPROM on the first “calibration” run rather than reading them from the chip on every power-up, that may be done. Recalibration would need to be completed if the chip was replaced.) The coefficients are plugged into the appropriate equations as indicated in the data sheet. Then the only chip write command, 0x24 (CONVERT), is issued to start the conversion. After waiting at least 3 milliseconds for the conversion to complete, the appropriate result data is read (again, one byte at a time). Once the uncompensated data is obtained, the compensated pressure can be calculated.

Hygrometer/Thermometer Chip. U16 is a Honeywell HIH6131-000-001 SPI hygrometer/thermometer chip, allowing readings of the humidity and temperature in the enclosure. The temperature reading from this chip has better resolution than the temperature reading from U15, although reading the chip is slower. C83 and C84 are bypass capacitors, while R50 is a pull-up resistor for the SS# line. Red LED 11 indicates when a programmable on-chip humidity/temperature alarm has been activated. The chip has a unidirectional SPI interface. Honeywell Technical Note 00971-1-EN (July 2012) is useful in understanding SPI communications with this chip. The SPI signals are driven and received by logic within the CPLD.

This chip has one SPI command, a write command with data ignored. Writing that command requests both a new measurement and retrieves data from the previous measurement into a register in the CPLD. To issue a command to the barometer chip, any value as data (0x0 suggested) is written to address 0xf3. (Data returned at this time may be ignored.) After a delay of at least 40 milliseconds to allow the conversion to complete, write again to address 0xf3 to fetch the data. Then wait for at least 70 more microseconds for the serial data to be retrieved, and issue a read request at address 0xfb to get the 32 bit word containing the temperature, humidity, and two status bits (see the register map for more details). If the high-order two bits (status bits) are both zero, the data is fresh. If they are anything else, repeat the process until fresh data is retrieved.

Universal DC Input Filter/Rectifier. The external coaxial wall-wart power jack might be vulnerable to the use of an incorrect wall adapter. Rather than simply protecting against reverse or excessive voltage input to the jack, the power input to the board is designed to allow operation from input voltages of either polarity from 10.8 to 26.4 volts. Reverse polarity voltage is rectified, and the incoming power is filtered and fed through a buck-boost switching power converter to raise or lower the input voltage as required, and provide a regulated +12 volts at 2 amperes output. The resulting +12 volt supply is used for the MIO board, fan, and load switching relays—all off-board loads. All of the power used on this board comes from the +5 volt USB connection to the MIO.

Power coming in the coaxial jack is protected against transients by C85, PTC1, and D11. C85 snubs the fast rising edges of the transient, bidirectional transient suppressor D11 clamps any voltages over 26.7 volts in either direction, and positive-temperature-coefficient thermistor PTC1 is designed to sharply increase in resistance upon a thermal overload (caused by clamping of D11). The resulting surge-protected voltage is fed through a filter composed of C86, L6, and C87, providing suppression of high-frequency noise. This is then full-wave rectified by Schottky diodes D12 through D15, and the resulting filtered, variable, positive voltage is fed to the buck-boost converter. Note that despite the full-wave rectification, this circuit is not designed for use with a 60 Hz AC-output wall adapter. A frequency and phase plot of the response of the entire input circuit is shown in FIG. 17C.

Buck-Boost Converter. A buck-boost converter can convert an incoming variable voltage up or down as required. This particular topology is known as a SEPIC (single-ended primary inductance converter). It is distinguished by the twin inductor, coupling capacitor, and non-inverting output. This is actually a variation of the inverting Cuk converter with the output connected upside down; the SEPIC has some but not all of the efficiency and low-noise advantages of the Cuk converter. U17 is a Linear Technology LT3959EUHE#PBF switching regulator chip designed specifically with SEPIC and Cuk converters in mind. Its switch is capable of handling a minimum of 6 amperes, which allows building a SEPIC converter with a small amount of boost capability that can deliver 2 amperes at +12 volts. The chip runs at an 800 kHz switching frequency, selected by R57. The SEPIC circuit configuration has continuous non-pulsating input current to reduce radiated noise on the input power cable. The chip is configured with a minimum startup voltage of 9.0 with operation down to 8.0 using R51 and R55. This prevents attempting operation with 6-volt wall adapters which would run into the chip's current limit. C76 selects a 27.5 millisecond soft-start time at power-up to keep startup switching stresses low. C95, C97, C98, and R58 are loop compensation components. R52 and R56 regulate the output voltage to just over +12 volts.

The result of the LT-Spice simulation for the LT3959 showing the output voltage response to a 1-2-1 A output load step is shown in FIG. 17D. The nominal output voltage is +12.1, the load add transient is 540 mV, the DC output shift under load is negligible, the load dump transient is 400 mV, and ripple is about 35 mV peak-to-peak under full load. The output stays within 5% during the load changes, and recovers in about 500 microseconds.

Returning to FIG. 14, LED 12 indicates the status of the buck-boost converter. When the chip's PGOOD# output is active-low, indicating that the output voltage is within regulation, emitter-follower Q7 turns on the LED. PGOOD is also readable as bit 10 (bit 2 of the upper byte) of the status register at 0xfc; a ‘1’ indicates power is OK. Connectors J8 and J9 supply regulated +12V and ground to the fan and MIO board respectively. +12V is also fed to J4 and the load relay drivers on schematic sheet 2. The operation of this converter is independent of the rest of the front end board.

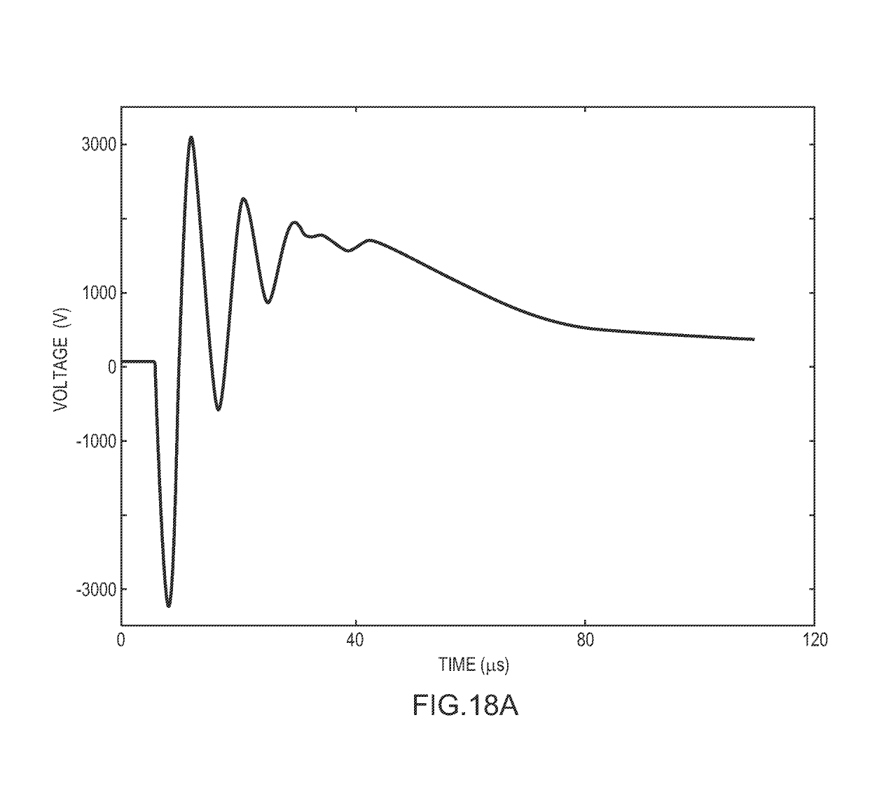

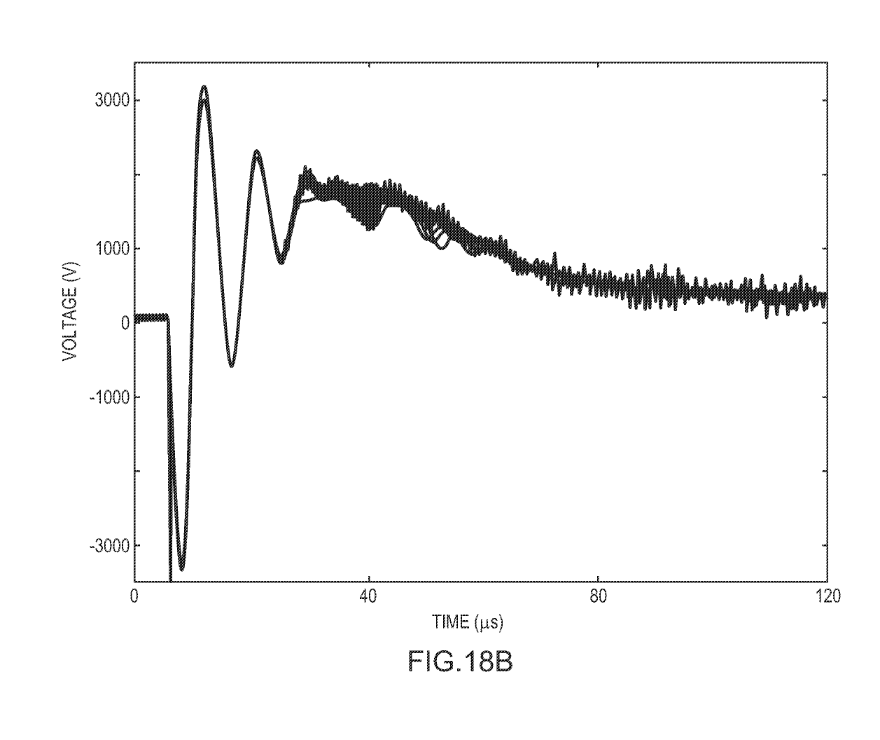

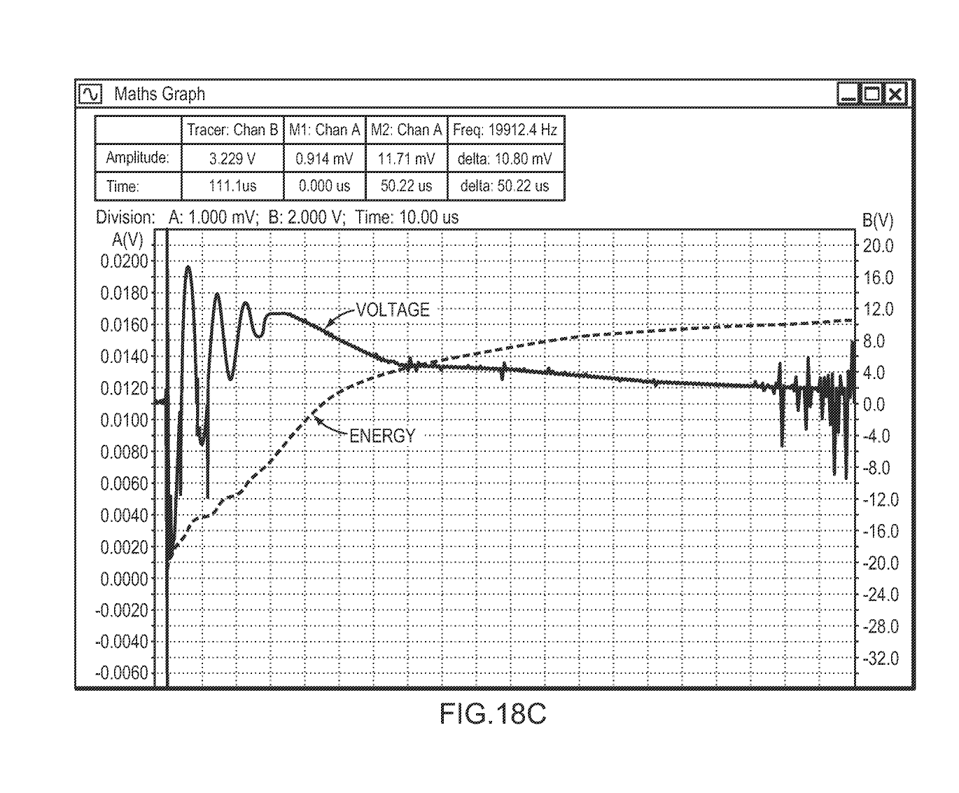

The apparatus and methods described herein may be used to test discharges from stun devices to determine the actual operation of the devices. It should be noted that each discharge from a stun device is not necessarily identical, thus making routine testing desirable. FIG. 18A depicts an “averaged waveform” from a commercially available stun device. FIG. 18B depicts 50 waveforms from the identical stun device, that were combined to make the averaged waveform of FIG. 18A. Notably, FIG. 18B shows variants in the waveform for a plurality of discharges, including transients. Although the general waveform shape is the same, the variants present in each discharge may aid in determining the biological effects of the stun device discharge on a human. FIG. 18C depicts a single discharge of the stun device of FIGS. 18A and 18B, depicting both voltage and the accumulating energy.

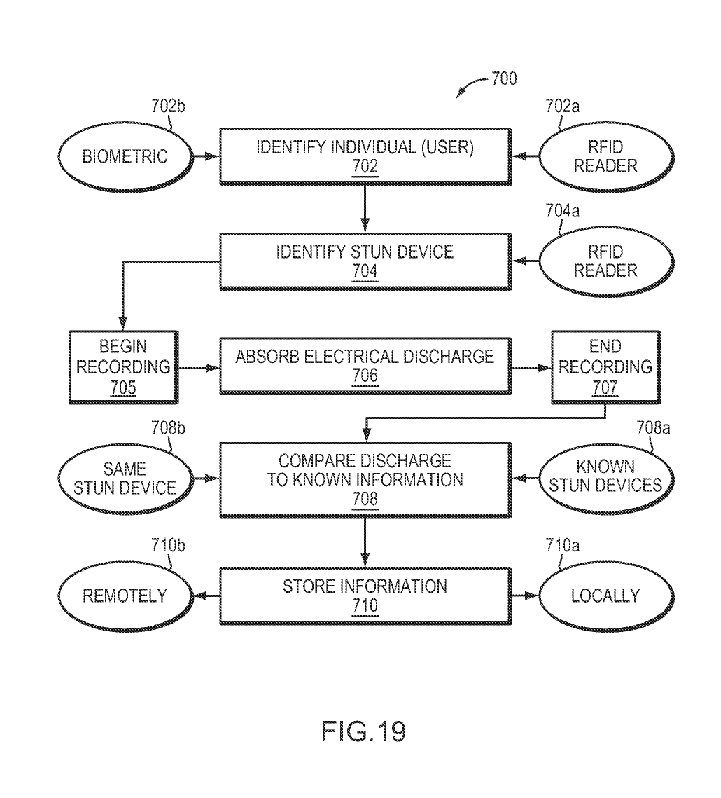

FIG. 19 depicts a method of testing an electric discharge stun device 700. The testing method 700 may begin by first identifying the user of the test apparatus and/or stun device 702. This identification may include one or more identification options. For example, the user may scan a badge containing an RFID circuit 702a. Alternatively or additionally, a biometric sensor (fingerprint scanner, voice detection device, eye scanner, etc.) may be utilized to identify the user. In a basic embodiment, a user may enter an identifying code or password, either through an external computer, or on the tester itself, to begin the testing sequence. Thereafter (or initially, if identification of the user is not desired), the stun device being tested may be identified to the tester 704. This may include scanning an RFID tag 704a located on the device, scanning a bar code or other optical identification device, entering a device serial number into the external computer or the tester itself, or simply inserting the discharge end of a device into the testing port. In operation 705, recordation begins. By beginning recordation prior to discharge of the stun device, electrical leakage, prior to actual discharge, may be detected. Such leakage may be indicative of an operational problem. The resulting electrical discharge is absorbed by the tester 706. Operation 706 may be repeated for any number of ports or test conditions. In one embodiment described herein, four separate ports are utilized. Recordation continues until no electrical signal is recorded from the stun device, and recording is stopped, per operation 707.

Once the device has been discharged, the test device (or a computer connected thereto) compares the discharge to known, stored information 708. This comparison or analysis may serve a number of purposes. In one instance, the discharge may be compared to discharges of known stun devices from one or more manufacturers 708a, this comparative information being stored either locally, remotely, or both. By comparing the discharge to the discharges of known stun devices, a previously unidentified stun device may be identified based on characteristics of its discharge. If the device under test is of an unknown manufacture, or is a new model from a known manufacturer, the discharge may be analyzed to determine whether it matches a known device, or if it has a waveform similar to that already produced by a particular manufacturer. Alternatively, the discharge from a previously unknown or untested device can be compared to known devices to determine if any discharge characteristics are shared. Knowledge of these discharge characteristics and the body's response thereto can help determine if the device is safe to use. In a second instance, the discharge may be compared to a previous discharge from the same device 708b, thus allowing a determination regarding the history and potential future performance (due to, for example, consistent waveform degradation) of the stun device. Regardless of what information the discharge characteristics are compared to, the information regarding the discharge may be stored in a storage medium 710, either locally 710a on the tester, or remotely 710b on a computer or remote database. This stored information may be used to create a repository of electrical discharge information for further access and study. In additional, information within the repository may include specifications of known stun devices and analysis based on the physical design of the device. In that regard, discharge characteristics may be predicted based on a comparison of specifications, as well.

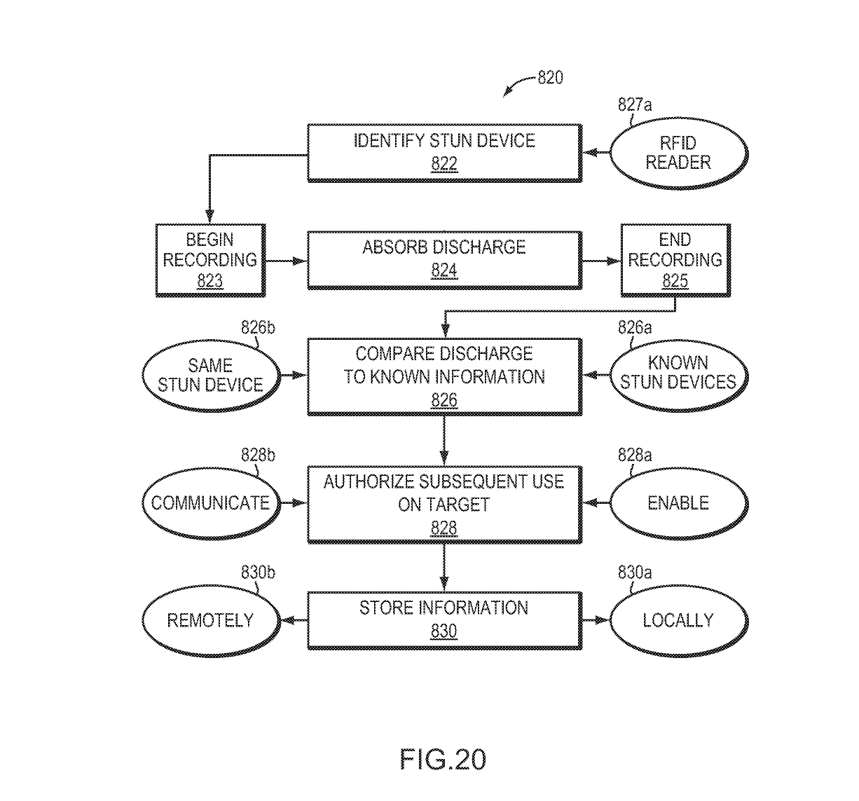

FIG. 20 depicts a method of ensuring proper operation of an electric discharge stun device 820, in accordance with one embodiment of the technology. As an initial operation, the device may be identified 822, either using an RFID reader 822a or some other mechanism, as described above. Recording begins prior to discharge in operation 823. Next, a user activates the device against one or more ports of the tester, which absorbs the discharge 824, as described above. Once no further electrical signal is received from the stun device, recordation stops 825. In operation 826, the discharge of the device is compared to known information, either from known stun devices 826a or from the same stun device 826b. Again, issues attendant with the comparison and analysis are described above. Thereafter, the tester, or a computer associated therewith, analyzes the results of the comparison and makes a determination as to whether the device is functioning properly, prior to any subsequent operation against a human target.

If the device discharges an appropriate waveform (e.g., corresponds to some other waveform previously determined to be “safe” or within manufacturer's specifications), the tester may authorize subsequent use of the stun device on a target 828. This authorization may be made in a number of ways. First, the tester may automatically enable or disable the device 828a, via a communication between the tester and the internal circuitry of the stun device. This action may be made via the lead described with regard to FIG. 6A. Alternatively, the tester may send out a wireless signal to enable or disable the stun device. Additionally, the tester may communicate to the user 828b (either via an audible or visible indicator) whether the stun device is performing properly. In addition to an absolute indicator of proper performance, the testing device may calculate a confidence value for proper performance based on analysis of the waveform and comparisons to known waveforms. Additionally, authorization may not be required for every subsequent discharge. The testing apparatus may authorize use of the stun device over a limited period of time, or until the stun device is next used against a human target. Regardless of the authorization operation, the information regarding the discharge characteristics may be stored 830, either locally 830a or remotely 830b, at least for the purposes described above.

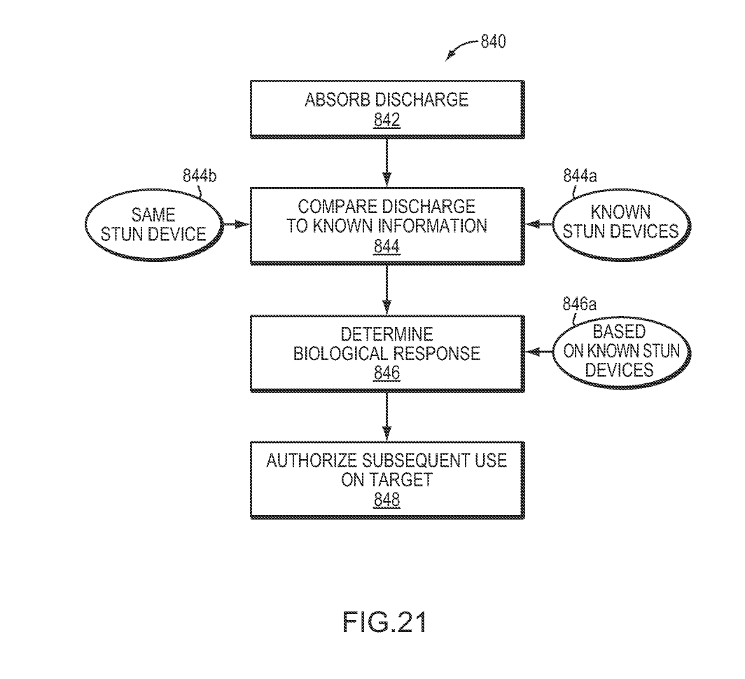

The two testing methods described above in FIGS. 19 and 20 enable another function of the present technology. FIG. 21 depicts a method of determining a biological response to an electric discharge from a stun device 840, in accordance with one embodiment of the technology. The first two operations are similar to those described above. A discharge is first absorbed by the tester 842. Information from that discharge is next compared to known information 844, either from the same stun device 844b, or from the repository of information regarding known stun devices 844a, or even from theoretical information based on the physical design of the stun device under test. Included in the repository are also known biological responses to known electrical discharges from known stun devices 846a. Based on this information, the tester can predict a likely biological response of a human target upon which the stun device is subsequently discharged 846, which may aid in an authorization operation 848, as described above with regard to FIG. 20.

A variety of biological responses may be predicted based on the information obtained from the electrical discharge. Exemplary biological responses may include those that affect all or a significant number of muscles of the body, for example, tetany, partial tetany, substantially complete tetany, etc. Tetany and related biological responses are described in U.S. Patent Application Publication No. 2007/0167241, the entire disclosure of which is hereby incorporated by reference herein in its entirety. In addition, it can be advantageous to determine biological responses that may be considered undesirable or dangerous. Such biological responses may include organ damage, abnormal heart rhythms, epileptic seizures, localized cell death or damage (due to, for example, burns), or complete incapacitation or death of the target. Additionally, information obtained from the electrical discharge may lead to a conclusion that no biological response or an ineffective biological response will be produced by the electrical discharge.

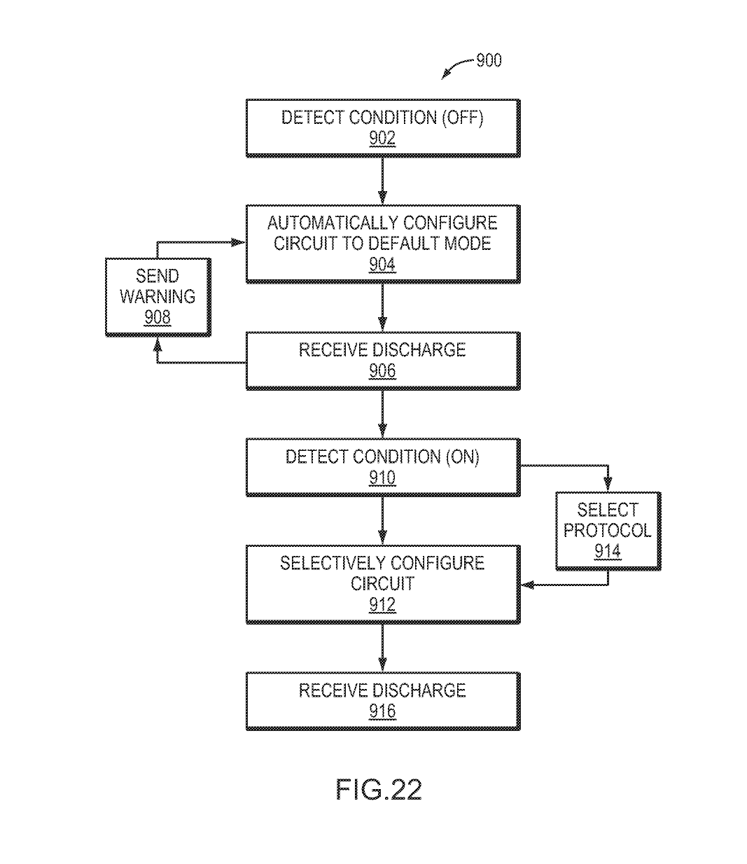

FIG. 22 depicts a method 900 of configuring a circuit in a stun device testing system in accordance with another embodiment of the present technology. A testing device detects a condition indicative of a loss of power to a circuit contained therein in operation 902. This condition, also called an “Off” condition, may be detected due to a position of a switch or a solenoid, or a loss of power to the circuit (due to, e.g., unplugging of the tester). When in the Off condition, the circuit is automatically configured to a default mode in operation 904. In the default mode, the circuit is automatically configured such a default resistor is disposed within the circuit, such that a discharge received from a stun device is routed through that default resistor. Thereafter, a discharge may be safely received by the tester circuit as in operation 906. In an optional operation, the tester may issue a warning 908 to warn the user that the tester is not operational.

In operation 910, the tester detects a condition indicative of a receipt of power to the circuit. This condition is called the “On” condition. Once in the On condition, the tester may configure the circuit so as to obtain the required resistance required for a test, as in operation 912. In this case, the tester and corresponding circuit may only be configured for a particular type of test. In an alternative embodiment, the tester may first select a protocol from a library of protocols, operation 914, prior to setting selectively configuring the circuit so as to have a desired resistance. Thereafter, the tester is ready to receive a discharge 916. Of course, the discharge recordation, analysis operations, and result presentations, such as described in FIGS. 19-21 may be performed at this time.

In the embodiments described above, the software may be configured to run on any computer or workstation such as a PC or PC-compatible machine, an Apple Macintosh, a Sun workstation, etc. In general, any computing device can be used, as long as it is able to perform the functions and capabilities described herein. The particular type of computer or workstation is not central to the technology, nor is the configuration, location, or design of the database, which may be flat-file, relational, or object-oriented, and may include one or more physical and/or logical components.

The servers may include a network interface continuously connected to the network, and thus support numerous geographically dispersed users and applications. In a typical implementation, the network interface and the other internal components of the servers intercommunicate over a main bi-directional bus. The main sequence of instructions effectuating the functions of the technology and facilitating interaction among clients, servers and a network, can reside on a mass-storage device (such as a hard disk or optical storage unit) as well as in a main system memory during operation. Execution of these instructions and effectuation of the functions of the technology is accomplished by a central-processing unit (“CPU”).

A group of functional modules that control the operation of the CPU and effectuate the operations of the technology as described above can be located in system memory (on the server or on a separate machine, as desired). An operating system directs the execution of low-level, basic system functions such as memory allocation, file management, and operation of mass storage devices. At a higher level, a control block, implemented as a series of stored instructions, responds to client-originated access requests by retrieving the user-specific profile and applying the one or more rules as described above.

While there have been described herein what are to be considered exemplary and preferred embodiments of the present technology, other modifications of the technology will become apparent to those skilled in the art from the teachings herein. The particular methods of operation and manufacture and configurations disclosed herein are exemplary in nature and are not to be considered limiting. It is therefore desired to be secured in the appended claims all such modifications as fall within the spirit and scope of the technology. Accordingly, what is desired to be secured by Letters Patent is the technology as defined and differentiated in the following claims, and all equivalents.

What is claimed is:

1. An apparatus comprising:
a housing comprising a port for receiving a discharge end of an electrical discharge device; and
an discharge-receiving circuit operatively connected to the port, the discharge-receiving circuit configured to receive a discharge from the electrical discharge device, wherein the discharge-receiving circuit comprises:
a plurality of resistors comprising a default resistor and at least one supplemental resistor, wherein when in a first setting, the discharge-receiving circuit is configured so as to pass the discharge automatically through at least the default resistor, and wherein when in a second setting, the discharge-receiving circuit is configurable so as to selectively pass the discharge through at least one of the plurality of resistors.

2. The apparatus of claim 1, wherein the at least one supplemental resistor comprises a first supplemental resistor and a second supplemental resistor.

3. The apparatus of claim 2, wherein a resistance of the default resistor is higher than a resistance of at least one of the first supplemental resistor and the second supplemental resistor.

4. The apparatus of claim 1, further comprising a switch for selectively setting the discharge-receiving circuit to either of the first setting and the second setting.

5. The apparatus of claim 1, wherein the discharge-receiving circuit is set to the first setting when the discharge-receiving circuit is unpowered.

6. The apparatus of claim 1, further comprising an environmental module for detecting at least one of an ambient temperature, an ambient humidity, and a barometric pressure.

7. The apparatus of claim 1, further comprising an air intake fan for drawing ambient air into the housing, and wherein the environmental module detects at least one of the ambient temperature and the ambient humidity, and wherein the environmental module is disposed downstream of the air intake fan.

8. The apparatus of claim 1, wherein the discharge-receiving circuit further comprises an analysis module.

9. A method of configuring a circuit, the method comprising:
detecting a condition indicative of a loss of power to the circuit;
configuring the circuit such that an electrical discharge through the circuit is routed through at least one of a plurality of resistors, wherein the electrical discharge is received from a device located external to the circuit.

10. The method of claim 9, further comprising receiving the electrical discharge from the external device.

11. The method of claim 9, further comprising:
detecting a condition indicative of a receipt of power to the circuit; and
selectively configuring the circuit so as to route the discharge through at least one of the plurality of resistors.

12. The method of claim 11, further comprising:
selecting a protocol; and
selectively configuring the circuit based at least in part on the selected protocol.

13. The method of claim 9, wherein the condition is based at least in part on the position of a switch in the circuit.

14. The method of claim 9, wherein the condition is based at least in part on an absence of supply power to the circuit.

15. The method of claim 9, wherein configuring the circuit comprises at least one of opening or closing a solenoid.

16. The method of claim 9, wherein the circuit is disposed within a testing device.
